(19) United States
(12) Patent Application Publication
(10) Pub. No.: US 2024/0125559 A1
(43) Pub. Date: Apr. 18, 2024

(54) BODY SHEET FOR VAPOR CHAMBER, VAPOR CHAMBER, AND ELECTRONIC APPARATUS

(71) Applicant: DAI NIPPON PRINTING CO., LTD., Tokyo-to (JP)

(72) Inventors: Kazunori ODA, Tokyo-to (JP); Shinichiro TAKAHASHI, Tokyo-to (JP); Takayuki OTA, Tokyo-to (JP); Toshihiko TAKEDA, Tokyo-to (JP); Shinya KIURA, Tokyo-to (JP); Makoto YAMAKI, Tokyo-to (JP); Isao INOUE, Tokyo-to (JP)

(73) Assignee: DAI NIPPON PRINTING CO., LTD., Tokyo-to (JP)

(21) Appl. No.: 18/275,632

(22) PCT Filed: Feb. 2, 2022
(86) PCT No.: PCT/JP2022/004135

§ 371 Date: Aug. 3, 2023

(30) Foreign Application Priority Data
Feb. 3, 2021 (JP) 2021-015966
Feb. 3, 2021 (JP) 2021-015977

(51) Int. Cl. F28D 15/02; H05K 7/20

(52) U.S. Cl. CPC F28D 15/0233; H05K 7/2029

(57) ABSTRACT

A body sheet for a vapor chamber includes a first body surface, a second body surface disposed opposite to the first body surface, and a penetration space extending from the first body surface to the second body surface. The penetration space extends in a first direction in plan view. As seen in a cross section perpendicular to the first direction, the penetration space includes a first opening positioned on the first body surface and a second opening positioned on the second body surface. The second opening extends from a region overlapping with the first opening in plan view to a position overlapping with the first groove in plan view.

### TECHNICAL FIELD

The present invention relates to a body sheet for a vapor chamber, a vapor chamber, and an electronic apparatus.

### BACKGROUND ART

Electronic apparatuses including mobile terminal, such as portable terminals and tablet terminals, employ electronic devices that generate heat. Examples of the electronic devices include a central processing unit (CPU), a light-emitting diode (LED), and a power semiconductor device. Such electronic devices are cooled by a heat radiator, such as a heat pipe (for example, see PTLs 1 and 2). For thinner electronic apparatuses, thinner heat radiators have recently been demanded. As heat radiators, vapor chambers thinner than heat pipes are under development. Vapor chambers can efficiently cool electronic devices by absorbing the heat of the electronic devices and diffusing the heat therein with enclosed-in working fluid.

More specifically, the working liquid (working fluid) in the vapor chamber receives the heat from the electronic device with a portion (evaporating portion) close to the electronic device. The heated working liquid evaporates to become working vapor. The working vapor diffuses in a vapor channel formed in the vapor chamber in directions away from the evaporating portion. The diffused working vapor is cooled and condensed to become working liquid. The vapor chamber houses a liquid channel portion with a capillary structure (wicks). The working liquid flows through the liquid channel portion to the evaporating portion. The working liquid conveyed to the evaporating portion is evaporated again by the heat at the evaporating portion. Thus, the working fluid refluxes in the vapor chamber while changing in phase, that is, repeating evaporation and condensation, to diffuse the heat of the electronic device. This increases the heat radiation efficiency of the vapor chamber.
PTL 1: Japanese Patent Laid-Open No. 2008-82698
PTL 2: Japanese Patent Laid-Open No. 2016-017702

### SUMMARY

It is an object of the present invention to provide a body sheet for a vapor chamber configured to increase in cooling efficiency, a vapor chamber, and an electronic apparatus.

The present invention provides, as a first solution, a body sheet for a vapor chamber in which a working fluid is enclosed, the body sheet including: a first body surface; a second body surface disposed opposite to the first body surface; a penetration space extending from the first body surface to the second body surface; and a plurality of first grooves provided on the first body surface and communicating with the penetration space, the plurality of first grooves extending in a first direction, wherein the penetration space extends in the first direction in plan view, and wherein, as seen in a cross section perpendicular to the first direction, the penetration space includes a first opening positioned on the first body surface and a second opening positioned on the second body surface, the second opening extending from a region overlapping with the first opening in plan view to a position overlapping with the first grooves in plan view.

The body sheet for a vapor chamber according to the first solution may be configured such that, as seen in a cross section perpendicular to the first direction, the penetration space includes a first space depressed portion disposed on the first body surface and defining the first opening and a second space depressed portion disposed on the second body surface and defining the second opening, the second space depressed portion communicating with the first space depressed portion, that the first space depressed portion includes a pair of first wall surfaces curved in a concave shape, that the second space depressed portion includes a pair of second wall surfaces curved in a concave shape, that the first wall surface and the second wall surface corresponding to each other are connected by a wall-surface protrusion protruding toward inside of the penetration space, and that, as seen in a cross section perpendicular to the first direction, the second space depressed portion includes a flat surface having a flat shape connecting the second wall surface and the wall-surface protrusion corresponding to each other.

The body sheet for a vapor chamber according to the first solution may be configured such that, as seen in a cross section perpendicular to the first direction, the penetration space includes a first space depressed portion disposed on the first body surface and defining the first opening and a second space depressed portion disposed on the second body surface and defining the second opening, the second space depressed portion communicating with the first space depressed portion, that the first space depressed portion includes a pair of first wall surfaces curved in a concave shape, that the second space depressed portion includes a pair of second wall surfaces curved in a concave shape, that the first wall surface and the second wall surface corresponding to each other are connected by a wall-surface protrusion protruding toward inside of the penetration space, that, as seen in a cross section perpendicular to the first direction, the second space depressed portion includes a protruding surface connecting the second wall surface and the wall-surface protrusion corresponding to each other, and that the protruding surface includes a spatial protrusion extending in the first direction and protruding toward the second body surface.

The body sheet for a vapor chamber according to the first solution may be configured such that the protruding surface includes a plurality of the spatial protrusions separate from each other.

The body sheet for a vapor chamber according to the first solution may be configured such that, as seen in a cross section perpendicular to the first direction, the penetration space includes a first space depressed portion disposed on the first body surface and defining the first opening and a second space depressed portion disposed on the second body surface and defining the second opening, the second space depressed portion communicating with the first space depressed portion, that the first space depressed portion includes a pair of first wall surfaces curved in a convex shape, and that the second space depressed portion includes a pair of second wall surfaces curved in a concave shape.

The body sheet for a vapor chamber according to the first solution may be configured such that, as seen in a cross section perpendicular to the first direction, the second opening extends from a region overlapping with the first opening in plan view to positions overlapping with the first grooves in plan view on both sides of the first opening.

The body sheet for a vapor chamber according to the first solution may further include a frame having a frame shape in plan view and extending from the first body surface to the second body surface, the frame defining the penetration space; and a land disposed inside the frame, the land extending in the first direction and extending from the first body surface to the second body surface, and may be configured such that the first opening and the second opening are positioned between the frame and the land, that the first grooves are positioned on the first body surface of the land, and that, as seen in a cross section perpendicular to the first direction, the second opening extends from a region overlapping with the first opening in plan view to a position overlapping with the first grooves positioned in the land in plan view, the second opening extending more toward outside of the frame than the first opening.

The present invention provides, as a second solution, a body sheet for a vapor chamber in which a working fluid is enclosed, the body sheet including: a first body surface; a second body surface disposed opposite to the first body surface; and a penetration space extending from the first body surface to the second body surface, wherein the penetration space extends in a first direction in plan view, wherein, as seen in a cross section perpendicular to the first direction, the penetration space includes a first space depressed portion disposed on the first body surface and a second space depressed portion disposed on the second body surface and communicating with the first space depressed portion, wherein the first space depressed portion includes a pair of first wall surfaces, wherein the second space depressed portion includes a pair of second wall surfaces, wherein one of the first wall surfaces of the first space depressed portion and corresponding one of the second wall surfaces of the second space depressed portion are connected by a first wall-surface protrusion, wherein the first wall-surface protrusion protrudes toward inside of the penetration space, wherein the first wall-surface protrusion is disposed off an intermediate position between the first body surface and the second body surface in a direction normal to the first body surface, and wherein the first wall surface positioned opposite to the first wall-surface protrusion of the first space depressed portion and corresponding one of the second wall surfaces of the second space depressed portion are continuously formed in a concave shape from the first wall surface to the second wall surface.

The body sheet for a vapor chamber according to the second solution may be configured such that the penetration space includes a first opening positioned on the first body surface and defined by the first space depressed portion and a second opening positioned on the second body surface and defined by the second space depressed portion, and that, as seen in a cross section perpendicular to the first direction, a center of the first opening is disposed off a center of the second opening.

The present invention provides, as a third solution, a body sheet for a vapor chamber in which a working fluid is enclosed, the body sheet including: a first body surface; a second body surface disposed opposite to the first body surface; and a penetration space extending from the first body surface to the second body surface, wherein the penetration space extends in a first direction in plan view, wherein, as seen in a cross section perpendicular to the first direction, the penetration space includes a first space depressed portion disposed on the first body surface and a second space depressed portion disposed on the second body surface and communicating with the first space depressed portion, wherein the first space depressed portion includes a pair of first wall surfaces, wherein the second space depressed portion includes a pair of second wall surfaces, wherein one of the first wall surfaces of the first space depressed portion and corresponding one of the second wall surfaces of the second space depressed portion are connected by a first wall-surface protrusion, wherein the first wall-surface protrusion protrudes toward inside of the penetration space, wherein the first wall-surface protrusion is disposed off an intermediate position between the first body surface and the second body surface in a direction normal to the first body surface, wherein the penetration space includes a first opening positioned on the first body surface and defined by the first space depressed portion and a second opening positioned on the second body surface and defined by the second space depressed portion, and wherein, as seen in a cross section perpendicular to the first direction, a center of the first opening is disposed off a center of the second opening.

The body sheet for a vapor chamber according to the third solution may further include: a frame having a frame shape in plan view; and a land disposed inside the frame, the land extending in the first direction and defining the penetration space with the frame, and may be configured such that a gap amount between the center of the first opening and the center of the second opening is expressed as 0.05 mm to (0.8×w1) mm, where w1 is a width of the land.

The body sheet for a vapor chamber according to the third solution may further include a plurality of first grooves provided on the first body surface and communicating with the penetration space, and may be configured such that the first wall-surface protrusion is disposed nearer to the first body surface than the intermediate position.

The body sheet for a vapor chamber according to the third solution may be configured such that the first wall surface of the first space depressed portion positioned opposite to the first wall-surface protrusion and corresponding one of the second wall surfaces of the second space depressed portion are connected by a second wall-surface protrusion, that the second wall-surface protrusion protrudes toward inside of the penetration space, and that the second wall-surface protrusion is disposed off an intermediate position between the first body surface and the second body surface in the direction of normal.

The body sheet for a vapor chamber according to the third solution may be configured such that the second wall-surface protrusion is disposed nearer to the first body surface than the intermediate position.

The present invention provides, as a fourth solution, a body sheet for a vapor chamber in which a working fluid is enclosed, the body sheet including: a first body surface; a second body surface disposed opposite to the first body surface; and a penetration space extending from the first body surface to the second body surface, wherein the penetration space extends in a first direction in plan view, wherein, as seen in a cross section perpendicular to the first direction, the penetration space includes a first space depressed portion disposed on the first body surface, a second space depressed portion disposed on the second body surface and communicating with the first space depressed portion, and third space depressed portions positioned on the second body surface on both sides of the second space depressed portion and communicating with the second space depressed portion, wherein the second space depressed portion includes a pair of second wall surfaces, wherein the third space depressed portions each include a third wall surface, wherein each of the second wall surfaces of the second space depressed portion and corresponding one of the third wall surfaces of the third space depressed portions are connected by a third wall-surface protrusion, and wherein the third wall-surface protrusion protrudes toward the second body surface.

The body sheet for a vapor chamber according to the fourth solution may be configured such that the first space depressed portion includes a pair of first wall surfaces, that one of the first wall surfaces of the first space depressed portion and corresponding one of the second wall surfaces of the second space depressed portion are connected by a first wall-surface protrusion, that the first wall-surface protrusion protrudes toward inside of the penetration space, and that the first wall-surface protrusion is disposed off an intermediate position between the first body surface and the second body surface in a direction normal to the first body surface.

The body sheet for a vapor chamber according to the fourth solution may further include a plurality of first grooves provided on the first body surface and communicating with the penetration space, and may be configured such that the first wall-surface protrusion is disposed nearer to the first body surface than the intermediate position.

The body sheet for a vapor chamber according to the fourth solution may be configured such that the first wall surface of the first space depressed portion positioned opposite to the first wall-surface protrusion and corresponding one of the second wall surfaces of the second space depressed portion are connected by a second wall-surface protrusion, that the second wall-surface protrusion protrudes toward inside of the penetration space, and that the second wall-surface protrusion is disposed off an intermediate position between the first body surface and the second body surface in the direction of normal.

The body sheet for a vapor chamber according to the fourth solution may be configured such that the second wall-surface protrusion is disposed nearer to the first body surface than the intermediate position.

The body sheet for a vapor chamber according to the fourth solution may be configured such that the first wall surface positioned opposite to the first wall-surface protrusion of the first space depressed portion and corresponding one of the second wall surfaces of the second space depressed portion are continuously formed in a concave shape from the first wall surface to the second wall surface.

The body sheet for a vapor chamber according to the fourth solution may be configured such that the penetration space includes a first opening positioned on the first body surface and defined by the first space depressed portion and a second opening positioned on the second body surface and defined by the second space depressed portion, and that, as seen in a cross section perpendicular to the first direction, a center of the first opening is disposed off a center of the second opening.

The body sheet for a vapor chamber according to the fourth solution may further include: a frame having a frame shape in plan view; and a land disposed inside the frame, the land extending in the first direction and defining the penetration space with the frame, and may be configured such that a gap amount between the center of the first opening and the center of the second opening is expressed as 0.05 mm to (0.8×w1) mm, where w1 is a width of the land.

The present invention provides, as a fifth solution, a body sheet for a vapor chamber, the body sheet including: a first body surface; a second body surface positioned opposite to the first body surface; a penetration space penetrating the first body surface and the second body surface; and a plurality of first grooves provided on the second body surface and communicating with the penetration space, wherein the penetration space includes a curved first wall surface positioned closer to the first body surface and a curved second wall surface positioned closer to the second body surface, wherein the first wall surface and the second wall surface join together at a protrusion protruding to inside the penetration space, wherein the protrusion is positioned nearer to the second body surface than an intermediate position between the first body surface and the second body surface, wherein the first wall surface includes a first wall surface end closer to the first body surface, and wherein the first wall surface end is positioned more inside the penetration space than the protrusion in plan view.

The body sheet for a vapor chamber according to the fifth solution may be configured such that the second wall surface includes a second wall surface end closer to the second body surface, and that a distance Ls between the second wall surface end and the first wall surface end is 1.05 or more times and two or less times a distance Lp between the second wall surface end and the protrusion in a width direction of the penetration space.

The body sheet for a vapor chamber according to the fifth solution may be configured such that the plurality of first grooves is disposed in parallel with each other, that a protrusion row is provided between the first grooves next to each other, that each protrusion row includes a plurality of protrusions, that the second wall surface includes a second wall surface end closer to the second body surface, and that a distance Ls between the second wall surface end and the first wall surface end is 1.1 or more times and 10 or less times a width of each of the protrusions.

The present invention provides, as a sixth solution, a vapor chamber including: a first sheet; a second sheet; and the body sheet for the vapor chamber according to any one of the first to sixth solutions, the body sheet being interposed between the first sheet and the second sheet.

The present invention provides, as a seventh solution, a vapor chamber in which a working fluid is enclosed, the vapor chamber including: a first sheet, a second sheet; and a body sheet for the vapor chamber, the body sheet being interposed between the first sheet and the second sheet, wherein the body sheet includes: a first body surface; a second body surface positioned opposite to the first body surface; a penetration space penetrating the first body surface and the second body surface; and a plurality of first grooves provided on the second body surface and communicating with the penetration space, wherein the penetration space includes a curved first wall surface positioned closer to the first body surface and a curved second wall surface positioned closer to the second body surface, wherein the first wall surface and the second wall surface join together at a protrusion protruding to inside the penetration space, wherein the protrusion is positioned nearer to the second body surface than an intermediate position between the first body surface and the second body surface, wherein the first wall surface includes a first wall surface end closer to the first body surface, and wherein the first wall surface end is positioned more inside the penetration space than the protrusion in plan view.

The vapor chamber according to the seventh solution may be configured such that the second wall surface includes a second wall surface end closer to the second body surface, and that a distance Ls between the second wall surface end and the first wall surface end is 1.05 or more times and two or less times a distance Lp between the second wall surface end and the protrusion in a width direction of the penetration space.

The vapor chamber according to the seventh solution may be configured such that the plurality of first grooves is disposed in parallel with each other, that a protrusion row is provided between the first grooves next to each other, that each protrusion row includes a plurality of protrusions, that the second wall surface includes a second wall surface end closer to the second body surface, and that a distance Ls between the second wall surface end and the first wall surface end is 1.1 or more times and 10 or less times a width of each of the protrusions.

The present invention provides, as an eighth solution, an electronic apparatus including: a housing; an electronic device housed in the housing; and the vapor chamber according to the sixth solution or the seventh solution, the vapor chamber being thermally in contact with the electronic device.

The present invention can enhance the cooling efficiency.

### BRIEF DESCRIPTION OF DRAWINGS

FIG. 1 is a schematic perspective view of an electronic apparatus according a first embodiment of the present invention.

FIG. 2 is a top view of a vapor chamber according to the first embodiment of the present invention.

FIG. 3 is a cross-sectional view of the vapor chamber in FIG. 2 taken along line A-A.

FIG. 4 is a top view of a lower sheet in FIG. 3.

FIG. 5 is a bottom view of a upper sheet in FIG. 3.

FIG. 6 is a top view of a wick sheet in FIG. 3.

FIG. 7 is a bottom view of the wick sheet in FIG. 3.

FIG. 8A is a partial enlarged cross-sectional view of FIG. 3 illustrating a second vapor passage.

FIG. 8B is a partial enlarged cross-sectional view of an example of an upper opening.

FIG. 8C is a partial enlarged cross-sectional view of an example of the upper opening.

FIG. 8D is a partial enlarged cross-sectional view of an example of the upper opening.

FIG. 8E is a partial enlarged cross-sectional view of an example of the upper opening.

FIG. 8F is a schematic diagram for illustrating a flat surface.

FIG. 9 is a partial enlarged top view of the liquid channel portion shown in FIG. 7.

FIG. 10 is a partial enlarged cross-sectional view of FIG. 3 illustrating a first vapor passage.

FIG. 11 is a partial enlarged cross-sectional view of a modification of the vapor chamber shown in FIG. 8A.

FIG. 12 is a partial enlarged cross-sectional view of a modification of the vapor chamber shown in FIG. 8A.

FIG. 13 is a partial enlarged cross-sectional view of a modification of the vapor chamber shown in FIG. 8A.

FIG. 14 is a partial enlarged cross-sectional view of a modification of the vapor chamber shown in FIG. 8A.

FIG. 15A is a partial enlarged top view of a modification of the wick sheet shown in FIG. 6.

FIG. 15B is a partial enlarged cross-sectional view of a second vapor passage in the second region shown in FIG. 15A.

FIG. 16 is a cross-sectional view of a vapor chamber according to a second embodiment of the present invention, corresponding to the cross section taken along line A-A in FIG. 2.

FIG. 17 is a partial enlarged cross-sectional view of FIG. 16.

FIG. 18 is a diagram for illustrating a wick sheet preparation process in a method for producing the vapor chamber according to the second embodiment.

FIG. 19 is a diagram for illustrating a resist forming process in the method for producing the vapor chamber according to the second embodiment.

FIG. 20 is a diagram for illustrating a resist patterning process in the method for producing the vapor chamber according to the second embodiment.

FIG. 21 is a diagram for illustrating an etching process in the method for producing the vapor chamber according to the second embodiment.

FIG. 22 is a diagram for illustrating a resist removing process in the method for producing the vapor chamber according to the second embodiment.

FIG. 23 is a diagram for illustrating a bonding process in the method for producing the vapor chamber according to the second embodiment.

FIG. 24 is a partial enlarged cross-sectional view of a modification of the vapor chamber shown in FIG. 17.

FIG. 25 is a partial enlarged cross-sectional view of another modification of the vapor chamber shown in FIG. 17.

FIG. 26 is a partial enlarged cross-sectional view of a vapor chamber according to a third embodiment of the present invention.

FIG. 27 is a diagram for illustrating a first resist forming process in a method for producing the vapor chamber according to the third embodiment.

FIG. 28 is a diagram for illustrating a first patterning process for a first resist in the method for producing the vapor chamber according to the third embodiment.

FIG. 29 is a diagram for illustrating a first etching process in the method for producing the vapor chamber according to the third embodiment.

FIG. 30 is a diagram for illustrating a first resist removing process in the method for producing the vapor chamber according to the third embodiment.

FIG. 31 is a diagram for illustrating a second resist forming process in the method for producing the vapor chamber according to the third embodiment.

FIG. 32 is a diagram for illustrating a second patterning process for a second resist in the method for producing the vapor chamber according to the third embodiment.

FIG. 33 is a diagram for illustrating a second etching process in the method for producing the vapor chamber according to the third embodiment.

FIG. 34 is a diagram for illustrating a second resist removing process in the method for producing the vapor chamber according to the third embodiment.

FIG. 35 is a partial enlarged cross-sectional view of a modification of the vapor chamber shown in FIG. 26.

FIG. 36 is a top view of a vapor chamber according to a fourth embodiment of the present invention.

FIG. 37 is a cross-sectional view of the vapor chamber in FIG. 36 taken along line B-B.

FIG. 38 is a top view of the lower sheet in FIG. 37.

FIG. 39 is a bottom view of the upper sheet in FIG. 37.

FIG. 40 is a top view of the wick sheet in FIG. 37.

FIG. 41 is a bottom view of the wick sheet in FIG. 37.

FIG. 42 is a partial enlarged cross-sectional view of FIG. 37.

FIG. 43 is a partial enlarged top view of the liquid channel portion shown in FIG. 40.

FIG. 44 is a diagram illustrating a method for producing a vapor chamber according to a fourth embodiment.

FIG. 45 is a diagram illustrating the method for producing the vapor chamber according to the fourth embodiment.

FIG. 46 is a diagram illustrating the method for producing the vapor chamber according to the fourth embodiment.

FIG. 47 is a partial enlarged cross-sectional view of a working fluid in a vapor channel portion according to the fourth embodiment.

### DETAILED DESCRIPTION

Embodiments of the present invention will be described hereinbelow with reference to the drawings. In the drawings attached to this specification, the scale, the aspect ratio, and so on are changed with exaggeration from real things for ease of illustration and understanding.

The geometric conditions, the physical characteristics, the terms specifying the degree of the geometric conditions or the physical characteristics, the numerical values indicating the geometric conditions or the physical characteristics, and so on used in this specification may be construed without being bound by strict meaning. The geometric conditions, the physical characteristics, the terms, the numerical values, and so on may be construed to the extent to which similar functions can be expected. Examples of the terms specifying the geometric conditions include “length”, “angle”, “shape”, and “disposition”.

Examples of the terms specifying the geometric conditions include “parallel”, “perpendicular”, and “identical”. For clarification of the drawings, the shapes of a plurality of portions that may provide similar functions are described in a regular manner. However, the shapes of the portions may differ from one another without being bound by strict meaning as far as the relevant functions can be expected. In the drawings, boundaries indicating the bonding surfaces of components and so on are indicated by simple straight lines. However, they are not limited to strict straight lines, and the boundaries may have any shapes as far as desired bonding performance can be expected.

### First Embodiment

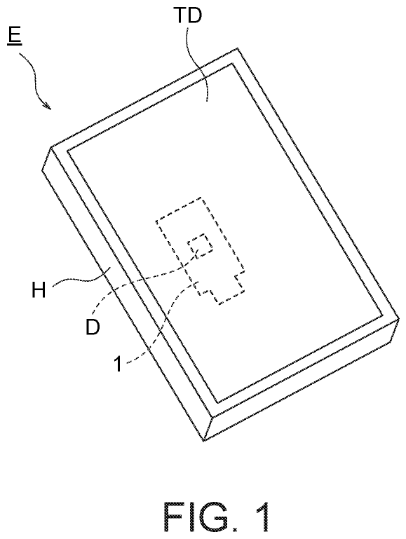

Referring to FIGS. 1 to 15B, a body sheet for a vapor chamber, a vapor chamber, and an electronic apparatus according to a first embodiment of the present invention will be described. A vapor chamber 1 of this embodiment is an apparatus housed in the housing H of an electronic apparatus E together with an electronic device D that generates heat and configured to cool the electronic device D. Examples of the electronic apparatus E include mobile terminals, such as portable terminals and tablet terminals. Examples of the electronic device D include a CPU, an LED, and a power semiconductor device. The electronic device D may also be referred to as “device to be cooled”.

Here, the electronic apparatus E in which the vapor chamber 1 according to this embodiment is mounted will be described taking a tablet terminal as an example. As shown in FIG. 1, the electronic apparatus E includes the housing H, the electronic device D housed in the housing H, and the vapor chamber 1. The electronic apparatus E shown in FIG. 1 includes a touch panel display TD at the front of the housing H. The vapor chamber 1 is housed in the housing H so as to be thermally in contact with the electronic device D. The vapor chamber 1 receives heat generated by the electronic device D when the electronic apparatus E is in operation. The heat received by the vapor chamber 1 is radiated outside the vapor chamber 1 via working fluids 2a and 2b, described later. Thus, the electronic device D is effectively cooled. If the electronic apparatus E is a tablet terminal, the electronic device D may be a central processing unit or the like.

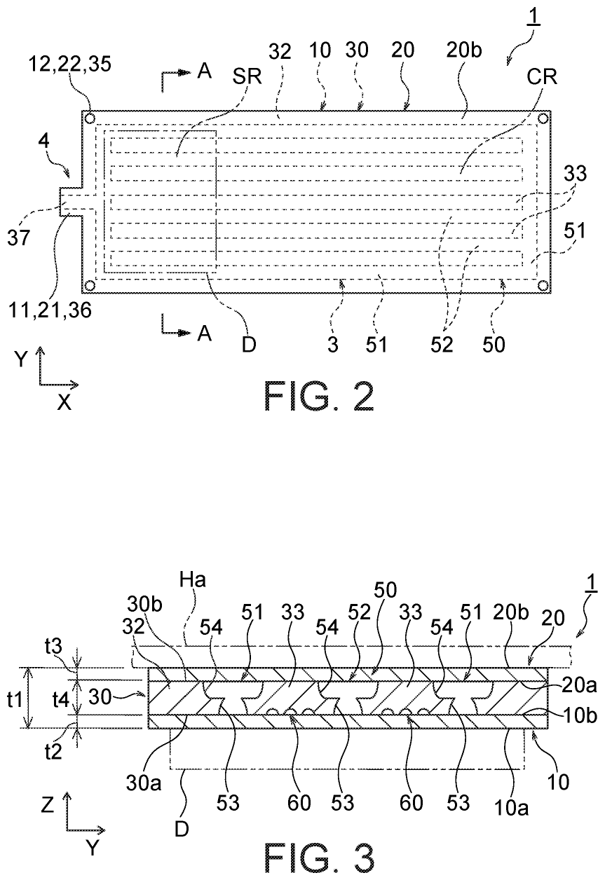

Next, the vapor chamber 1 according to this embodiment will be described. As shown in FIGS. 2 and 3, the vapor chamber 1 has a sealed space 3 in which the working fluids 2a and 2b are enclosed. Repetition of the phase change of the working fluids 2a and 2b in the sealed space 3 allows the electronic device D in the electronic apparatus E to be effectively cooled. Examples of the working fluids 2a and 2b include pure water, ethanol, methanol, acetone, and a mixture thereof. The working fluids 2a and 2b may have freeze expansivity. In other words, the working fluids 2a and 2b may be fluid that expands when freezes. Examples of the working fluids 2a and 2b having freeze expansivity include pure water and an aqueous solution in which an additive, such as alcohol, is added to pure water.

As shown in FIGS. 2 and 3, the vapor chamber 1 includes a lower sheet 10, an upper sheet 20, a wick sheet 30 for the vapor chamber, a vapor channel portion 50, and a liquid channel portion 60. The wick sheet 30 is interposed between the lower sheet 10 and the upper sheet 20. The wick sheet 30 for the vapor chamber is hereinafter simply referred to as “wick sheet 30”. In the vapor chamber 1 according to this embodiment, the lower sheet 10, the wick sheet 30, and the upper sheet 20 are overlapped in this order.

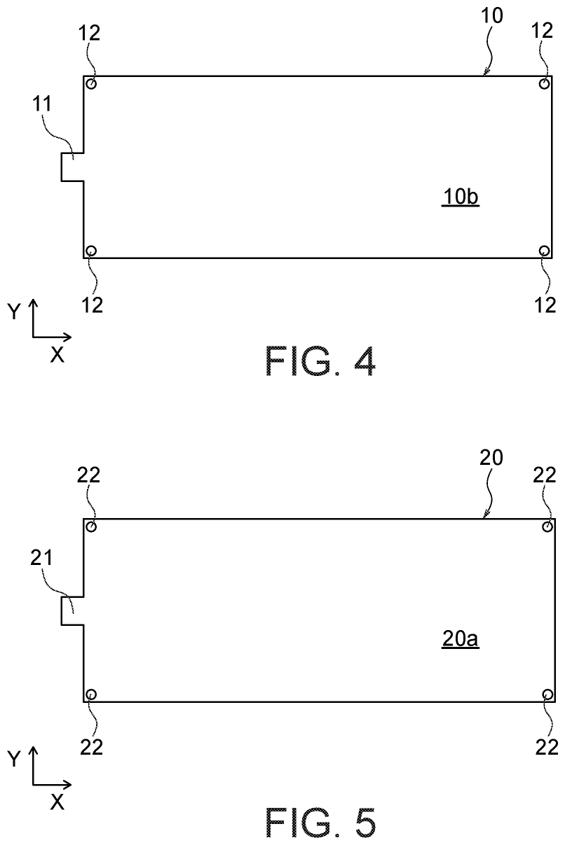

The vapor chamber 1 is schematically formed like a thin flat plate. The vapor chamber 1 may have any planar shape, such as a rectangular shape as shown in FIG. 2. The vapor chamber 1 may be a rectangle 1 cm on one side and 3 cm on the other side in plan view, or alternatively a square 15 cm on one side. The vapor chamber 1 may have any planar dimensions. This embodiment shows an example in which the vapor chamber 1 is a rectangle that is long in the X-direction (described later) in planar shape. In this case, as shown in FIGS. 4 to 7, the lower sheet 10, the upper sheet 20, and the wick sheet 30 may have a planar shape similar to the vapor chamber 1. The planar shape of the vapor chamber 1 is not limited to the rectangular shape and may be a circular shape, an elliptical shape, an L-shape, a T-shape, or any other shape.

As shown in FIG. 2, the vapor chamber 1 includes an evaporation region SR where the working fluids 2a and 2b evaporate and a condensation region CR where the working fluids 2a and 2b condense. The working vapor 2a is a gaseous-state working fluid, and the working liquid 2b is a liquid-state working fluid.

The evaporation region SR is overlapping with the electronic device D in plan view and is fitted with the electronic device D. The evaporation region SR may be disposed at any place of the vapor chamber 1. In this embodiment, the evaporation region SR is formed on one side of the vapor chamber 1 in the X-direction (on the left in FIG. 2). The heat from the electronic device D is transmitted to the evaporation region SR, and the heat causes the working liquid 2b to evaporate in the evaporation region SR. The heat from the electronic device D can be transmitted not only to a region overlapping the electronic device D in plan view but also to the periphery of the region. For this reason, the evaporation region SR includes the region overlapping with the electronic device D in plan view and its peripheral region. The plan view may be the view of the vapor chamber 1 seen from a direction perpendicular to a surface of the vapor chamber 1 that receives the heat from the electronic device D and a surface that radiates the heat. The surface that receives the heat corresponds to a first lower sheet surface 10a of the lower sheet 10, described below. The surface that radiates the heat corresponds to a second upper sheet surface 20b of the upper sheet 20, described below. For example, the plan view corresponds to a state in which the vapor chamber 1 is seen from above or below, as shown in FIG. 2.

The condensation region CR is a region that is not overlapping with the electronic device D in plan view and in which the working vapor 2a of the working fluid radiates heat to condense. The condensation region CR may be the periphery of the evaporation region SR. In the condensation region CR, the heat from the working vapor 2a is radiated to the upper sheet 20, so that the working vapor 2a is cooled in the condensation region CR to condense.

The vapor chamber 1, if installed in a mobile terminal, may change in the vertical relationship according to the orientation of the mobile terminal. However, in this embodiment, the sheet that receives the heat from the electronic device D is referred to as the lower sheet 10, described above, and the sheet that radiates the received heat is referred to as the upper sheet 20, described above, for convenience. Accordingly, the following description is made, with the lower sheet 10 disposed on the lower side, and the upper sheet 20 on the upper side.

As shown in FIG. 3, the lower sheet 10 is an example of a first sheet. The lower sheet 10 includes a first lower sheet surface 10a disposed opposite to the wick sheet 30 and a second lower sheet surface 10b disposed opposite to the first lower sheet surface 10a. The second lower sheet surface 10b is located closer to the wick sheet 30. In this embodiment, the second lower sheet surface 10b is in contact with a first body surface 30a of the wick sheet 30, described below. As shown in FIG. 4, the lower sheet 10 may have alignment holes 12 at the four corners. The electronic device D, described above, may be attached to the first lower sheet surface 10a.

As shown in FIG. 3, the upper sheet 20 is an example of a second sheet. The upper sheet 20 includes a first upper sheet surface 20a disposed closer to the wick sheet 30 and a second upper sheet surface 20b disposed opposite to the first upper sheet surface 20a. In this embodiment, the first upper sheet surface 20a is in contact with a second body surface 30b of the wick sheet 30, described later. As shown in FIG. 5, the upper sheet 20 may have alignment holes 22 at the four corners. A housing member Ha that constitutes part of the housing H, described above, may be attached to the second upper sheet surface 20b. The entire second upper sheet surface 20b may be covered with the housing member Ha.

As shown in FIG. 3, the wick sheet 30 is an example of the body sheet. The wick sheet 30 includes the first body surface 30a and the second body surface 30b disposed opposite to the first body surface 30a. The first body surface 30a is disposed closer to the lower sheet 10, and the lower sheet 10 is disposed on the first body surface 30a. The second body surface 30b is disposed closer to the upper sheet 20, and the upper sheet 20 is disposed on the second body surface 30b.

The second lower sheet surface 10b of the lower sheet 10 and the first body surface 30a of the wick sheet 30 may be permanently bonded to each other using diffusion bonding. Likewise, the first upper sheet surface 20a of the upper sheet 20 and the second body surface 30b of the wick sheet 30 may be permanently bonded to each other using diffusion bonding. The lower sheet 10, the upper sheet 20, and the wick sheet 30 may be bonded together, not using the diffusion bonding, but using any other method for permanent bonding, such as blazing. The term “permanent bonding” is not limited to a strict meaning but may be used as a term that means that the bonding of the lower sheet 10 and the wick sheet 30 can be maintained to a degree that the sealing performance of the sealed space 3 can be maintained while the vapor chamber 1 is in operation. The term “permanent bonding” may be used as a term that means that the upper sheet 20 and the wick sheet 30 are bonded together to a degree that the bonding can be maintained.

As shown in FIGS. 3, 6, and 7, the wick sheet 30 according to this embodiment includes a frame 32 shaped like a rectangular frame in plan view and a plurality of lands 33 provided in the frame 32. The frame 32 and the lands 33 extend from the first body surface 30a to the second body surface 30b. The frame 32 and the lands 33 are portions of the material of the wick sheet 30 left without being etched in an etching process, described later. In this embodiment, the frame 32 is shaped like a rectangular frame in plan view. The vapor channel portion 50 is defined in the frame 32. The vapor channel portion 50 is disposed around the individual lands 33 in the frame 32. The working vapor 2a flows around the individual lands 33. The vapor channel portion 50 is defined between the frame 32 and the lands 33 in such a manner as to be defined between a pair of adjacent lands 33.

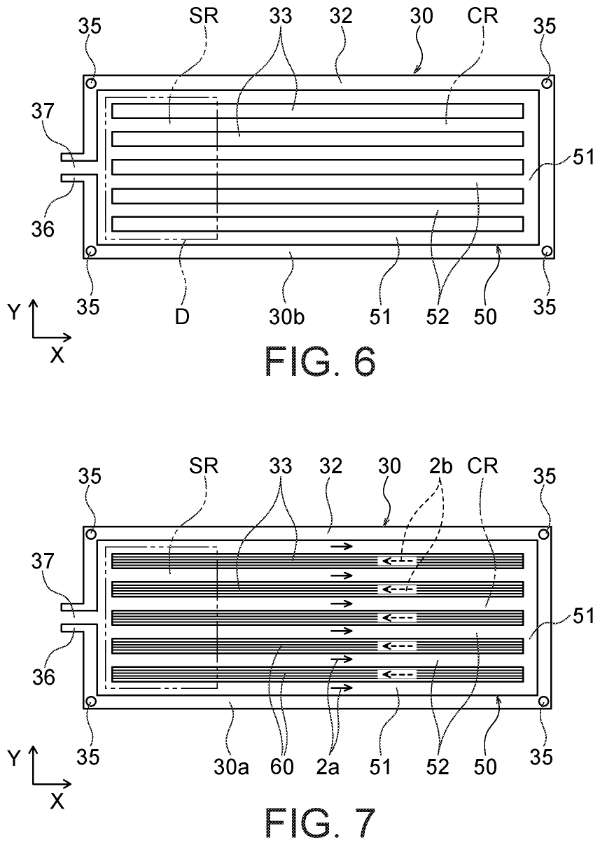

In this embodiment, the lands 33 may extend in an elongated manner in plan view, with the X-direction as the longitudinal direction. The lands 33 may have an elongated rectangular shape in plan view. The lands 33 may be disposed parallel to each other at regular intervals in the Y-direction. The working vapor 2a flows around the individual lands 33 and is conveyed to the condensation region CR. This eliminates or reduces obstruction to the flow of the working vapor 2a. In this embodiment, the X-direction is an example of a first direction, which corresponds to the lateral direction in FIG. 6. The Y-direction is an example of a second direction, which corresponds to the vertical direction in FIG. 6. The X-direction is taken as the longitudinal direction of the lands 33, and the Y-direction is taken as the direction perpendicular to the X-direction in plan view. The direction perpendicular to the X-direction and the Y-direction is taken as the Z-direction.

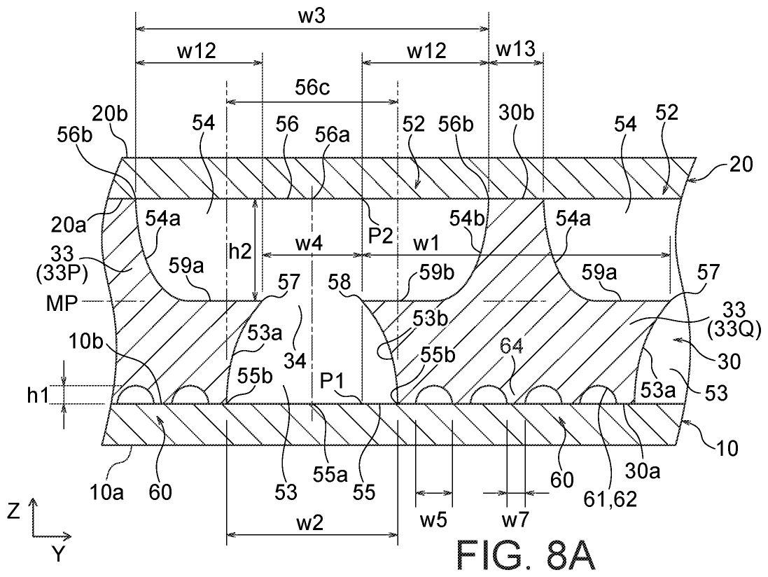

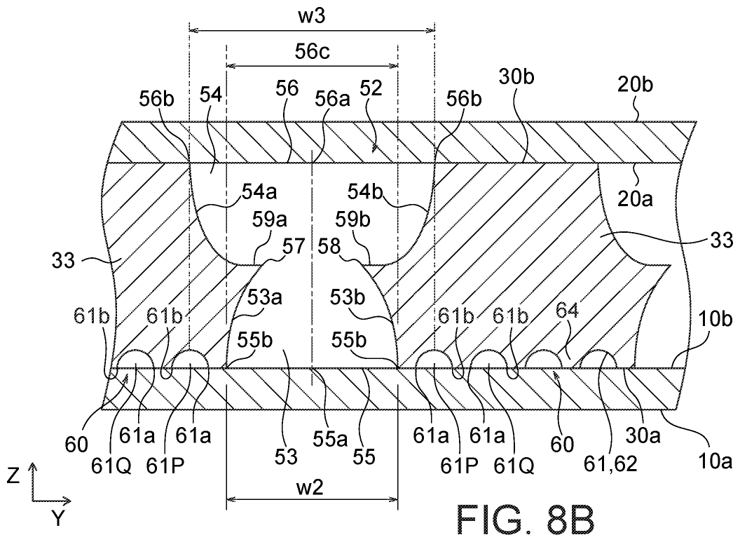

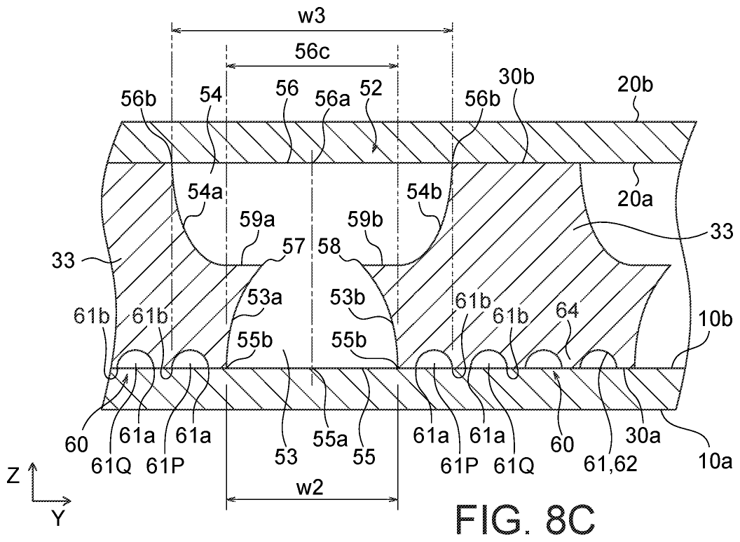

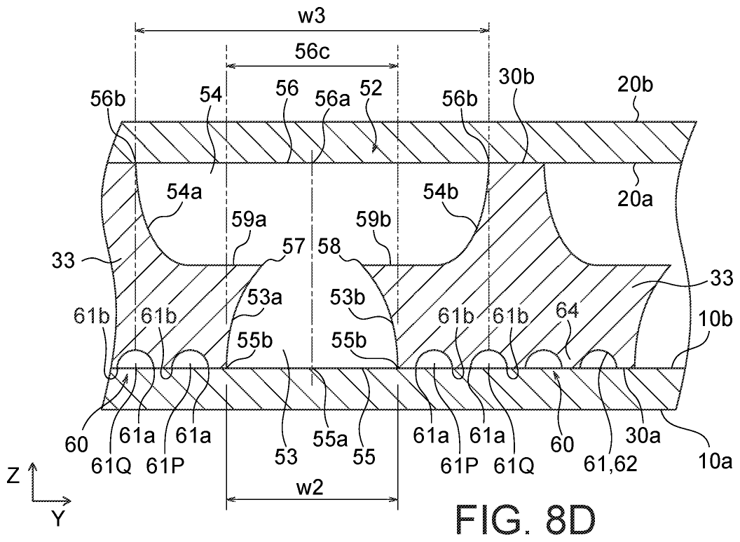

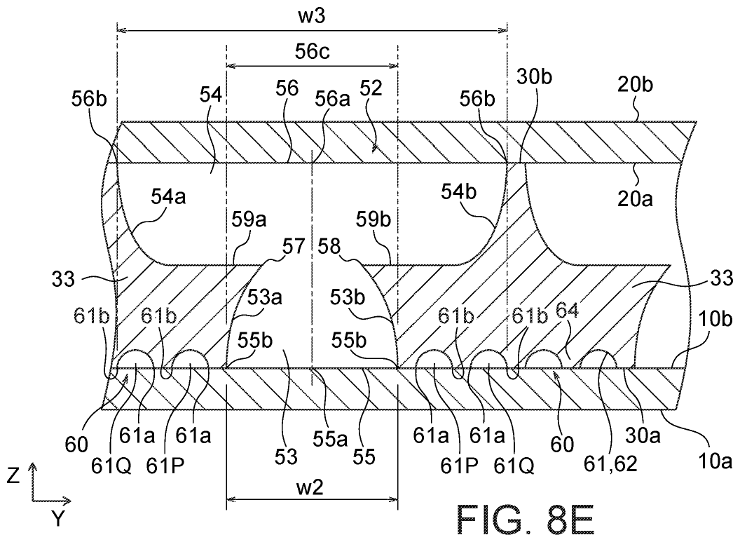

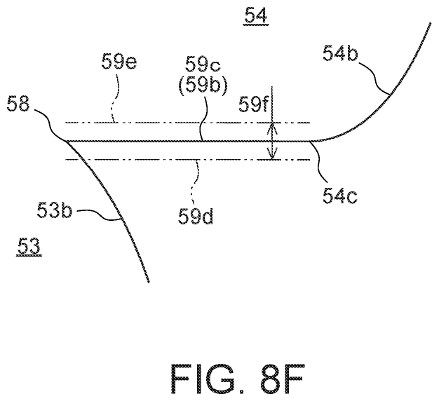

The width w1 of each land 33 (see FIG. 8A) may be, for example, from 100 μm to 3,000 μm. The width w1 of the land 33 is the dimension of the land 33 in the Y-direction. The width w1 of the land 33, which will be described in detail with reference to wall-surface protrusions 57 and 58 described below, is the distance between the end of the first wall-surface protrusion 57 and the end of the second wall-surface protrusion 58, which define the land 33, in the Y-direction.

The frame 32 and the lands 33 are bonded to the lower sheet 10 and the upper sheet 20 using diffusion bonding. This increases the mechanical strength of the vapor chamber 1. Lower wall surfaces 53a and 53b of a lower vapor channel depressed portion 53 and upper wall surfaces 54a and 54b of an upper vapor channel depressed portion 54, described below, constitute the side walls of the land 33. The first body surface 30a and the second body surface 30b of the wick sheet 30 may be formed in flat shape across the frame 32 and the lands 33.

The vapor channel portion 50 is an example of a penetration space. The vapor channel portion 50 may be provided on the first body surface 30a of the wick sheet 30. The vapor channel portion 50 may be a channel that allows mainly the working vapor 2a to pass through. The vapor channel portion 50 may also allow the working liquid 2b to pass through. In this embodiment, the vapor channel portion 50 extends from the first body surface 30a to the second body surface 30b to penetrate the wick sheet 30. The vapor channel portion 50 may be covered with the lower sheet 10 on the first body surface 30a and may be covered with the upper sheet 20 on the second body surface 30b.

As shown in FIGS. 6 and 7, the vapor channel portion 50 of this embodiment includes a first vapor passage 51 and a plurality of second vapor passages 52. The first vapor passage 51 includes a portion extending in the X-direction and a portion extending in the Y-direction in plan view and is formed between the frame 32 and the lands 33. The first vapor passage 51 is continuously formed inside the frame 32 and outside the lands 33. The first vapor passage 51 has a rectangular frame shape in plan view. The second vapor passages 52 extend in the X-direction in plan view between the adjacent lands 33. The second vapor passages 52 has an elongated rectangular shape in plan view. The vapor channel portion 50 is divided into the first vapor passage 51 and the plurality of second vapor passages 52 by the plurality of lands 33.

As shown in FIG. 8A, the first vapor passage 51 and the second vapor passages 52 extend from the first body surface 30a to the second body surface 30b of the wick sheet 30. The first vapor passage 51 and the second vapor passages 52 each include a lower vapor channel depressed portion 53, an upper vapor channel depressed portion 54, a lower opening 55 and an upper opening 56. The lower vapor channel depressed portion 53 is an example of a first space depressed portion, which is provided on the first body surface 30a. The upper vapor channel depressed portion 54 is an example of a second space depressed portion, which is provided on the second body surface 30b. The lower vapor channel depressed portion 53 and the upper vapor channel depressed portion 54 communicate with each other so that the first vapor passage 51 and the second vapor passages 52 of the vapor channel portion 50 extend from the first body surface 30a to the second body surface 30b. The lower opening 55 is an example of a first opening, which is located on the first body surface 30a. The lower opening 55 is defined by the lower vapor channel depressed portion 53 on the first body surface 30a. The upper opening 56 is an example of a second opening, which is located on the second body surface 30b. The upper opening 56 is defined by the upper vapor channel depressed portion 54 on the second body surface 30b.

The lower vapor channel depressed portion 53 is formed into a concave shape on the first body surface 30a by etching the first body surface 30a of the wick sheet 30 in the etching process, described below. This provides the lower vapor channel depressed portion 53 with a pair of curved lower wall surfaces 53a and 53b, as shown in FIG. 8A. The lower wall surfaces 53a and 53b are one example of a first wall surface. The lower wall surface 53a is the left-hand wall surface in FIG. 8A, and the lower wall surface 53b is the right-hand wall surface in FIG. 8A. The lower wall surface 53a and the lower wall surface 53b extend from the lower opening 55 toward the second body surface 30b. The lower wall surfaces 53a and 53b may be curved in a concave shape. The lower wall surfaces 53a and 53b may define the lower vapor channel depressed portion 53 and may be curved so as to decrease in distance from the opposing lower wall surfaces 53a and 53b with a decreasing distance to the second body surface 30b in the cross section shown in FIG. 8A. The lower vapor channel depressed portion 53 constitutes part of the first vapor passage 51 and part of the second vapor passages 52. The lower vapor channel depressed portion 53 may constitute the lower half of the first vapor passage 51 and the lower half of the second vapor passages 52.

The width w2 of the lower opening 55 may be, for example, from 100 μm to 3,000 μm. The width w2 of the lower opening 55 indicates the width of the lower vapor channel depressed portion 53 on the first body surface 30a. The width w2 corresponds to the Y-directional dimension of a portion of the first vapor passage 51 extending in the X-direction and the Y-directional dimension of the second vapor passages 52. In this embodiment, the Y-directional dimension between the lower wall surface 53a and the lower wall surface 53b of the lower vapor channel depressed portion 53 increases gradually from the second body surface 30b toward the first body surface 30a and becomes the maximum at the first body surface 30a. The width w2 is therefore the maximum value of the Y-directional dimension between the lower wall surface 53a and the lower wall surface 53b. However, the Y-directional dimension between the lower wall surface 53a and the lower wall surface 53b does not have to be the maximum on the first body surface 30a. For example, the Y-directional dimension between the lower wall surface 53a and the lower wall surface 53b may be the maximum at a position nearer to the second body surface 30b than the first body surface 30a. The width w2 also corresponds to the X-directional dimension of a portion of the first vapor passage 51 extending in the Y-direction.

The upper vapor channel depressed portion 54 is formed into a concave shape on the second body surface 30b by etching the second body surface 30b of the wick sheet 30 in the etching process, described below. This provides the upper vapor channel depressed portion 54 with a pair of curved upper wall surfaces 54a and 54b, as shown in FIG. 8A. The upper wall surfaces 54a and 54b are one example of a second wall surface. The upper wall surface 54a is the left-hand wall surface in FIG. 8A, and the upper wall surface 54b is the right-hand wall surface in FIG. 8A. The upper wall surface 54a and the upper wall surface 54b extend from the upper opening 56 toward the first body surface 30a. The upper wall surfaces 54a and 54b may be curved in a concave shape. The upper wall surfaces 54a and 54b may define the upper vapor channel depressed portion 54 and may be curved so as to decrease in distance from the opposing upper wall surfaces 54a and 54b with a decreasing distance to the first body surface 30a in the cross section shown in FIG. 8A. The upper vapor channel depressed portion 54 constitutes part of the first vapor passage 51 and part of the second vapor passages 52. The upper vapor channel depressed portion 54 may constitute the upper half of the first vapor passage 51 and the upper half of the second vapor passages 52.

The width w3 of the upper opening 56 may be larger than the width w2 of the lower opening 55. The width w3 may be, for example, from 160 μm to 5,800 μm. The width w3 of the upper opening 56 indicates the width of the upper vapor channel depressed portion 54 on the second body surface 30b. The width w3 corresponds to the Y-directional dimension of a portion of the first vapor passage 51 extending in the X-direction and the Y-directional dimension of the second vapor passages 52. In this embodiment, the Y-directional dimension between the upper wall surface 54a and the upper wall surface 54b increases gradually from the first body surface 30a toward the second body surface 30b and becomes the maximum at the second body surface 30b. The width w3 is therefore the maximum value of the Y-directional dimension between the upper wall surface 54a and the upper wall surface 54b. However, the Y-directional dimension between the upper wall surface 54a and the upper wall surface 54b does not have to be the maximum on the second body surface 30b. For example, the Y-directional dimension between the upper wall surface 54a and the upper wall surface 54b may be the maximum at a position nearer to the first body surface 30a than the second body surface 30b. The width w3 also corresponds to the X-directional dimension of a portion of the first vapor passage 51 extending in the Y-direction.

As shown in FIG. 8A, the center 55a of the lower opening 55 may be overlapping with the center 56a of the upper opening 56 in plan view. Alternatively, the center 55a of the lower opening 55 may be out of alignment with the center 56a of the upper opening 56.

The lower opening 55 may be defined by a pair of lower opening side edges 55b extending in the X-direction. Each of the lower opening side edges 55b is an example of a first opening side edge. The center 55a of the lower opening 55 may be the midpoint of the pair of lower opening side edges 55b as seen in a cross section perpendicular to the X-direction. In FIG. 8A, the lower opening side edges 55b are the points of intersection of the first body surface 30a and the lower wall surfaces 53a and 53b. The midpoint of the points of intersection may be the center 55a of the lower opening 55.

The upper opening 56 may be defined by a pair of upper opening side edges 56b extending in the X-direction. Each of the upper opening side edges 56b is an example of a second opening side edge. The center 56a of the upper opening 56 may be the midpoint of the pair of upper opening side edges 56b as seen in a cross section perpendicular to the X-direction. In FIG. 8A, the upper opening side edges 56b are the points of intersection of the second body surface 30b and the upper wall surfaces 54a and 54b. The midpoint of the points of intersection may be the center 56a of the upper opening 56.

The width w3 of the upper opening 56 may be larger than the width w2 of the lower opening 55, as described above. The upper opening 56 may extend from a region 56c overlapping with the lower opening 55 in plan view to a position overlapping with main channel grooves 61, described below, in plan view. This can make the channel cross-sectional area of the upper vapor channel depressed portion 54 larger than that of the lower vapor channel depressed portion 53. Here, the point of intersection at which the straight line extending through the second wall-surface protrusion 58 in the Z-direction intersects the second lower sheet surface 10b is denoted by P1, as shown in FIG. 8A. The region defined by the point of intersection P1, the lower opening side edge 55b, the lower wall surface 53b, and the second wall-surface protrusion 58 is referred to as a lower vapor channel partial region. The point of intersection at which the straight line extending in through the second wall-surface protrusion 58 in the Z-direction intersects the first upper sheet surface 20a is denoted by P2. The region defined by the point of intersection P2, the upper opening side edge 56b, the upper wall surface 54b, and the second wall-surface protrusion 58 is referred to as an upper vapor channel partial region. Since the upper vapor channel partial region has a channel cross-sectional area larger than that of the lower vapor channel partial region, the capillary action of the upper vapor channel partial region is smaller than the capillary action of the lower vapor channel partial region. This allows the upper vapor channel partial region to reduce the channel resistance of the working vapor 2a in the upper vapor channel partial region to easily diffuse the working vapor 2a, thereby increasing the heat radiation efficiency. The same also applies to the region defined by the lower wall surface 53a and the upper wall surface 54a. The land 33 bonded to the upper sheet 20 is formed between the upper openings 56 adjacent in the Y-direction. This can enhance the mechanical strength of the vapor chamber 1. Thus, the vapor chamber 1 of this embodiment increases the heat radiation efficiency while making efficient use of the limited space and providing sufficient mechanical strength.

Part of the upper opening 56 may be overlapping with part of the main channel grooves 61 next to the vapor passages 51 and 52 in plan view. Part of the upper opening 56 may be overlapping with a plurality of main channel grooves 61 in plan view. Any number of main channel grooves 61 may be overlapping with the upper opening 56.

Examples of the positional relationship between the upper opening 56 and the main channel grooves 61 will be described with reference to FIGS. 8B to 8E. Here, a main channel groove 61 next to the second vapor passage 52 constituted by one upper opening 56 is referred to as a main channel groove 61P, and another main channel groove 61 next to the main channel groove 61P is referred to as a main channel groove 61Q. The main channel groove 61Q is positioned farther from the center 55a of the lower opening 55 than the main channel groove 61P. In other words, the main channel groove 61Q is farther from the center 56a of the upper opening 56 than the main channel groove 61P. In this embodiment, the center 55a of the lower opening 55 is overlapping with the center 56a of the upper opening 56 in plan view. Here, the positional relationship between the upper opening 56 and the main channel grooves 61 will be described using the center 55a of the lower opening 55.

The main channel grooves 61P and 61Q each include a first main channel groove side edge 61a and a second main channel groove side edge 61b extending in the X-direction. FIGS. 8B to 8E show the first main channel groove side edge 61a and the second main channel groove side edge 61b as the point of intersection of the first body surface 30a and a wall surface 62, described later. The first main channel groove side edge 61a is positioned nearer to the center 55a of the lower opening 55 than the second main channel groove side edge 61b, and the second main channel groove side edge 61b is positioned farther from the center 55a of the lower opening 55 than the first main channel groove side edge 61a.

For example, as shown in FIG. 8B, the upper opening 56 may extend to a position overlapping with part of the main channel groove 61P in Y-direction. In this case, the upper opening side edge 56b may be positioned nearer to the center 55a of the lower opening 55 than the second main channel groove side edge 61b of the main channel groove 61P in plan view.

Alternatively, as shown in FIG. 8C, the upper opening 56 may extend to a position overlapping with the whole of the main channel groove 61P next to the second vapor passage 52 in the Y-direction. In this case, the upper opening side edge 56b may be positioned at a position overlapping with the second main channel groove side edge 61b of the main channel groove 61P in plan view or may be positioned farther from the center 55a of the lower opening 55 than the second main channel groove side edge 61b of the main channel groove 61P. Alternatively, the upper opening side edge 56b may be positioned at a position overlapping with the first main channel groove side edge 61a of the main channel groove 61Q in plan view.

Alternatively, as shown in FIG. 8D, the upper opening 56 may extend to a position overlapping with part of the main channel groove 61Q in the Y-direction. In this case, the upper opening side edge 56b may be positioned farther from the center 55a of the lower opening 55 than the first main channel groove side edge 61a of the main channel groove 61Q in plan view or may be positioned nearer to the center 55a of the lower opening 55 than the second main channel groove side edge 61b of the main channel groove 61Q.

Alternatively, as shown in FIG. 8E, the upper opening 56 may extend to a position overlapping with the whole of the main channel groove 61Q in the Y-direction. In this case, the upper opening side edge 56b may be positioned at a position overlapping with the second main channel groove side edge 61b of the main channel groove 61Q in plan view or may be positioned farther from the center 55a of the lower opening 55 than the second main channel groove side edge 61b of the main channel groove 61Q.

That is an example of the positional relationship between the upper opening 56 and the main channel grooves 61 adjacent to the second vapor passage 52 constituted by the upper opening 56. The same also applies to the positional relationship between the upper opening 56 and the main channel grooves 61 adjacent to the first vapor passage 51 formed of the upper opening 56.

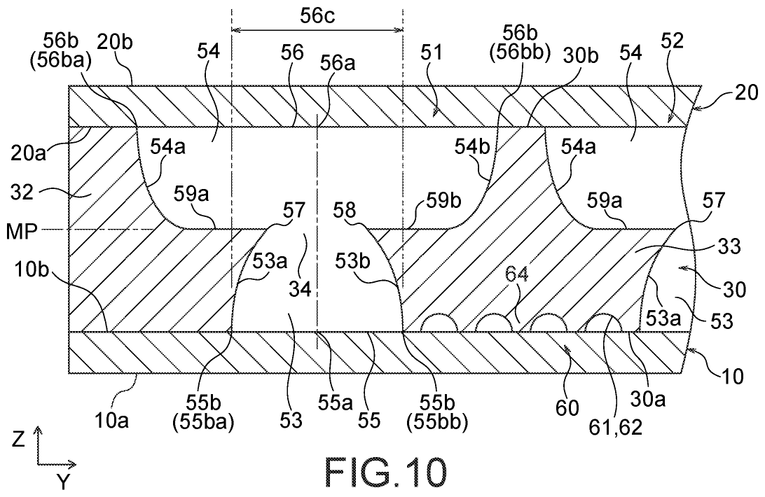

As shown in FIG. 10, as seen in a cross section perpendicular to the X-direction, the upper opening 56 of the first vapor passage 51 may extend from a region 56c overlapping with the lower opening 55 in plan view toward the outside of the frame 32 with respect to the lower opening 55. The lower opening 55 and the upper opening 56 of the first vapor passage 51 are positioned between the frame 32 and the land 33 adjacent to the frame 32. Here, the upper opening 56 at a portion of the first vapor passage 51 extending in the X-direction will be described. The width of the upper opening 56 may be larger than the width of the lower opening 55 also at a portion of the first vapor passage 51 extending in the Y-direction.

More specifically, assuming that the pair of lower opening side edges 55b is constituted by a first lower opening side edge 55ba and a second lower opening side edge 55bb, the first lower opening side edge 55ba defines the boundary between the frame 32 and the lower opening 55, and the second lower opening side edge 55bb defines the boundary between the lands 33 and the lower opening 55. Assuming that the pair of upper opening side edges 56b is constituted by a first upper opening side edge 56ba and a second upper opening side edge 56bb, the first upper opening side edge 56ba defines the boundary between the frame 32 and the upper opening 56, and the second upper opening side edge 56bb defines the boundary between the lands 33 and the upper opening 56.

The first upper opening side edge 56ba is positioned nearer to the outside of the frame 32 than the first lower opening side edge 55ba. In the example shown in FIG. 10, the first upper opening side edge 56ba is positioned on the left of the first lower opening side edge 55ba.

In a cross section perpendicular to the X-direction, the upper opening 56 of the first vapor passage 51 may extend from the region 56c to a position overlapping with the lower opening 55 in plan view to a position overlapping with the main channel grooves 61 positioned in the lands 33 in plan view. The second upper opening side edge 56bb is positioned at a position overlapping with the liquid channel portion 60 positioned in the land 33. In the example shown in FIG. 10, the second upper opening side edge 56bb is positioned on the right side of the second lower opening side edge 55bb.

In a cross section perpendicular to the X-direction as shown in FIG. 8A, the upper opening 56 of the second vapor passage 52 may extend from the region 56c overlapping with the lower opening 55 in plan view to a position overlapping with the main channel grooves 61 in the land 33 in plan view. The upper opening 56 of the second vapor passage 52 may extend from the region 56c overlapping with the lower opening 55 in plan view to positions overlapping with the main channel grooves 61 in plan view on both sides of the lower opening 55.

More specifically, assuming that the second vapor passage 52 is positioned between a first land 33P and a second land 33Q adjacent to each other, the lower opening 55 and the upper opening 56 are positioned between the first land 33P and the second land 33Q.

In a cross section perpendicular to the X-direction, the upper opening 56 of the second vapor passage 52 may extend from a position overlapping with the main channel grooves 61 in the first land 33P in plan view to a position overlapping with the main channel grooves 61 in the second land 33Q in plan view. The upper opening side edges 56b are positioned at positions overlapping with the liquid channel portions 60 of the corresponding lands 33P and 33Q. In the example shown in FIG. 8A, the left-hand upper opening side edge 56b is positioned on the left side of the left-hand lower opening side edge 55b. The right-hand upper opening side edge 56b is positioned on the right side of the right-hand lower opening side edge 55b.

As shown in FIG. 8A, the distances from the wall-surface protrusions 57 and 58 to the corresponding upper opening side edges 56b are expressed as w12. The value w12 may be, for example, from 30 μm to 1,400 μm. The distance w12 indicates the planar distance from the first wall-surface protrusion 57 to the upper opening side edge 56b on the left side as seen in a cross section perpendicular to the X-direction and also the planar distance from the second wall-surface protrusion 58 to the upper opening side edge 56b on the right side. The distance w12 corresponds to the Y-directional dimension.

As shown in FIG. 8A, the width of the land 33 in the second body surface 30b is expressed as w13. The value w13 may be, for example, from 30 μm to 2,900 μm. The width w13 indicates the distance from the upper opening side edge 56b, which defines one upper opening 56, to the upper opening side edge 56b, which defines the other upper opening 56, as seen in a cross section perpendicular to the X-direction. The width w13 corresponds to the Y-directional dimension.

As shown in FIG. 8A, the lower wall surfaces 53a and 53b of the lower vapor channel depressed portion 53 and the corresponding upper wall surfaces 54a and 54b of the upper vapor channel depressed portion 54 are connected together with the wall-surface protrusions 57 and 58, respectively. More specifically, the lower wall surface 53a of the lower vapor channel depressed portion 53 and the corresponding upper wall surface 54a of the upper vapor channel depressed portion 54 are connected together with the first wall-surface protrusion 57. The lower wall surface 53b of the lower vapor channel depressed portion 53 and the corresponding upper wall surface 54b of the upper vapor channel depressed portion 54 are connected together with the second wall-surface protrusion 58. The first wall-surface protrusion 57 is the wall-surface protrusion on the left side in FIG. 8A, and the second wall-surface protrusion 58 is the wall-surface protrusion on the right side in FIG. 8A.

As shown in FIG. 8A, the first wall-surface protrusion 57 may protrude toward the inside of the vapor passages 51 and 52. The second wall-surface protrusion 58 may protrude toward the inside of the vapor passages 51 and 52. In this embodiment, the pair of wall-surface protrusions 57 and 58 protrude in the direction along the first body surface 30a and the second body surface 30b so as to face each other.

In this embodiment, the first wall-surface protrusion 57 is disposed at an intermediate position MP between the first body surface 30a and the second body surface 30b in the Z-direction. However, the embodiment is not limited thereto. The first wall-surface protrusion 57 may be disposed out of alignment with the intermediate position MP. In the example shown in FIG. 8A, the first wall-surface protrusion 57 is disposed at the same position as that of the second wall-surface protrusion 58 in the Z-direction. However, the embodiment is not limited thereto. The first wall-surface protrusion 57 may be disposed out of alignment with the second wall-surface protrusion 58 in the Z-direction.

Similarly, in this embodiment, the second wall-surface protrusion 58 is disposed at the intermediate position MP between the first body surface 30a and the second body surface 30b in the Z-direction. However, the embodiment is not limited thereto. The second wall-surface protrusion 58 may be disposed out of alignment with the intermediate position MP. In the example shown in FIG. 8A, the second wall-surface protrusion 58 is disposed at the same position as that of the first wall-surface protrusion 57 in the Z-direction. However, the embodiment is not limited thereto. The second wall-surface protrusion 58 may be disposed out of alignment with the first wall-surface protrusion 57 in the Z-direction.

The pair of wall-surface protrusions 57 and 58 defines a through portion 34, where the lower vapor channel depressed portion 53 and the upper vapor channel depressed portion 54 communicate with each other. In this embodiment, the planar shape of the through portion 34 in the first vapor passage 51 is a rectangular frame shape similar to the first vapor passage 51. The planar shape of the through portion 34 in the second vapor passage 52 is an elongated rectangular shape similar to the second vapor passage 52. The width w4 of this through portion 34 (see FIG. 8A) may be, for example, from 200 μm to 500 μm. The width w4 of the through portion 34 corresponds to the gap between the adjacent lands 33 in the Y-direction. In more detail, the width w4 indicates the Y-directional distance between the end of the first wall-surface protrusion 57 and the end of the second wall-surface protrusion 58 which define the through portion 34.

The upper vapor channel depressed portion 54 may include two flat surfaces 59a and 59b as seen in a cross section perpendicular to the X-direction. The flat surfaces 59a and 59b connect the corresponding upper wall surfaces 54a and 54b and the wall-surface protrusions 57 and 58, respectively. The flat surface 59a is the left-hand surface in FIG. 8A, and the flat surface 59b is the right-hand surface in FIG. 8A. More specifically, the upper wall surface 54a is connected to the first wall-surface protrusion 57 via one flat surface 59a, and the flat surface 59a is formed between the upper wall surface 54a and the first wall-surface protrusion 57. The upper wall surface 54b is connected to the second wall-surface protrusion 58 via the other flat surface 59b, and the flat surface 59b is formed between the upper wall surface 54b and the second wall-surface protrusion 58. The flat surfaces 59a and 59b may be along the second body surface 30b as seen in a cross section perpendicular to the X-direction. In this case, the flat surfaces 59a and 59b may be parallel to the second body surface 30b or to the first body surface 30a. Alternatively, the flat surfaces 59a and 59b may be inclined with respect to the second body surface 30b. Both of the two flat surfaces 59a and 59b may be along the second body surface 30b or may be inclined with respect to the second body surface 30b. Alternatively, one of the two flat surfaces 59a and 59b may be along the second body surface 30b, and the other may be inclined with respect to the second body surface 30b.

The flat surfaces 59a and 59b may be flat. For example, as seen in a cross section perpendicular to the X-direction, the flat surfaces 59a and 59b may be formed within a range of less than 3 μm in the direction perpendicular to the flat surfaces 59a and 59b. For example, as seen in a cross section perpendicular to the X-direction, the flat surfaces 59a and 59b may be within a range of less than 3 μm in the direction perpendicular to reference lines connecting the wall-surface protrusions 57 and 58 and end points of the upper wall surfaces 54a and 54b, respectively.

Referring to FIG. 8F, the flat surfaces 59a and 59b will be described in more detail. The flat surface 59b will be representatively described for clarity of the description. The flat surface 59a is similar to the flat surface 59b, and a detailed description will be omitted.

As shown in FIG. 8F, the reference line corresponding to the flat surface 59b is indicated by the line denoted by sign 59c. The reference line 59c may be a straight line connecting the second wall-surface protrusion 58 and an end point 54c of the upper wall surface 54b. The end point 54c may be a point of the upper wall surface 54b closest to the second wall-surface protrusion 58. The flat surface 59b may be formed in a range 59f between a first boundary line 59d and a second boundary line 59e. The first boundary line 59d may be off the reference line 59c in the direction nearer to the first body surface 30a and may be parallel to the reference line 59c. The second boundary line 59e may be off the reference line 59c in the direction nearer to the second body surface 30b and may be parallel to the reference line 59c. The flat surface 59b may be formed in the range 59f between the first boundary line 59d and the second boundary line 59e thus defined.

As shown in FIG. 8F, the reference line 59c may be along the second body surface 30b. In this case, the first boundary line 59d and the second boundary line 59e may also be along the second body surface 30b. However, the embodiment is not limited thereto. The reference line 59c may be inclined with respect to the second body surface 30b. In this case, the first boundary line 59d and the second boundary line 59e may also be inclined with respect to the second body surface 30b.

As shown in FIG. 8F, the distance between the first boundary line 59d and the reference line 59c and the distance between the second boundary line 59e and the reference line 59c may be equal to each other. In this case, the distance between the first boundary line 59d and the reference line 59c may be, for example, less than 1.5 μm. The distance between the second boundary line 59e and the reference line 59c may be, for example, less than 1.5 μm. However, the distance between the first boundary line 59d and the reference line 59c and the distance between the second boundary line 59e and the reference line 59c do not have to be equal to each other. Provided that the distance between the first boundary line 50d and the second boundary line 59e is less than 3.0 μm, the distance between the first boundary line 59d and the reference line 59c and the distance between the second boundary line 59e and the reference line 59c may differ from each other. The first boundary line 59d may be overlapping with the reference line 59c, or alternatively, the second boundary line 59e may be overlapping with the reference line 59c.

As shown in FIG. 8A, the depth of the upper vapor channel depressed portion 54 is indicated by h2. The value of h2 may be, for example, from 20 μm to 250 μm. The depth h2 indicates the distance from the second body surface 30b to the flat surface 59a or 59b as seen in a cross section perpendicular to the X-direction. The depth h2 corresponds to the Z-directional dimension.

The width w3 of the upper opening 56 may be larger than the width w2 of the lower opening 55 across the entire region of the land 33 in the X-direction. This can increase the channel cross-sectional areas of the vapor passages 51 and 52 across the entire region of the land 33 in the X-direction.

The vapor channel portion 50 including the first vapor passage 51 and the second vapor passages 52 with this configuration constitutes part of the sealed space 3 described above. As shown in FIG. 3, the vapor channel portion 50 of this embodiment is defined mainly by the lower sheet 10, the upper sheet 20, and the frame 32 and the lands 33 of the wick sheet 30. The vapor passages 51 and 52 each have a relatively large channel cross-sectional area so as to allow the working vapor 2a to pass through.

FIG. 3 shows the first vapor passage 51 and the second vapor passages 52 in enlarged view for clarification, in which the number and disposition of the vapor passages 51 and 52 differ from those of FIGS. 2, 6, and 7.

The vapor channel portion 50 may have therein a plurality of support portions (not shown) for supporting the lands 33 in the frame 32. Support portions for supporting the adjacent lands 33 may also be provided. These support portions may be disposed on both sides of each land 33 in the X-direction or on both sides of the land 33 in the Y-direction. The support portions may be formed so as not to hamper the flow of the working vapor 2a diffusing in the vapor channel portion 50. For example, the support portions may be disposed closer to one of the first body surface 30a and the second body surface 30b of the wick sheet 30, and a space constituting a vapor channel may be disposed closer to the other. This allows the support portions to be thinner than the wick sheet 30, thereby eliminating or reducing separation of the first vapor passage 51 and the second vapor passages 52 in the X-direction and the Y-direction.

As shown in FIGS. 6 and 7, the wick sheet 30 may have alignment holes 35 at the four corners, like the lower sheet 10 and the upper sheet 20.

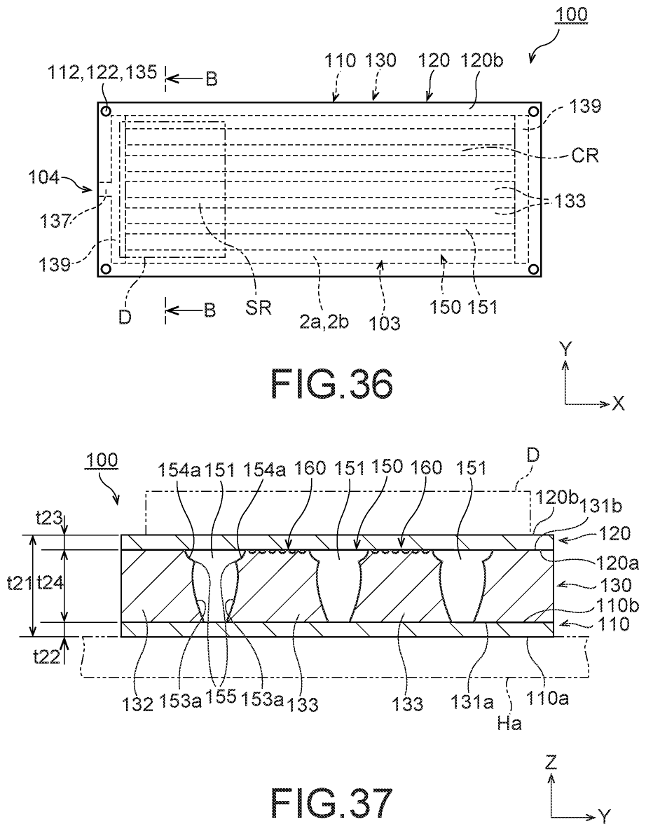

As shown in FIG. 2, the vapor chamber 1 may further include an injecting portion 4 for injecting the working liquid 2b into the sealed space 3 at one end edge in the X-direction. In the configuration shown in FIG. 2, the injecting portion 4 is disposed near the evaporation region SR and protrudes from the edge closer to the evaporation region SR outward from the vapor chamber 1. The injecting portion 4 does not have to protrude outward from the vapor chamber 1, as shown in FIG. 36 and so on described later.

More specifically, the injecting portion 4 may include a lower injecting protrusion 11 (see FIG. 4), an upper injecting protrusion 21 (see FIG. 5), and a wick-sheet injecting protrusion 36 (see FIGS. 6 and 7). The lower injecting protrusion 11 constitutes the lower sheet 10. The upper injecting protrusion 21 constitutes the upper sheet 20. The wick-sheet injecting protrusion 36 constitutes the wick sheet 30. Among them, the wick-sheet injecting protrusion 36 has an injection channel 37 formed therein. The injection channel 37 may extend from the first body surface 30a to the second body surface 30b of the wick sheet 30 and may penetrate the wick-sheet injecting protrusion 36 of the wick sheet 30 in the Z-direction. The injection channel 37 communicates with the vapor channel portion 50. The working liquid 2b is injected into the sealed space 3 through the injection channel 37. Depending on the location of the liquid channel portion 60, the injection channel 37 may communicate with the liquid channel portion 60. The upper surface and the lower surface of the wick-sheet injecting protrusion 36 may be schematically flat. The upper surface of the lower injecting protrusion 11 and the lower surface of the upper injecting protrusion 21 may also be schematically flat. The planar shapes of the injecting protrusions 11, 21, and 36 may be the same.

Although this embodiment shows an example in which the injecting portion 4 is provided at one of a pair of edges of the vapor chamber 1 in the X-direction, the embodiment is not limited thereto. The injecting portion 4 may be disposed at any position. The injection channel 37 in the wick-sheet injecting protrusion 36 does not have to penetrate the wick-sheet injecting protrusion 36 and may be any channel that allows the working liquid 2b to pass through. In this case, the injection channel 37 communicating with the vapor channel portion 50 can be constituted by a depressed portion formed in one of the first body surface 30a and the second body surface 30b of the wick sheet 30.

As shown in FIGS. 3, 8A, and 10, the liquid channel portion 60 may be disposed between the lower sheet 10 and the wick sheet 30. In this embodiment, the liquid channel portion 60 is disposed on the first body surface 30a of the wick sheet 30. The liquid channel portion 60 may be a channel that mainly allows the working liquid 2b to pass through. The liquid channel portion 60 may allow the working vapor 2a to pass through. The liquid channel portion 60 constitutes part of the sealed space 3 and communicates with the vapor channel portion 50. The liquid channel portion 60 has a capillary structure (wick) for conveying the working liquid 2b to the evaporation region SR. In this embodiment, the liquid channel portion 60 is disposed on the first body surface 30a of each land 33 of the wick sheet 30. The liquid channel portion 60 may be formed across the entire first body surface 30a of the land 33. The liquid channel portion 60 may be provided on the second body surface 30b of each land 33 (not shown in FIG. 3 and so on).

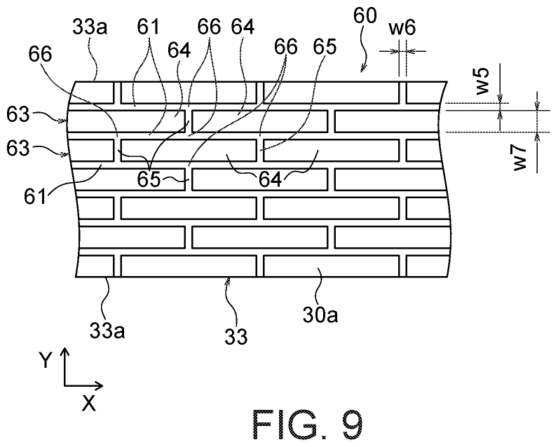

As shown in FIG. 9, the liquid channel portion 60 is an example of a group of grooves including a plurality of grooves. More specifically, the liquid channel portion 60 includes a plurality of main channel grooves 61 that allows the working liquid 2b to pass through and a plurality of communication grooves 65 communicating with the main channel grooves 61. Each of the main channel grooves 61 of the liquid channel portion 60 is an example of a first groove. Each of the communication grooves 65 of the liquid channel portion 60 is an example of a second groove. The main channel grooves 61 and the communication grooves 65 are grooves that allow the working liquid 2b to pass through. The communication grooves 65 communicate with the main channel grooves 61.

The main channel grooves 61 extend in the X-direction, as shown in FIG. 9. The main channel grooves 61 have a channel cross-sectional area smaller than that of the first vapor passages 51 or the second vapor passages 52 of the vapor channel portion 50 so that the working liquid 2b mainly flows by a capillary action. Thus, the main channel grooves 61 are configured to convey the working liquid 2b condensed from the working vapor 2a to the evaporation region SR. The main channel grooves 61 may be disposed at regular intervals along the Y-direction perpendicular to the X-direction.

The main channel grooves 61 are formed by etching the first body surface 30a of the wick sheet 30 in the etching process, described later. As a result, the main channel grooves 61 each have a curved wall surface 62, as shown in FIG. 8A. The wall surface 62 defines the main channel grooves 61 and is curved so as to swell toward the second body surface 30b.

As shown in FIGS. 8A and 9, the width w5 of each main channel groove 61 (the Y-directional dimension) may be, for example, from 5 μm to 400 μm. The width w5 of the main channel groove 61 is the dimension in the first body surface 30a. As shown in FIG. 8A, the depth h1 of the main channel groove 61 (the Z-directional dimension) may be, for example, from 5 μm to 100 μm.

As shown in FIG. 9, the communication grooves 65 extend in a direction different from the X-direction. In this embodiment, the communication grooves 65 extend in the Y-direction at right angles to the main channel grooves 61. Some communication grooves 65 are disposed so as to communicate between the adjacent main channel grooves 61. The other communication grooves 65 are disposed so as to communicate between the vapor channel portion 50 (the first vapor passage 51 or the second vapor passages 52) and the main channel grooves 61. In other words, these communication grooves 65 extend from a side edge 33a of the land 33 in the Y-direction to the main channel groove 61 adjacent to this side edge 33a. Thus, the first vapor passage 51 or the second vapor passages 52 of the vapor channel portion 50 and the main channel grooves 61 communicate with each other.

The communication grooves 65 have a channel cross-sectional area smaller than that of the first vapor passage 51 or the second vapor passages 52 of the vapor channel portion 50 so that the working liquid 2b mainly flows by the capillary action. The communication grooves 65 may be disposed at regular intervals along the X-direction.

The communication grooves 65 are also formed by means of etching, as are the main channel grooves 61, and have a curved wall surface (not shown) similar to the main channel grooves 61. As shown in FIG. 9, the width w6 of each communication groove 65 (the X-directional dimension) may be equal to the width w5 of the main channel groove 61, or may be larger than or smaller than the width w5. The depth of the communication groove 65 may be equal to the depth h1 of the main channel groove 61, or may be larger than or smaller than the depth h1.

As shown in FIG. 9, the liquid channel portion 60 includes protrusion rows 63 on the first body surface 30a of the wick sheet 30. Each protrusion row 63 is disposed between the adjacent main channel grooves 61. Each protrusion row 63 includes a plurality of protrusions 64 (an example of liquid channel protrusions) arrayed in the X-direction. The protrusions 64 are disposed in the liquid channel portion 60 and are in contact with the upper sheet 20. The protrusions 64 are formed in a rectangular shape in plan view so as to be long in the X-direction. The main channel grooves 61 are each interposed between the protrusions 64 adjacent to each other in the Y-direction, and the communication groove 65 is interposed between the protrusions 64 adjacent to each other in the X-direction. The communication grooves 65 extend in the Y-direction and each communicate between the main channel grooves 61 adjacent in the Y-direction. This allows the working liquid 2b to flow back and forth between the main channel grooves 61.

The protrusions 64 are portions of the material of the wick sheet 30 left without being etched in the etching process, described later. The planar shape of each protrusion 64 is the shape at the first body surface 30a of the wick sheet 30 as shown in FIG. 9, which is rectangular in this embodiment.

In this embodiment, the protrusions 64 are disposed in a staggered pattern. More specifically, the protrusions 64 of the protrusion rows 63 adjacent to each other in the Y-direction are staggered in the X-direction. The amount of stagger may be half of the arrangement pitch of the protrusions 64 in the X-direction. The width w7 (the Y-directional dimension) of each protrusion 64 may be, for example, from 5 μm to 500 μm. The width w7 of the protrusion 64 is the dimension in the first body surface 30a. The protrusions 64 do not have to be disposed in the staggered pattern and may be disposed in parallel. In this case, the protrusions 64 of the protrusion rows 63 adjacent to each other in the Y-direction are arrayed also in the Y-direction.

The main channel groove 61 each includes an intersecting portion 66 communicating with the communication groove 65. At the intersecting portion 66, the main channel groove 61 and the communication groove 65 communicate in T-shape. This can eliminate or reduce, at the intersecting portion 66 at which one main channel groove 61 and the communication groove 65 on one side (for example, the upper side in FIG. 9) communicate, communication between the communication groove 65 on the other side (for example, the lower side in FIG. 9) and the main channel groove 61.

In other words, in the case where the communication grooves 65 on both sides (the upper and lower sides in FIG. 9) of one main channel groove 61 in the Y-direction are disposed on the same positions in the X-direction, the main channel grooves 61 and the communication grooves 65 intersect in the form of a cross. In this case, the wall surface 62 of the main channel groove 61 (see FIG. 8A) is notched on both sides (the upper and lower sides in FIG. 9) by the communication grooves 65 at the same position in the X-direction. At the notch position, a cross-shaped continuous space is formed, which can reduce the capillary action of the main channel groove 61.

In contrast, in this embodiment, the communication grooves 65 on both sides (the upper and lower sides in FIG. 9) in the Y-direction of one main channel groove 61 are disposed at different positions in the X-direction. This allows, of the wall surface 62 of the main channel groove 61, the position at which the wall surface 62 is notched by the communication groove 65 on one side in the Y-direction and the position at which the wall surface 62 is notched by the communication groove 65 on the other side in the Y-direction to be made different in the X-direction. In this case, since the main channel groove 61 communicates with the communication groove 65 on one side in the Y-direction, the wall surface 62 of the main channel groove 61 can be left on the other side in the Y-direction. As a result, a continuous space is formed in T-shape at the position where the wall surface 62 of the main channel grooves 61 is notched by the communication groove 65, which can eliminate or reduce reduction in the capillary action of the main channel groove 61. This can therefore eliminate or reduce a decrease in the propulsive force of the working liquid 2b toward the evaporation region SR at the intersecting portion 66.

The lower sheet 10, the upper sheet 20, and the wick sheet 30 may be made of any materials having high thermal conductivity to the extent that the vapor chamber 1 is given sufficient heat radiation efficiency. Examples of the materials for the sheets 10, 20, and 30 include copper and copper alloys having high thermal conductivity and corrosion resistance in the case where pure water is used as the working fluid. Examples of the copper include pure copper and oxygen free copper (C1020). Examples of the copper alloys include copper alloys containing tin, copper alloys containing titanium (for example, C1990), and Corson copper alloys (for example, C7025), which are copper alloys containing nickel, silicon, and magnesium. One example of the copper alloys containing tin is phosphor bronze (for example, C5210).

The thickness t1 of the vapor chamber 1 shown in FIG. 3 may be, for example, from 100 μm to 500 μm. Setting the thickness t1 of the vapor chamber 1 to 100 μm or more allows the vapor channel portion 50 to be appropriately held, enabling the vapor chamber 1 to function properly. In contrast, setting the thickness t1 to 500 μm or less can eliminate or reduce an increase in the thickness t1 of the vapor chamber 1.

The wick sheet 30 may be thicker than the lower sheet 10. Similarly, the wick sheet 30 may be thicker than the upper sheet 20. Although this embodiment shows an example in which the lower sheet 10 and the upper sheet 20 have an equal thickness, the embodiment is not limited thereto. The lower sheet 10 and the upper sheet 20 may have different thicknesses.

The thickness t2 of the lower sheet 10 may be, for example, from 6 μm to 100 μm. Setting the thickness t2 of the lower sheet 10 to 6 μm or more can enhance the mechanical strength and long-term reliability of the lower sheet 10. In contrast, setting the thickness t2 of the lower sheet 10 to 100 μm or less can eliminate or reduce an increase in the thickness t1 of the vapor chamber 1. Similarly, the thickness t3 of the upper sheet 20 may be set as is the thickness t2 of the lower sheet 10.

The thickness t4 of the wick sheet 30 may be, for example, from 50 μm to 300 μm. Setting the thickness t4 of the wick sheet 30 to 50 μm or more allows the vapor channel portion 50 to be appropriately held, thereby enabling the vapor chamber 1 to function properly. In contrast, setting the thickness t4 to 300 μm or less can eliminate or reduce an increase in the thickness t1 of the vapor chamber 1. The thickness t4 of the wick sheet 30 may be the distance between the first body surface 30a and the second body surface 30b.

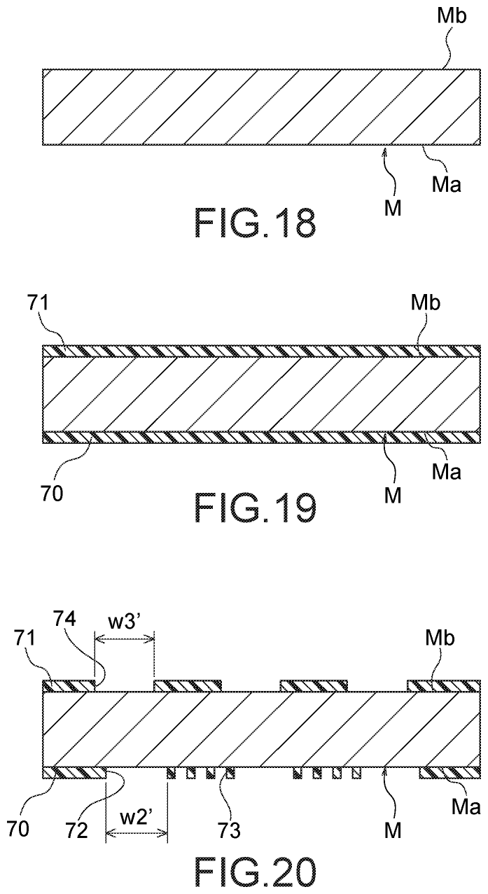

The vapor chamber 1 with such a configuration according to this embodiment can be produced with reference to a production method described with reference to FIGS. 18 to 23, described later. The flat surfaces 59a and 59b of the upper vapor channel depressed portion 54 can easily be formed by adjusting etching conditions, such as the shape of the resist, the etchant flow method, and the etching time.

Next, a method for operating the vapor chamber 1, that is, a method for cooling the electronic device D, will be described.

The vapor chamber 1 obtained as described above is installed in the housing H of a mobile terminal or the like, and the housing member Ha is mounted on the second upper sheet surface 20b of the upper sheet 20. Alternatively, the vapor chamber 1 is mounted on the housing member Ha. The electronic device D, which is the device to be cooled, such as a CPU, is mounted on the first lower sheet surface 10a of the lower sheet 10. Alternatively, the vapor chamber 1 is mounted on the electronic device D. The working liquid 2b in the sealed space 3 is attached to the wall surface of the sealed space 3 by its surface tension. More specifically, the working liquid 2b is attached to the lower wall surfaces 53a and 53b of the lower vapor channel depressed portion 53, the upper wall surfaces 54a and 54b of the upper vapor channel depressed portion 54, the flat surfaces 59a and 59b, the wall surfaces 62 of the main channel grooves 61, and the wall surfaces of the communication grooves 65. The working liquid 2b can also be attached to a portion of the second lower sheet surface 10b of the lower sheet 10 exposed to the lower vapor channel depressed portion 53. The working liquid 2b can also be attached to portions of the first upper sheet surface 20a of the upper sheet 20 exposed to the upper vapor channel depressed portion 54, the main channel grooves 61, and the communication grooves 65.

When the electronic device D generates heat in this state, the working liquid 2b in the evaporation region SR (see FIGS. 6 and 7) receives the heat from the electronic device D. The received heat is absorbed as latent heat to evaporate (vaporize) the working liquid 2b to generate the working vapor 2a. Most of the generated working vapor 2a diffuses in the first vapor passage 51 and the second vapor passages 52 constituting the sealed space 3 (see the solid arrows in FIG. 7). More specifically, the working vapor 2a diffuses mainly in the X-direction in portions of the first vapor passage 51 extending in the X-direction and in the second vapor passages 52 of the vapor channel portion 50. In contrast, in portions of the first vapor passage 51 extending in the Y-direction, the working vapor 2a diffuses in the Y-direction. In this embodiment, since the upper opening 56 is larger than the lower opening 55, the channel cross-sectional areas of the vapor passages 51 and 52 are large. This reduces the channel resistance of the working vapor 2a, allowing the working vapor 2a to diffuse smoothly.

The working vapor 2a in the vapor passages 51 and 52 is separated from the evaporation region SR, and most of the working vapor 2a is conveyed to the condensation region CR with relatively low-temperature (the right-hand portion in FIGS. 6 and 7). In the condensation region CR, the working vapor 2a radiates heat mainly to the upper sheet 20 and is cooled. The heat that the upper sheet 20 receives from the working vapor 2a is transmitted to the outside air via the housing member Ha (see FIG. 3).

The working vapor 2a radiates heat to the upper sheet 20 in the condensation region CR to thereby lose the latent heat absorbed in the evaporation region SR and is condensed to generate the working liquid 2b. The generated working liquid 2b attaches to the respective wall surfaces 53a, 53b, 54a, and 54b of the vapor channel depressed portions 53 and 54, the flat surfaces 59a and 59b, the second lower sheet surface 10b of the lower sheet 10, and the first upper sheet surface 20a of the upper sheet 20. In the evaporation region SR, the working liquid 2b continues to evaporate. This causes the working liquid 2b in a region of the liquid channel portion 60 other than the evaporation region SR (that is, the condensation region CR) to be conveyed to the evaporation region SR (see the broken line arrows in FIG. 7) owing to the capillary action of the main channel grooves 61. This causes the working liquid 2b attached to the wall surfaces 53a, 53b, 54a, and 54b, the flat surfaces 59a and 59b, the second lower sheet surface 10b, and the first upper sheet surface 20a to move to the liquid channel portion 60 and enter the main channel grooves 61 through the communication grooves 65. Thus, the working liquid 2b is charged into the main channel grooves 61 and the communication grooves 65. Thus, the charged working liquid 2b is given a propulsive force toward the evaporation region SR due to the capillary action of the main channel grooves 61 and is smoothly conveyed to the evaporation region SR.

In the liquid channel portion 60, each main channel groove 61 communicates with the adjacent another main channel grooves 61 via the corresponding communication grooves 65. This allows the working liquid 2b to flow back and forth between the adjacent main channel grooves 61, thereby eliminating or reducing generation of dry-out in the main channel grooves 61. This provides a capillary action to the working liquid 2b in the main channel grooves 61, allowing the working liquid 2b to be smoothly conveyed to the evaporation region SR.

In contrast, the working liquid 2b attached to the respective wall surfaces 53a, 53b, 54a, and 54b and flat surfaces 59a and 59b of the vapor channel depressed portions 53 and 54 can be conveyed to the evaporation region SR also using the capillary action of the vapor channel depressed portions 53 and 54. The vapor channel depressed portions 53 and 54 mainly functions as channels for the working vapor 2a. The working liquid 2b attached to the wall surfaces 53a, 53b, 54a, and 54b and the flat surfaces 59a and 59b can be acted upon by a capillary action.

The working liquid 2b that has reached the evaporation region SR is evaporated by receiving the heat from the electronic device D again. The working vapor 2a evaporated from the working liquid 2b moves to the lower vapor channel depressed portion 53 and the upper vapor channel depressed portion 54 with a large channel cross-sectional area through the communication grooves 65 in the evaporation region SR and diffuses in the vapor channel depressed portions 53 and 54. Thus, the working fluids 2a and 2b reflux in the sealed space 3 while repeating a phase change, that is, evaporation and condensation, to diffuse and radiate the heat of the electronic device D. As a result, the electronic device D is cooled.

According to this embodiment, as seen in a cross section perpendicular to the X-direction, the upper opening 56 in the second body surface 30b extends from the region 56c overlapping with the lower opening 55 in the first body surface 30a in plan view to a position overlapping with the main channel grooves 61 in plan view. This configuration allows the channel cross-sectional areas of the vapor passages 51 and 52 to be increased. This can therefore reduce the channel resistance of the working vapor 2a, allowing the working vapor 2a to be easily diffused. This allows the heat radiation efficiency of the vapor chamber 1 to be increased, thereby increasing the effect of cooling the electronic device D.

According to this embodiment, as seen in a cross section perpendicular to the X-direction, the upper vapor channel depressed portion 54 includes the flat surfaces 59a and 59b that connect the corresponding upper wall surface 54a and the wall-surface protrusions 57 and 58, respectively. The flat surfaces 59a and 59b are formed in a planar shape. This configuration can further reduce the channel resistance of the working vapor 2a, allowing the working vapor 2a to be diffused more easily.

According to this embodiment, as seen in a cross section perpendicular to the X-direction, the upper opening 56 extends from the region 56c overlapping with the lower opening 55 in plan view to positions overlapping with the main channel grooves 61 on both sides of the lower opening 55 in plan view. This can further increase the channel cross-sectional areas of the vapor passages 51 and 52. This allows the channel resistance of the working vapor 2a to be reduce, thereby easily diffusing the working vapor 2a. This allows the heat radiation efficiency of the vapor chamber 1 to be increased, thereby increasing the effect of cooling the electronic device D.

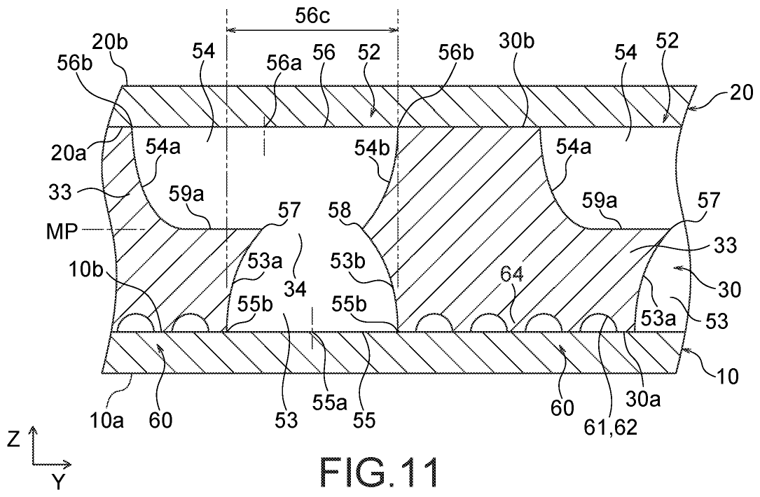

In the embodiment described above, the upper opening 56 extends from the region 56c overlapping with the lower opening 55 in plan view to positions overlapping with the main channel grooves 61 in plan view on both sides of the lower opening 55 as seen in a cross section perpendicular to the X-direction. However, the embodiment is not limited thereto. For example, as shown in FIG. 11, the upper opening 56 may extend from the region 56c overlapping with the lower opening 55 in plan view to a position overlapping with the main channel grooves 61 in plan view on one side of the lower opening 55. The upper opening 56 does not have to extend to a position overlapping with the main channel grooves 61 in plan view on the other side of the lower opening 55. This configuration can also increase the channel cross-sectional areas of the vapor passages 51 and 52. In the example shown in FIG. 11, the upper opening 56 extends to the left side of the lower opening 55. The upper vapor channel depressed portion 54 includes one flat surface 59a as seen in a cross section perpendicular to the X-direction. The flat surface 59a is disposed where the upper opening 56 extends. The flat surface 59a connects one upper wall surface 54a and the first wall-surface protrusion 57. The other upper wall surface 54b and the second wall-surface protrusion 58 are connected not via the flat surface 59b (see FIG. 8A). The upper opening side edge 56b opposite to the flat surface 59a may be positioned at a position overlapping with the corresponding lower opening side edge 55b in plan view. In the example shown in FIG. 11, the center 55a of the lower opening 55 and the center 56a of the upper opening 56 may be out of alignment with each other.

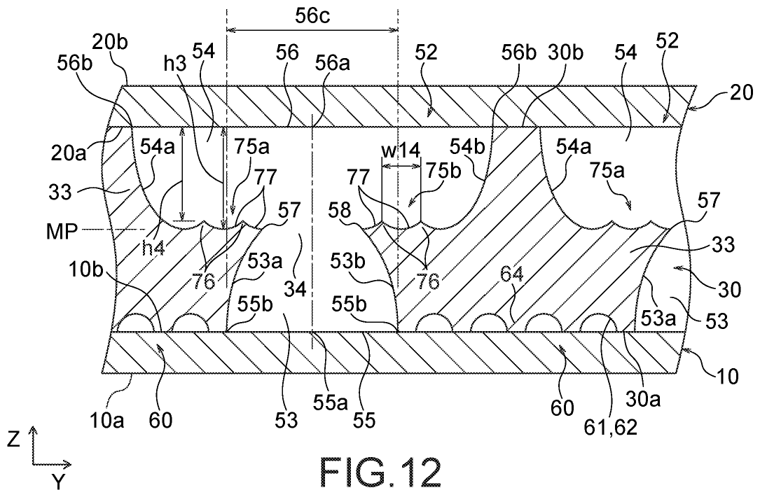

In the embodiment described above, the upper vapor channel depressed portion 54 includes the flat surfaces 59a and 59b as seen in a cross section perpendicular to the X-direction. However, the embodiment is not limited thereto. For example, the upper vapor channel depressed portion 54 may include protruding surfaces 75a and 75b, as shown in FIG. 12. The protruding surfaces 75a and 75b connect the corresponding upper wall surfaces 54a and 54b and wall-surface protrusions 57 and 58, respectively. The protruding surface 75a is the left-hand surface in FIG. 12, and the protruding surface 75b is the right-hand surface in FIG. 12. More specifically, the upper wall surface 54a is connected to the first wall-surface protrusion 57 via one protruding surface 75a, and the upper wall surface 54b is connected to the second wall-surface protrusion 58 via the other protruding surface 75b. The protruding surfaces 75a and 75b each include a spatial protrusion 76. The spatial protrusion 76 extends in the X-direction and protrudes toward the second body surface 30b. This allows the working vapor 2a to be rectified so as to flow along the spatial protrusion 76. This allows the channel resistance of the working vapor 2a to be reduced, thereby diffusing the working vapor 2a more easily. The protruding surfaces 75a and 75b may each include a plurality of spatial protrusion 76 spaces apart from each other. A concave curved surface 77 formed in a concave curved shape may be formed between two adjacent spatial protrusions 76. The concave curved surface 77 may also be formed between the wall-surface protrusions 57 and 58 and the adjacent spatial protrusions 76, respectively. In the example shown in FIG. 12, the protruding surfaces 75a and 75b each include two spatial protrusions 76. This allows the working vapor 2a to be further rectified.

As shown in FIG. 12, the depth of the upper vapor channel depressed portion 54 is expressed as h3. The value of h3 may be, for example, from 20 μm to 250 μm. The depth h3 indicates the maximum distance from the second body surface 30b to the protruding surfaces 75a and 75b as seen in a cross section perpendicular to the X-direction. The depth h3 corresponds to the Z-directional dimension.

As shown in FIG. 12, the depth from the second body surface 30b to the spatial protrusion 76 is expressed as h4. The value of h4 may be, for example, from 17 μm to 245 μm. The depth h4 indicates the distance from the second body surface 30b to the end of the spatial protrusion 76 as seen in a cross section perpendicular to the X-direction. The depth h4 corresponds to the Z-directional dimension.

As shown in FIG. 12, the interval between the spatial protrusions 76 is expressed as w14. The value of w14 may be, for example, from 30 μm to 300 μm. The interval w14 indicates the pitch distance between the adjacent spatial protrusions 76 as seen in a cross section perpendicular to the X-direction. The interval w14 corresponds to the Y-directional dimension.

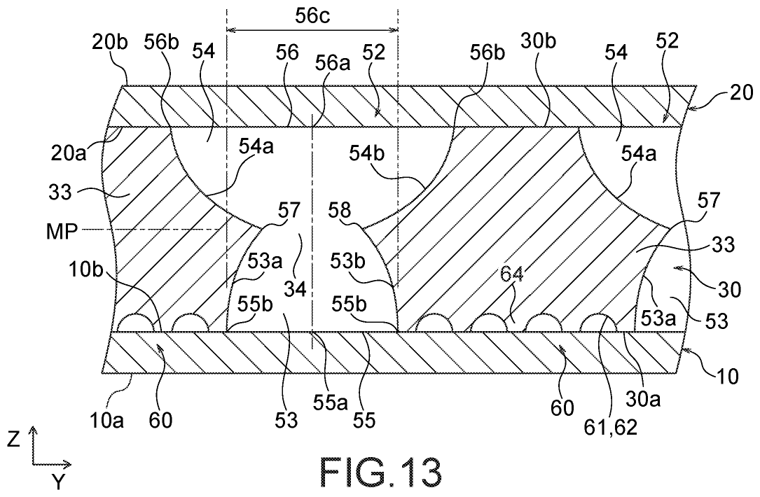

In the embodiment described above, the upper vapor channel depressed portion 54 includes the flat surfaces 59a and 59b as seen in a cross section perpendicular to the X-direction. However, the embodiment is not limited thereto. For example, the upper vapor channel depressed portion 54 does not have to include the flat surfaces 59a and 59b, as shown in FIG. 13. More specifically, the upper wall surfaces 54a and 54b and the wall-surface protrusions 57 and 58 are connected not via the flat surfaces 59a and 59b, respectively. Also in this case, the upper opening 56 in the second body surface 30b need only extend from the region 56c overlapping with the lower opening 55 in the first body surface 30a in plan view to a position overlapping with the main channel grooves 61 in plan view. This configuration can increase the channel cross-sectional areas of the vapor passages 51 and 52 and reduce the channel resistance of the working vapor 2a.

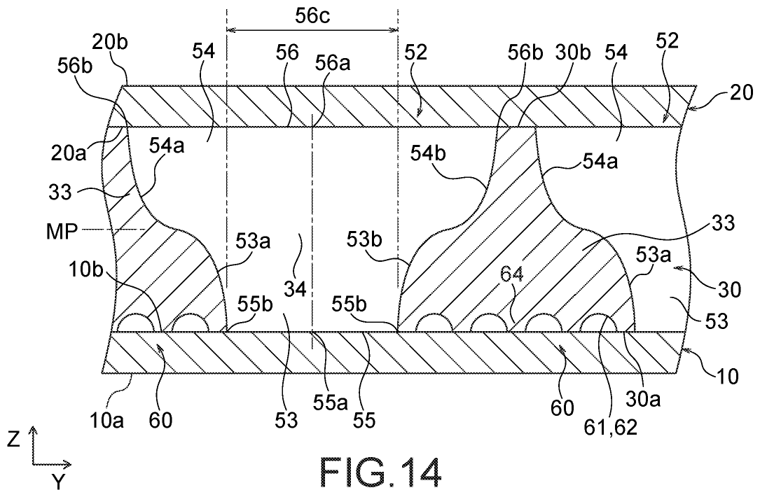

In the embodiment described above, the lower wall surfaces 53a and 53b of the lower vapor channel depressed portion 53 are curved in a concave shape. However, the embodiment is not limited thereto. As shown in FIG. 14, the lower wall surfaces 53a and 53b may be curved in a convex shape. The lower wall surfaces 53a and 53b and the upper wall surfaces 54a and 54b may be connected not via the wall-surface protrusions 57 and 58, respectively. The lower wall surfaces 53a and 53b and the upper wall surfaces 54a and 54b may be connected not via the flat surfaces 59a and 59b, respectively. The convex curve of the lower wall surfaces 53a and 53b can eliminate or reduce formation of the wall-surface protrusions 57 and 58. This configuration can increase the channel cross-sectional areas of the vapor passages 51 and 52 and reduce the channel resistance of the working vapor 2a. The lower wall surfaces 53a and 53b and the upper wall surfaces 54a and 54b may be connected via the flat surfaces 59a and 59b, respectively.

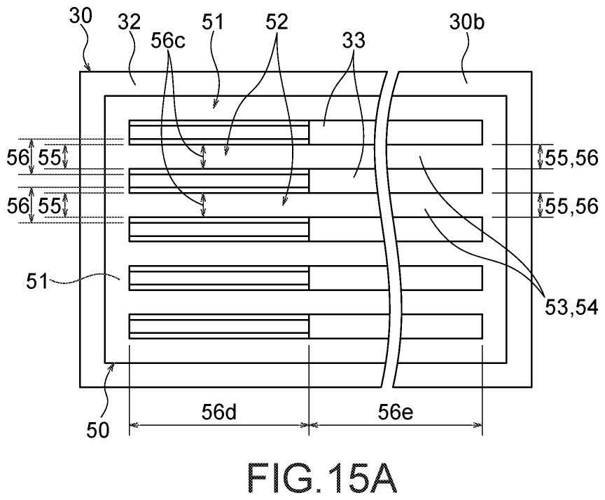

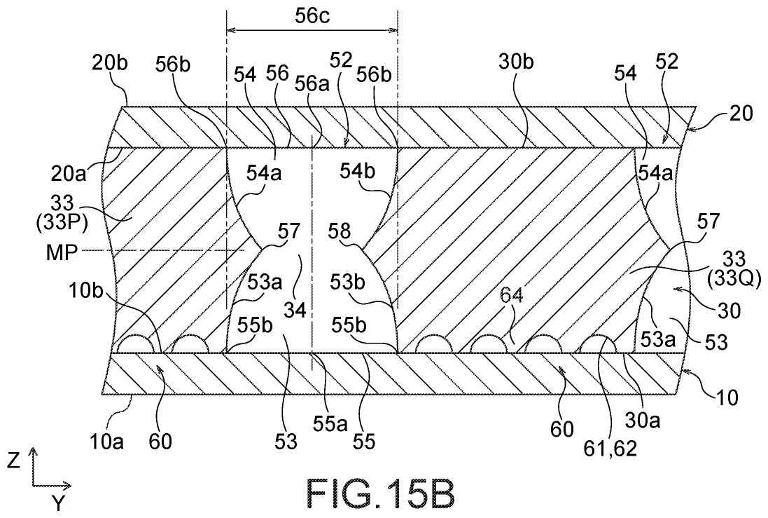

In the embodiment described above, the width w3 of the upper opening 56 is larger than the width w2 of the lower opening 55 across the entire region of the land 33 in the X-direction. However, the embodiment is not limited thereto. For example, as shown in FIG. 15A, the width w3 of the upper opening 56 may be larger than the width w2 of the lower opening 55 in part of the land 33 in the X-direction.

In the example shown in FIG. 15A, the upper opening 56 includes a first region 56d and a second region 56e. The first region 56d is a region in which the upper opening 56 extends from the region 56c overlapping with the lower opening 55 in plan view to a position overlapping with the main channel grooves 61 in plan view. The second region 56e is a region in which the upper opening 56 does not extend from the region 56c overlapping with the lower opening 55 in plan view to a position overlapping with the main channel grooves 61 in plan view. In the first region 56d, the width w3 is larger than width w2. The width w3 of the second region 56e is smaller than the width w3 of the first region 56d, as shown in FIG. 15B. In the second region 56e, the width w3 may be equal to the width w2, and the upper opening 56 may be overlapping with the lower opening 55 in plan view. More specifically, the upper opening side edge 56b is positioned at a position overlapping with the corresponding lower opening side edge 55b in plan view, and the upper opening side edge 56b is positioned at a position overlapping with the corresponding lower opening side edge 55b in plan view. This configuration can increase the area of the junction area of the land 33 and the upper sheet 20, increasing the mechanical strength of the vapor chamber 1.

The first region 56d and the second region 56e may be disposed at any position in the X-direction. For example, the first region 56d may be positioned in the evaporation region SR, and the second region 56e may be positioned in the condensation region CR. This configuration can increase the channel cross-sectional areas of the vapor passages 51 and 52 in the evaporation region SR in which the working vapor 2a tends to increase in pressure.

For example, the first region 56d may be positioned in the condensation region CR, and the second region 56e may be positioned in the evaporation region SR. This configuration can reduce the flow rate of the working vapor 2a and can accelerate the condensation in the condensation region CR.

For example, the first region 56d may be positioned in an intermediate portion of the vapor chamber 1 in the X-direction. The first region 56d may be positioned in a region of the condensation region CR near the evaporation region SR. This configuration can reduce the channel resistance of the working vapor diffused from the evaporation region SR, allowing the working vapor 2a to be diffused far from the evaporation region SR. This can increase the heat radiation efficiency of the vapor chamber 1.

### Second Embodiment

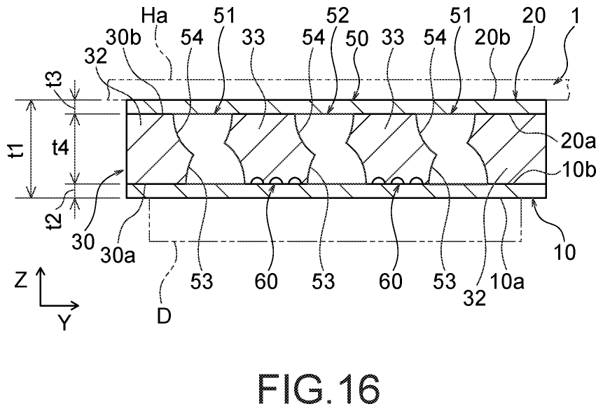

Referring next to FIGS. 16 to 25, a body sheet for a vapor chamber, a vapor chamber, and an electronic apparatus according to a second embodiment of the present invention will be described.

The second embodiment shown in FIG. 16 to FIG. 25 mainly differs in that the first wall-surface protrusion is disposed out of alignment with an intermediate position between the first body surface and the second body surface in the direction of normal to the first body surface. The other configurations are substantially the same as those of the first embodiment shown in FIGS. 1 to 15. In FIGS. 16 to 25, the same as those of the first embodiment shown in FIGS. 1 to 15 are given the same reference signs, and detailed descriptions will be omitted.

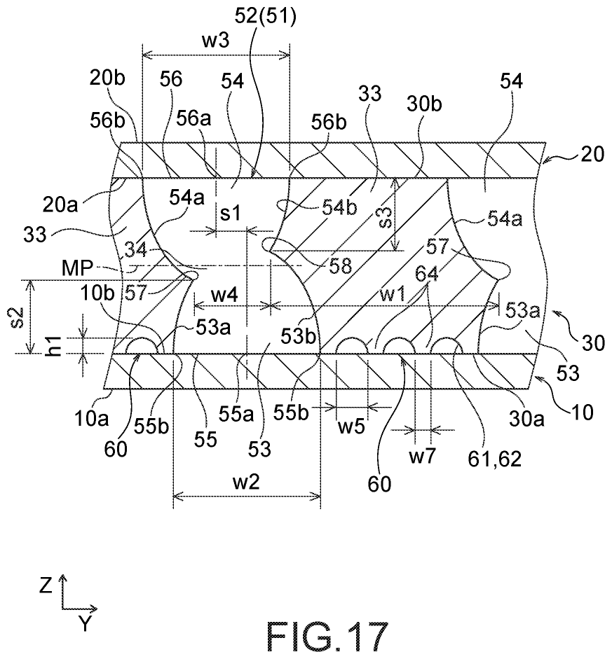

As shown in FIGS. 16 and 17, the center 55a of the lower opening 55 is out of alignment with the center 56a of the upper opening 56 as seen in a cross section perpendicular to the X-direction. More specifically, in a portion of the first vapor passage 51 extending in the X-direction, the center 55a of the lower opening 55 is disposed off the center 56a of the upper opening 56 to one side in the Y-direction. Similarly, also in the second vapor passages 52, the center 55a of the lower opening 55 is disposed off the center 56a of the upper opening 56 to one side in the Y-direction. Thus, in this embodiment, the cross-sectional shapes of the first vapor passage 51 and the second vapor passages 52 may be asymmetric in the Y-direction.

Although FIGS. 16 and 17 show an example in which the center 55a of the lower opening 55 is disposed off the center 56a of the upper opening 56 to the right side, the center 55a may be off to the left side. As shown in FIG. 17, the amount of the gap s1 between the center 55a of the lower opening 55 and the center 56a of the upper opening 56 may be, for example, 0.05 mm to (0.8×w1) mm. Setting the gap amount s1 to 0.05 mm can provide the effect of the gap between the center 55a and the center 56a, described later. In contrast, setting the gap amount s1 to (0.8×w1) mm or less can make the width w1 of the land 33 80% or less. This configuration can enhance the mechanical strength of the lands 33, thereby eliminating or reducing the deformation of the wick sheet 30 under a load in diffusion bonding or the like. FIGS. 2, 6, and 7 show a state in which the center 55a of the lower opening 55 is not out of alignment with the center 56a of the upper opening 56 for clarification of the drawings

The width w1 of the land 33 according to this embodiment (see FIG. 17) may be, for example, from 100 μm to 1,500 μm. The width w2 of the lower opening 55 according to this embodiment may be, for example, from 100 μm to 5,000 μm. The width w3 of the upper opening 56 according to this embodiment may be, for example, from 100 μm to 5,000 μm, as is the width w2 of the lower opening 55 described above. Alternatively, the width w3 of the upper opening 56 may differ from the width w2 of the lower opening 55.

Each lower opening side edge 55b is disposed off the corresponding upper opening side edge 56b as seen in a cross section perpendicular to the X-direction. Each lower opening side edge 55b is disposed off the corresponding upper opening side edge 56b to the right side.

Also in a portion of the first vapor passage 51 extending in the Y-direction, the center 55a of the lower opening 55 may be disposed off the center 56a of the upper opening 56 to one side in the X-direction. In this case, each lower opening side edge 55b may be disposed off the corresponding upper opening side edge 56b to one side.

The pair of wall-surface protrusions 57 and 58 according to this embodiment protrudes obliquely so as to face each other. The first wall-surface protrusion 57 protrudes toward the upper right. The second wall-surface protrusion 58 protrudes toward the lower left.

In this embodiment, the first wall-surface protrusion 57 is disposed out of alignment with the intermediate position MP between the first body surface 30a and the second body surface 30b in the Z-direction. The Z-direction is the thickness direction of the wick sheet 30, which corresponds to the direction of the normal to the first body surface 30a. As shown in FIG. 17, the first wall-surface protrusion 57 may be disposed nearer to the first body surface 30a than the intermediate position MP described above. In this case, the first wall-surface protrusion 57 is disposed not near the second body surface 30b but near the first body surface 30a. The distance s2 from the first body surface 30a to the first wall-surface protrusion 57 may be, for example, h1 or more or less than t4/2. The value h1 indicates the depth of the main channel grooves 61, as described above. The value t4 indicates the thickness of the wick sheet 30, as described above.

Similarly, in this embodiment, the second wall-surface protrusion 58 is disposed out of alignment with the intermediate position MP between the first body surface 30a and the second body surface 30b in the Z-direction. As shown in FIG. 17, the second wall-surface protrusion 58 may be disposed nearer to the second body surface 30b than the intermediate position MP. In this case, the second wall-surface protrusion 58 is disposed not near the first body surface 30a but near the second body surface 30b. The distance s3 from the second body surface 30b to the second wall-surface protrusion 58 may be equal to or differ from the distance s2 from the first body surface 30a to the first wall-surface protrusion 57. The distance s3 may be, for example, h1 or more or less than t4/2.

A method for producing the vapor chamber 1 of this embodiment with this configuration will next be described with reference to FIGS. 18 to 23.

In this section, first, a wick sheet producing process for producing the wick sheet 30 will be described.

First, as shown in FIG. 18, a material preparing process is performed in which a planar metallic material sheet M including a lower surface Ma (an example of a first material surface) and an upper surface Mb (an example of a second material surface) is prepared. The metallic material sheet M may be a rolled sheet having a desired thickness.

After the material preparing process, as shown in FIG. 19, a resist forming process is performed in which a lower resist film 70 is formed on the lower surface Ma of the metallic material sheet M, and an upper resist film 71 is formed on the upper surface Mb. Before the resist films 70 and 71 are formed, the lower surface Ma and the upper surface Mb of the metallic material sheet M may be subjected to an acidic defatting process as preprocessing. The resist films 70 and 71 may be formed by applying a liquid resist to the lower surface Ma and the upper surface Mb and drying and curing the liquid resist. Alternatively, the resist films 70 and 71 may be formed by applying a dry film resist to the lower surface Ma and the upper surface Mb.

Next, as shown in FIG. 20, a patterning process is performed in which the lower resist film 70 and the upper resist film 71 are patterned using a photolithography technique. In this case, first resist openings 72 corresponding to the lower openings 55 are formed in the lower resist film 70, and second resist openings 73 corresponding to the main channel grooves 61 and the communication grooves 65 are formed in the lower resist film 70. Third resist openings 74 corresponding to the upper openings 56 are formed in the upper resist film 71. The center of each first resist opening 72 is disposed off the center of the corresponding third resist opening 74 to one side in the Y-direction. The Y-directional dimension w2′ of the first resist opening 72 may be equal to or differ from the Y-directional dimension w3′ of each third resist opening 74. The dimension w2′ is a dimension corresponding to the width w2 of the lower opening 55 and is set to form the width w2 of the lower opening 55 by etching. Similarly, the dimension w3′ is a dimension corresponding to the width w3 of the lower opening 55 and is set to form the width w3 of the upper opening 56 by etching.

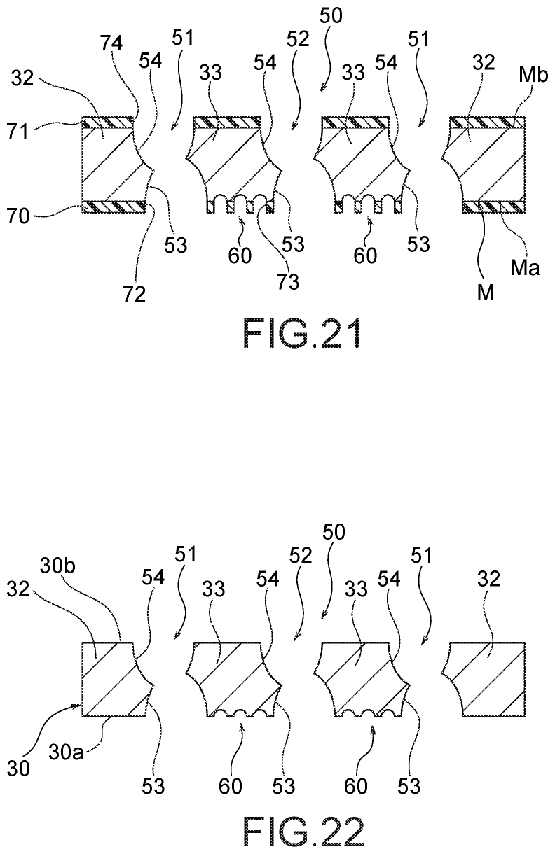

Next, as shown in FIG. 21, an etching process is performed in which the lower surface Ma and the upper surface Mb of the metallic material sheet M are etched. Thus, portions of the lower surface Ma of the metallic material sheet M corresponding to the first resist opening 72 and the second resist opening 73 are etched. As a result, the lower vapor channel depressed portions 53 of the vapor channel portions 50 and the main channel grooves 61 and the communication grooves 65 of the liquid channel portions 60, as shown in FIG. 21, are formed. Portions of the upper surface Mb corresponding to the third resist openings 74 are etched to form the upper vapor channel depressed portions 54 of the vapor channel portions 50, as shown in FIG. 21. Examples of the etchant include a ferric chloride etchant, such as a ferric chloride water solution, and a copper chloride etchant, such as a copper chloride water solution.

The lower surface Ma and the upper surface Mb of the metallic material sheet M may be etched at the same time. However, the embodiment is not limited thereto. The lower surface Ma and the upper surface Mb may be etched in separate processes. The vapor channel portions 50 and the liquid channel portions 60 may be etched at the same time or in separate processes.

In the etching process, etching the lower surface Ma and the upper surface Mb of the metallic material sheet M forms a predetermined outer shape of the wick sheet 30, as shown in FIGS. 6 and 7.

After the etching process, a resist removing process is performed in which the lower resist film 70 and the upper resist film 71 are removed, as shown in FIG. 22.

Thus, the wick sheet 30 according to this embodiment is provided.

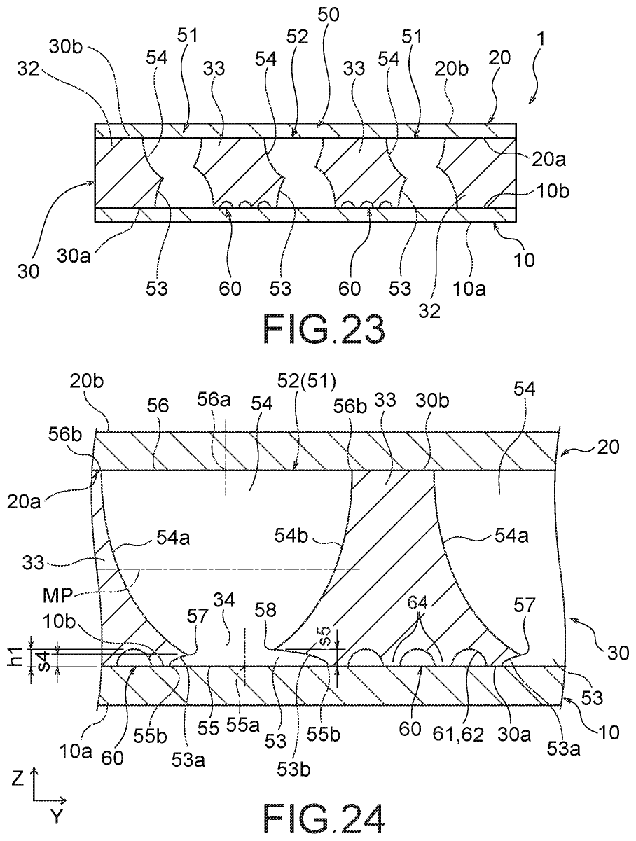

After the process of producing the wick sheet 30, a bonding process is performed in which the lower sheet 10, the upper sheet 20, and the wick sheet 30 are bonded together, as shown in FIG. 23. The lower sheet 10 and the upper sheet 20 may be rolled sheets having a desired thickness.

More specifically, first, the lower sheet 10, the wick sheet 30, and the upper sheet 20 are laminated in this order. In this case, the first body surface 30a of the wick sheet 30 is placed on the second lower sheet surface 10b of the lower sheet 10, and the first upper sheet surface 20a of the upper sheet 20 is placed on the second body surface 30b of the wick sheet 30. In this case, the sheets 10, 20, and 30 are aligned using the alignment holes 12 of the lower sheet 10, the alignment holes 35 of the wick sheet 30, and the alignment holes 22 of the upper sheet 20.

Next, the lower sheet 10, the wick sheet 30, and the upper sheet 20 are temporarily bonded together. For example, the sheets 10, 20, and 30 may be temporarily bonded using spot resistance welding or laser welding.

Next, the lower sheet 10, the wick sheet 30, and the upper sheet 20 are bonded permanently by means of diffusion bonding. The diffusion bonding is a method for bonding the sheets 10, 20, and 30 by bringing the lower sheet 10 and the wick sheet 30 into close-contact with each other and bringing the wick sheet 30 and the upper sheet 20 into close-contact with each other. More specifically, the sheets 10, 20, and 30 are pressurized and heated in the laminating direction in a controlled atmosphere, such as vacuum or an inert gas. Thus, the sheets 10, 20, and 30 are bonded together using atomic scattering generated on the bonded surface. The diffusion bonding heats the materials of the sheets 10, 20, and 30 to a temperate near the melting point. However, this temperature is lower than the melting point, which can eliminate or reduce melting and deformation of the sheets 10, 20, and 30. More specifically, the frame 32 of the wick sheet 30 and the first body surfaces 30a of the lands 33 are diffusion-bonded to the second lower sheet surface 10b of the lower sheet 10. The frame 32 of the wick sheet 30 and the second body surfaces 30b of the lands 33 are diffusion-bonded to the first upper sheet surface 20a of the upper sheet 20. Thus, the sheets 10, 20, and 30 are diffusion-bonded to form a sealed space 3 including the vapor channel portion 50 and the liquid channel portion 60 between the lower sheet 10 and the upper sheet 20. At the injecting portion 4, the lower injecting protrusion 11 of the lower sheet 10 and the wick-sheet injecting protrusion 36 of the wick sheet 30 are diffusion-bonded. The wick-sheet injecting protrusion 36 and the upper injecting protrusion 21 of the upper sheet 20 are diffusion-bonded. Thus, the injection channel 37 becomes a closed space.

After the bonding process, the working liquid 2b is injected from the injecting portion 4 into the sealed space 3. In the injection, the working liquid 2b passes through the injection channel 37 into the sealed space 3.

Thereafter, the injection channel 37 is sealed. For example, the injection channel 37 may be sealed by partly melting the injecting portion 4. This can block the communication between the sealed space 3 and the outside to enclose the working liquid 2b in the sealed space 3, thereby eliminating or reducing leaking of the working liquid 2b in the sealed space 3 to the outside. After the sealing, the injecting portion 4 may be cut off.

Thus, the vapor chamber 1 according to this embodiment is provided.

The operation of the vapor chamber 1 according to this embodiment will be described.

The working liquid 2b attached to the respective wall surfaces 53a and 53b and 54a and 54b of the vapor channel depressed portions 53 and 54 can also be conveyed to the evaporation region SR by means of the capillary action of the vapor channel depressed portions 53 and 54. The vapor channel depressed portions 53 and 54 function mainly as a channel for the working vapor 2a. The working liquid 2b attached to the wall surfaces 53a, 53b, 54a, and 54b can be acted upon by a capillary action. In the case where the lengths of the wall surfaces 53a, 53b, 54a, and 54b are large as seen in a cross section perpendicular to the X-direction, the capillary action on the working liquid 2b attached to the wall surfaces 53a and 53b, and 54a and 54b can be enhanced. The length of the wall surface is the length of the wall surface as seen in a cross section perpendicular to the X-direction.

As shown in FIG. 17, in this embodiment, the first wall-surface protrusion 57 is disposed nearer to the first body surface 30a than the intermediate position MP between the first body surface 30a and the second body surface 30b in the Z-direction. In this case, the length of the lower wall surface 53a connected to the first wall-surface protrusion 57 is small, which can enhance the capillary action on the working liquid 2b attached to the lower wall surface 53a.

In contrast, the length of the upper wall surface 54a connected to the first wall-surface protrusion 57 is large as seen in a cross section perpendicular to the X-direction. This configuration can enhance the action to hold the working liquid 2b on the upper wall surface 54a, which can increase the amount of the working liquid 2b held on the upper wall surface 54a. The working liquid 2b held on the upper wall surface 54a flows over the first wall-surface protrusion 57 to move to the lower wall surface 53a and is conveyed to the evaporation region SR owing to the capillary action of the lower wall surface 53a. This can increase the amount of the working liquid 2b conveyed to the evaporation region SR using the working liquid 2b held on the upper wall surface 54a.

The lower wall surface 53a is connected to the first body surface 30a, and the first body surface 30a has the main channel grooves 61 and the communication grooves 65 of the liquid channel portion 60. In this case, the lower wall surface 53a is near the liquid channel portion 60, which allows the working liquid 2b to flow back and forth between the lower wall surface 53a and the liquid channel portion 60.

Similarly, in this embodiment, the second wall-surface protrusion 58 is disposed nearer to the second body surface 30b than the intermediate position MP between the first body surface 30a and the second body surface 30b in the Z-direction. In this case, the length of the upper wall surface 54b connected to the second wall-surface protrusion 58 is small, which can enhance the capillary action on the working liquid 2b attached to the upper wall surface 54b.

In contrast, the length of the lower wall surface 53b connected to the second wall-surface protrusion 58 is large as seen in a cross section perpendicular to the X-direction. This configuration can enhance the action to hold the working liquid 2b on the lower wall surface 53b, which can increase the amount of the working liquid 2b held on the lower wall surface 53b. The working liquid 2b held on the lower wall surface 53b flows over the second wall-surface protrusion 58 to move to the upper wall surface 54b and is conveyed to the evaporation region SR owing to the capillary action of the upper wall surface 54b. This can increase the amount of the working liquid 2b conveyed to the evaporation region SR using the working liquid 2b held on the lower wall surface 53b.

The lower wall surface 53b is connected to the first body surface 30a, and the first body surface 30a has the main channel grooves 61 and the communication grooves 65 of the liquid channel portion 60. In this case, the lower wall surface 53b is near the liquid channel portion 60, which allows the working liquid 2b held on the lower wall surface 53b to move to the liquid channel portion 60. This can also increase the amount of the working liquid 2b conveyed to the evaporation region SR.

Thus, the working liquid 2b can be conveyed to the evaporation region SR using not only the liquid channel portion 60 but also the vapor channel portion 50.

Thus, in this embodiment, the lower wall surface 53a of the lower vapor channel depressed portion 53 and the upper wall surface 54a of the upper vapor channel depressed portion 54 are connected by the first wall-surface protrusion 57. The first wall-surface protrusion 57 protrudes toward the inside of the vapor channel portion 50 and is disposed out of alignment with the intermediate position MP between the first body surface 30a and the second body surface 30b in the Z-direction. This can make the length of the lower wall surface 53a and the length of the upper wall surface 54a different as seen in a cross section perpendicular to the X-direction. This can enhance the capillary action on the working liquid 2b attached to a short one of the lower wall surface 53a and the upper wall surface 54a and enhance the action to hold the working liquid 2b on the other longer wall surface. For example, if the lower wall surface 53a is short, the working liquid 2b held on the upper wall surface 54a can be conveyed to the evaporation region SR using the capillary action of the lower wall surface 53a. Thus, the amount of the working liquid 2b conveyed to the evaporation region SR can be increased. This can increase the heat radiation efficiency of the vapor chamber 1, thereby increasing the efficiency of cooling the electronic device D.

According to this embodiment, the first body surface 30a includes the liquid channel portion 60 including the plurality of main channel grooves 61 and the plurality of communication grooves 65, and the first wall-surface protrusion 57 is disposed nearer to the first body surface 30a than the intermediate position MP between the first body surface 30a and the second body surface 30b. This allows the first wall-surface protrusion 57 to be disposed near the liquid channel portion 60. This configuration can enhance the capillary action on the working liquid 2b attached to the lower wall surface 53a near the liquid channel portion 60, allowing the working liquid 2b to flow back and forth between the lower wall surface 53a and the liquid channel portion 60. This allows the working liquid 2b to be collected to, of the lower wall surface 53a and the liquid channel portion 60, the one with stronger capillary action, thereby increasing the amount of the working liquid 2b conveyed to the evaporation region SR.

According to this embodiment, the lower wall surface 53b of the lower vapor channel depressed portion 53 and the upper wall surface 54b of the upper vapor channel depressed portion 54 are connected by the second wall-surface protrusion 58. The second wall-surface protrusion 58 protrudes toward the inside of the vapor channel portion 50 and is disposed out of alignment with the intermediate position MP between the first body surface 30a and the second body surface 30b in the Z-direction. This can make the length of the lower wall surface 53b and the length of the upper wall surface 54b different as seen in a cross section perpendicular to the X-direction. This can enhance the capillary action on the working liquid 2b attached to a short one of the lower wall surface 53b and the upper wall surface 54b and enhance the action to hold the working liquid 2b on the other longer wall surface. For example, if the upper wall surface 54b is short, the working liquid 2b held on the lower wall surface 53b can be conveyed to the evaporation region SR using the capillary action of the upper wall surface 54b. Thus, the amount of the working liquid 2b conveyed to the evaporation region SR can be increased. This can increase the heat radiation efficiency of the vapor chamber 1, thereby increasing the efficiency of cooling the electronic device D.

According to this embodiment, the center 55a of the lower opening 55 of the vapor channel portion 50 positioned in the first body surface 30a of the wick sheet 30 is disposed off the center 56a of the upper opening 56 in the second body surface 30b. This allows the first wall-surface protrusion 57 and the second wall-surface protrusion 58 to be easily disposed off the intermediate position MP between the first body surface 30a and the second body surface 30b. This allows the amount of the working liquid 2b conveyed to the evaporation region SR to be easily increased. In the case where the center 55a of the lower opening 55 is disposed off the center 56a of the upper opening 56, the difference between the width w2 of the lower opening 55 and the width w3 of the upper opening 56 can be reduced. This can eliminate or reduce the imbalance between the action to hold the working liquid 2b with the lower wall surface 53b and the action to hold the working liquid 2b with the upper wall surface 54a. This can eliminate or reduce the influence of the orientation of the vapor chamber 1 on the performance of the vapor chamber 1, thereby improving the reliability of the vapor chamber 1.

In the embodiment described above, the first wall-surface protrusion 57 is disposed nearer to the first body surface 30a than the intermediate position MP, and the second wall-surface protrusion 58 is disposed nearer to the second body surface 30b than the intermediate position MP. However, the embodiment is not limited thereto. The first wall-surface protrusion 57 may be disposed nearer to the second body surface 30b than the intermediate position MP, and the second wall-surface protrusion 58 may be disposed nearer to the first body surface 30a than the intermediate position MP. This allows the second wall-surface protrusion 58 to be disposed near the liquid channel portion 60, allowing the working liquid 2b to flow back and forth between the lower wall surface 53b and the liquid channel portion 60. Alternatively, the second wall-surface protrusion 58 may be disposed at the intermediate position MP.

Alternatively, as shown in FIG. 24, the first wall-surface protrusion 57 may be disposed nearer to the first body surface 30a than the intermediate position MP, and the second wall-surface protrusion 58 may be disposed nearer to the first body surface 30a than the intermediate position MP.

For example, forming the first resist opening 72 so as to decrease the etching speed for the lower vapor channel depressed portion 53 in the etching process shown in FIG. 21 allows the first wall-surface protrusion 57 and the second wall-surface protrusion 58 shown in FIG. 24 to be formed. In FIG. 24, the distance s4 from the first body surface 30a to the first wall-surface protrusion 57 may be, for example, 20 μm or more. For example, the distance s4 may be less than t4/2, or may be h1 or less. The distance s5 from the first body surface 30a to the second wall-surface protrusion 58 may be equal to or differ from the distance s4. The distance s5 may be, for example, 20 μm or more. For example, the distance s5 may be less than t4/2, or may be h1 or less.

According to a modification shown in FIG. 24, the first wall-surface protrusion 57 is disposed nearer to the first body surface 30a than the intermediate position MP, and the second wall-surface protrusion 58 is disposed nearer to the first body surface 30a than the intermediate position MP. This allows the first wall-surface protrusion 57 and the second wall-surface protrusion 58 to be disposed close to the liquid channel portion 60. This configuration can enhance the capillary action on the working liquid 2b attached to the lower wall surface 53a and the lower wall surface 53b close to the liquid channel portion 60. In this case, the working liquid 2b can flow back and forth between the lower wall surface 53a and the liquid channel portion 60 and between the lower wall surface 53b and the liquid channel portion 60. This allows the working liquid 2b to be collected to a portion of the lower wall surface 53a, the lower wall surface 53b, and the liquid channel portion 60 having a strong capillary action, thereby increasing the amount of the working liquid 2b conveyed to the evaporation region SR.

According to the modification shown in FIG. 24, the first wall-surface protrusion 57 is disposed nearer to the first body surface 30a than the intermediate position MP, and the second wall-surface protrusion 58 is disposed nearer to the first body surface 30a than the intermediate position MP. This allows the channel of the working vapor 2a diffusing in the upper vapor channel depressed portion 54 to have a nearly large circular shape. This can reduce the channel resistance of the working vapor 2a, allowing the working vapor 2a to be easily diffused. This allows enhancement of the heat radiation efficiency of the vapor chamber 1, thereby improving the efficiency of cooling the electronic device D.

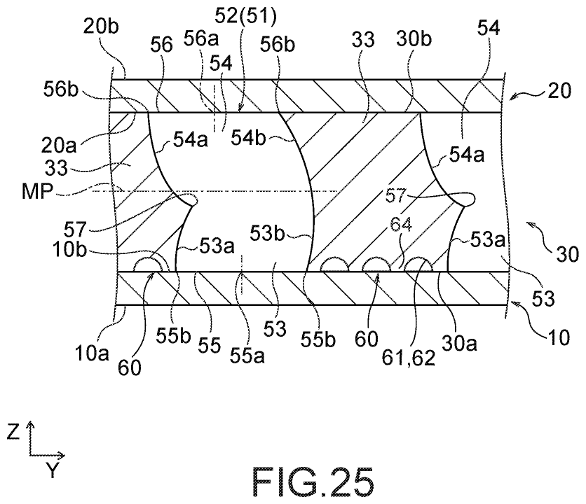

In the embodiment described above, the lower wall surface 53b of the lower vapor channel depressed portion 53 and the upper wall surface 54b of the upper vapor channel depressed portion 54 are connected by the second wall-surface protrusion 58. However, the embodiment is not limited thereto. For example, as shown in FIG. 25, the lower wall surface 53b and the upper wall surface 54b may be continuously formed in a concave shape from the lower wall surface 53b to the upper wall surface 54b. In this case, the lower wall surface 53b and the upper wall surface 54b may be formed so as to swell outward from the vapor channel depressed portions 53 and 54. For example, the lower wall surface 53b and the upper wall surface 54b may be formed so as to swell outward from the vapor channel depressed portions 53 and 54 with respect to the straight line connecting the right-hand lower opening side edge 55b and the right-hand upper opening side edge 56b in FIG. 25. The lower wall surface 53b and the upper wall surface 54b may be continuously smoothly curved.

For example, in the etching process shown in FIG. 21, the etching speed of the portion of the lower vapor channel depressed portion 53 which is disposed near the lower wall surface 53b, may be higher than the etching speed of the portion of the lower vapor channel depressed portion 53 which is disposed near the lower wall surface 53a. For example, the first resist opening 72 may be formed so that the etching speed for the portion of the lower vapor channel depressed portion 53 which is disposed near the lower wall surface 53a, is decreased. This configuration can make the etching speed for the portion of the lower vapor channel depressed portion 53 which is disposed near the lower wall surface 53b, higher than the etching speed for the portion of the lower vapor channel depressed portion 53 which is disposed near the lower wall surface 53a. Similarly, the third resist opening 74 may be formed so that the etching speed for the portion of the upper vapor channel depressed portion 54 which is disposed near the upper wall surface 54a, is decreased. This configuration can make the etching speed for the portion of the upper vapor channel depressed portion 54 which is disposed near the upper wall surface 54b, higher than the etching speed for the portion of the upper vapor channel depressed portion 54 which is disposed near the upper wall surface 54a. Thus, the lower wall surface 53b and the upper wall surface 54b are formed so as not to form the second wall-surface protrusion 58. As a result, the lower wall surface 53b and the upper wall surface 54b are continuously formed in a concave shape.

According to the modification shown in FIG. 25, the lower wall surface 53b and the upper wall surface 54b are continuously formed in a concave shape. This allows the channel of the working vapor 2a diffusing in the vapor channel depressed portions 53 and 54 to have a nearly large circular shape. This can reduce the channel resistance of the working vapor 2a, allowing the working vapor 2a to be easily diffused. This allows enhancement of the heat radiation efficiency of the vapor chamber 1, thereby improving the efficiency of cooling the electronic device D.

### Third Embodiment

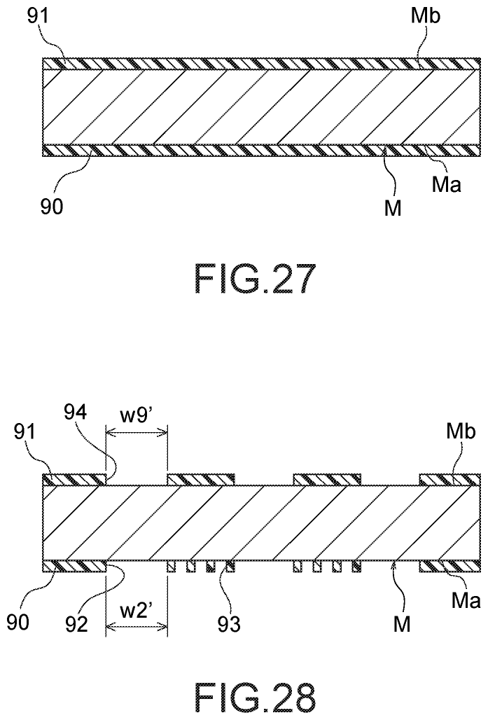

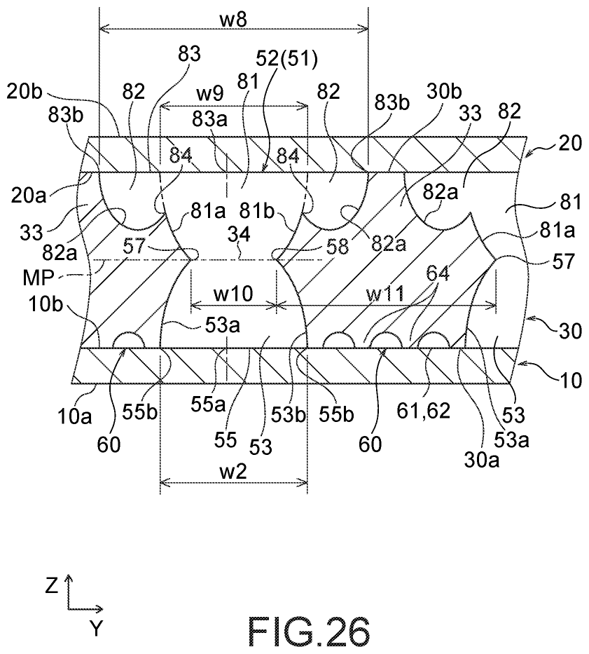

Referring next to FIGS. 26 to 35, a body sheet for a vapor chamber, a vapor chamber, and an electronic apparatus according to a third embodiment of the present invention will be described.

The third embodiment shown in FIGS. 26 to 35 mainly differs in that the second body surface has third space depressed portions on both sides of the second space depressed portion and that a pair of third wall-surface protrusions connecting the wall surfaces of the second space depressed portion and the third wall surfaces of the corresponding third space depressed portion protrudes toward the second body surface. The other configurations are substantially the same as those of the second embodiment shown in FIGS. 16 to 25. In FIGS. 26 to 35, the same as those of the second embodiment shown in FIGS. 16 to 25 are given the same reference signs, and detailed descriptions will be omitted.

In the vapor chamber 1 of this embodiment, as shown in in FIG. 26, the first vapor passage 51 and the second vapor passage 52 of the vapor channel portion 50 each include a lower vapor channel depressed portion 53, a first upper vapor channel depressed portion 81, and second upper vapor channel depressed portions 82. The lower vapor channel depressed portion 53 is an example of the first space depressed portion, which is disposed on the first body surface 30a. The first upper vapor channel depressed portion 81 is an example of the second space depressed portion, which is disposed on the second body surface 30b. The second upper vapor channel depressed portions 82 are examples of the third space depressed portions, which are disposed on the second body surface 30b. The first upper vapor channel depressed portion 81 includes a pair of first upper wall surfaces 81a and 81b. The first upper wall surfaces 81a and 81b are examples of the second wall surface. The first upper wall surface 81a is a left-hand wall surface in FIG. 26. The first upper wall surface 81b is a right-hand wall surface in FIG. 26. The first upper vapor channel depressed portion 81 and the first upper wall surfaces 81a and 81b of this embodiment are substantially the same as the upper vapor channel depressed portion 54 and the upper wall surfaces 54a and 54b shown in FIG. 16 and so on. For this reason, detailed descriptions of the first upper vapor channel depressed portion 81 and the first upper wall surfaces 81a and 81b will be omitted.

As shown in FIG. 26, the second upper vapor channel depressed portions 82 are positioned on both sides of the first upper vapor channel depressed portion 81 as seen in a cross section perpendicular to the X-direction. The second upper vapor channel depressed portions 82 communicate with the first upper vapor channel depressed portion 81 to form a continuous opening in the second body surface 30b.

The second upper vapor channel depressed portions 82 are formed in a concave shape in the second body surface 30b by etching the second body surface 30b of the wick sheet 30 in a second etching process, described later. This forms a curved second upper wall surface 82a formed in a curved shape at the second upper vapor channel depressed portion 82, as shown in FIG. 26. The second upper wall surface 82a is an example of a third wall surface. The second upper wall surface 82a defines the second upper vapor channel depressed portion 82 and constitutes part of the first vapor passage 51 and part of the second vapor passage 52.

An upper opening 83 of this embodiment is positioned in the second body surface 30b and is an opening of the first upper vapor channel depressed portion 81 and the second upper vapor channel depressed portions 82 of the second body surface 30b. The planar shape of the upper opening 83 at the first vapor passage 51 has a rectangular frame shape, as shown in FIG. 6. The planar shape of the upper opening 83 at the second vapor passages 52 has an elongated rectangular shape, as shown in FIG. 6. The upper opening 83 is an opening defined by the first upper vapor channel depressed portion 81 and the second upper vapor channel depressed portions 82 in the second body surface 30b.

The width w8 of the upper opening 83 may be, for example, from 200 μm to 6,000 μm. The width w8 of the upper opening 83 is the Y-directional dimension of the upper opening 83. The width w8 of the upper opening 83 corresponds to the Y-directional dimension of a portion of the first vapor passage 51 extending in the X-direction and corresponds to the Y-directional dimension of the second vapor passages 52. In this embodiment, the Y-directional dimension between the second upper wall surfaces 82a of the pair of second upper vapor channel depressed portions 82 that define the vapor passages 51 and 52 increases gradually from the first body surface 30a toward the second body surface 30b and becomes the maximum at the second body surface 30b. The width w8 is therefore the maximum value of the Y-directional dimension between the pair of second upper wall surfaces 82a. The Y-directional dimension between the pair of second upper wall surfaces 82a does not have to be the maximum at the second body surface 30b. For example, the position where the Y-directional dimension between the pair of second upper wall surfaces 82a is the maximum may be nearer to the first body surface 30a than the second body surface 30b. The width w8 also corresponds to the X-directional dimension at a portion of the first vapor passage 51 extending in the Y-direction. The width w8 of the upper opening 83 may be larger than the width w2 of the lower opening 55. Also in this embodiment, the upper opening 83 may extend from the region 56c overlapping with the lower opening 55 in plan view to a position overlapping with the main channel grooves 61 in plan view.

In this embodiment, the cross-sectional shapes of the first vapor passage 51 and the second vapor passages 52 may be symmetrical in the Y-direction. In other words, the center 55a of the lower opening 55 may be disposed at the same position in the Y-direction as the position of the center 83a of the upper opening 83.

The upper opening 83 is defined by a pair of upper opening side edges 83b (an example of the second opening side edge) extending in the X-direction. The center 83a of the upper opening 83 is the midpoint of the pair of upper opening side edges 83b as seen in a cross section perpendicular to the X-direction. In FIG. 26, the upper opening side edges 83b are each expressed as a point of intersection of the second body surface 30b and the second upper wall surface 82a of the second upper vapor channel depressed portion 82. The midpoint of these points of intersection is the center 83a of the upper opening 83.

Each upper opening side edges 83b is disposed off the corresponding lower opening side edge 55b to one side. In FIG. 26, the upper opening side edge 83b on the right side of the upper opening 83 is disposed off the lower opening side edge 55b on the right side of the lower opening 55 to the right side, and the left-hand upper opening side edge 83b is disposed off the left-hand lower opening side edge 55b to the left side. Thus, the width w8 of the upper opening 83 is larger than the width w2 of the lower opening 55.

In this embodiment, the first upper wall surfaces 81a and 81b of the first upper vapor channel depressed portion 81 do not extend to the second body surface 30b. The width w9 of the opening when the first upper wall surfaces 81a and 81b extend to the second body surface 30b along the curved shape of the first upper wall surfaces 81a and 81b may be equal to the width w3 of the upper opening 56 shown in FIG. 17. In other words, a third resist opening 94 formed in a first upper resist film 91 formed on the second body surface 30b in a first patterning process described below may be equal to a first resist opening 92 formed in a first lower resist film 90 formed on the first body surface 30a.

As shown in FIG. 26, the first upper wall surfaces 81a and 81b of the first upper vapor channel depressed portion 81 and the second upper wall surface 82a of the corresponding second upper vapor channel depressed portion 82 are connected by the third wall-surface protrusion 84. For this reason, the first upper wall surfaces 81a and 81b do not extend to the second body surface 30b, and the first upper vapor channel depressed portion 81 communicates with the second upper vapor channel depressed portions 82 on both sides thereof.

The third wall-surface protrusion 84 may protrude toward the second body surface 30b. The third wall-surface protrusion 84 may be formed so as to protrude toward the upper sheet 20. The third wall-surface protrusion 84 is positioned nearer to the first body surface 30a than the second body surface 30b and is spaced apart from the first upper sheet surface 20a of the upper sheet 20.

The lower wall surfaces 53a and 53b of the lower vapor channel depressed portion 53 and the corresponding first upper wall surfaces 81a and 81b of the first upper vapor channel depressed portion 81 are connected by the wall-surface protrusions 57 and 58, respectively. More specifically, the lower wall surface 53a of the lower vapor channel depressed portion 53 and the corresponding first upper wall surface 81a of the first upper vapor channel depressed portion 81 are connected by the first wall-surface protrusion 57. The lower wall surface 53b of the lower vapor channel depressed portion 53 and the corresponding first upper wall surface 81b of the first upper vapor channel depressed portion 81 are connected by the second wall-surface protrusion 58. The first wall-surface protrusion 57 is the left-hand wall-surface protrusion in FIG. 26, and the second wall-surface protrusion 58 is the right-hand wall-surface protrusion in FIG. 26.

As shown in FIG. 26, the first wall-surface protrusion 57 may be disposed at the intermediate position MP between the first body surface 30a and the second body surface 30b. The second wall-surface protrusion 58 may be disposed at the intermediate position MP between the first body surface 30a and the second body surface 30b.

The pair of wall-surface protrusions 57 and 58 defines the through portion 34, where the lower vapor channel depressed portion 53 and the first upper vapor channel depressed portion 81 communicate with each other. The width w10 of the through portion 34 (see FIG. 26) may be, for example, from 400 μm to 1,600 μm. The width w10 of the through portion 34 corresponds to the gap between the lands 33 adjacent to each other in the Y-direction. More specifically, the width w10 is the Y-directional distance between the end of the first wall-surface protrusion 57 and the end of the second wall-surface protrusion 58 which define the through portion 34.

The width w11 of the land 33 according to this embodiment (see FIG. 26) may be, for example, from 100 μm to 1,500 μm. The width w11 of the land 33 is the maximum dimension of the land 33 in the Y-direction. More specifically, the width w11 of the land 33 is the Y-directional distance between the end of the first wall-surface protrusion 57 and the end of the second wall-surface protrusion 58 which define the land 33.

A method for producing the vapor chamber 1 with such a configuration according to this embodiment will be described with reference to FIGS. 27 to 34. Here, differences from the second embodiment will be mainly described.

After the material preparing process shown in FIG. 18, a first resist forming process is performed, as shown in FIG. 27, in which the first lower resist film 90 is formed on the lower surface Ma of the metallic material sheet M, and the first upper resist film 91 is formed on the upper surface Mb. The first resist forming process may be performed as in the resist forming process shown in FIG. 19.

Next, as shown in FIG. 28, a first patterning process is performed in which the first lower resist film 90 and the first upper resist film 91 are patterned using a photolithography technique. In this case, the first resist opening 92 corresponding to the lower opening 55 and second resist openings 93 corresponding to the main channel grooves 61 and the communication grooves 65 of the liquid channel portion 60 are formed in the first lower resist film 90. The third resist opening 94 corresponding to the upper opening 83 is formed in the first upper resist film 91. The Y-directional dimension w9′ of the third resist opening 94 is the dimension corresponding to the width w9 shown in FIG. 26. The dimension w9′ is set to form the width w9 by etching. The value w9′ may be equal to or different from the Y-directional dimension w3′ of the first resist opening 92.

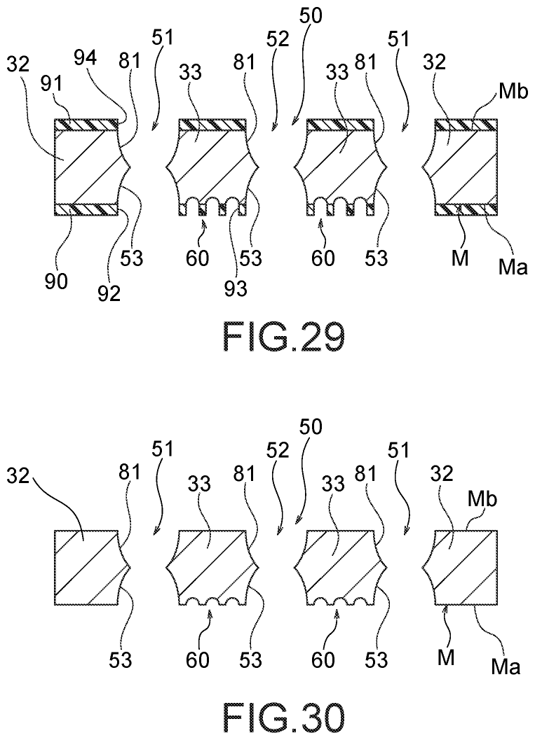

Next, as shown in FIG. 29, a first etching process is performed in which the lower surface Ma and the upper surface Mb of the metallic material sheet M are etched as in the etching process shown in FIG. 21. As a result, the lower vapor channel depressed portion 53 of the vapor channel portion 50 and the main channel grooves 61 and the communication grooves 65 of the liquid channel portion 60 as shown in FIG. 29 are formed on the lower surface Ma of the metallic material sheet M. The first upper vapor channel depressed portion 81 of the vapor channel portion 50 is formed on the upper surface Mb.

After the first etching process, as shown in FIG. 30, a first resist removing process is performed in which the first lower resist film 90 and the first upper resist film 91 are removed.

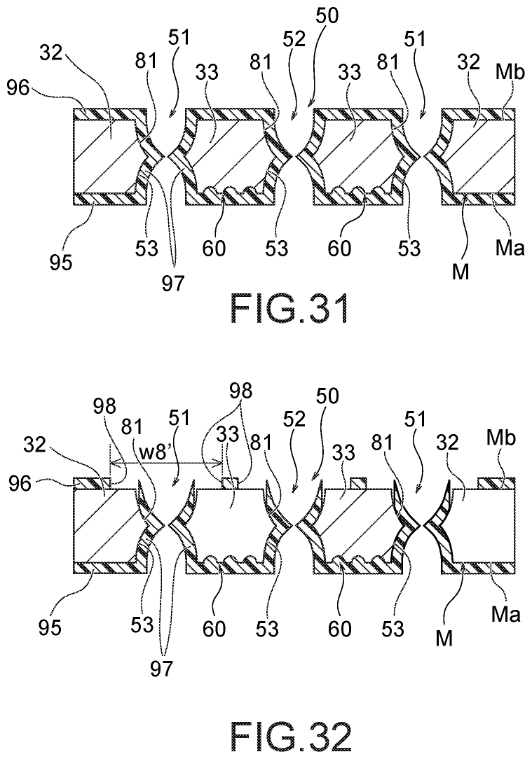

After the first resist removing process, a second resist forming process is performed as shown in FIG. 31, in which a second lower resist film 95 is formed on the lower surface Ma of the metallic material sheet M and a second upper resist film 96 is formed on the upper surface Mb. A wall surface resist film 97 is formed on the lower wall surfaces 53a and 53b of the lower vapor channel depressed portion 53 and the first upper wall surfaces 81a and 81b of the first upper vapor channel depressed portion 81. The second lower resist film 95, the second upper resist film 96, and the wall surface resist film 97 may be formed with a liquid resist. This allows easily forming the wall surface resist film 97 on the lower wall surfaces 53a and 53b and the first upper wall surfaces 81a and 81b. Before the resist films 95 to 97 are formed, the lower surface Ma and the upper surface Mb of the metallic material sheet M and the wall surfaces 53a, 53b, 81a, and 81b may be subjected to an acidic degreasing process as preprocessing.

Next, as shown in FIG. 32, a second patterning process is performed in which the second upper resist film 96 and the wall surface resist film 97 are patterned using a photolithography technique. In this case, fourth resist openings 98 corresponding to the second upper vapor channel depressed portions 82 are formed in the second upper resist film 96 and the wall surface resist film 97. The fourth resist openings 98 are formed so as to extend from the second upper resist film 96 to the wall surface resist film 97. As shown in FIG. 32, the fourth resist openings 98 may be formed so that the opening edges opposite to the first upper vapor channel depressed portion 81 satisfy a Y-directional dimension w8′. The dimension w8′ is a dimension corresponding to the width w8 of the upper opening 83 and is set to form the width w8 of the upper opening 83 by etching.

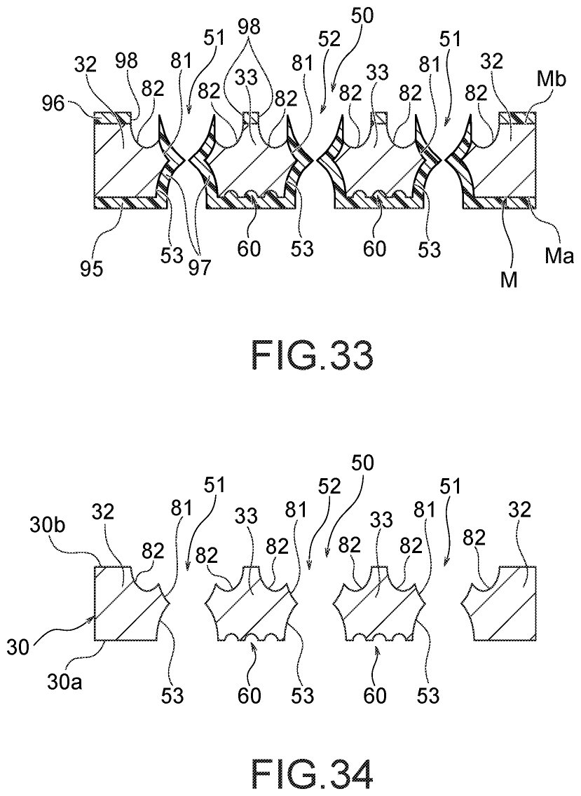

Next, as shown in FIG. 33, a second etching process is performed in which the upper surface Mb of the metallic material sheet M and the first upper wall surfaces 81a and 81b of the first upper vapor channel depressed portion 81 are etched as in the etching process shown in FIG. 21. As a result, the second upper vapor channel depressed portions 82 of the vapor channel portion 50 are formed on the upper surface Mb of the metallic material sheet M and the first upper wall surfaces 81a and 81b.

After the second etching process, as shown in FIG. 34, a second resist removing process is performed in which the second lower resist film 95 and the second upper resist film 96 are removed.

Thus, the wick sheet 30 according to this embodiment is obtained.

Thus, according to this embodiment, the first upper wall surfaces 81a and 81b of the first upper vapor channel depressed portion 81 and the second upper wall surfaces 82a of the second upper vapor channel depressed portions 82 positioned on both sides of the first upper vapor channel depressed portion 81 are connected by the third wall-surface protrusions 84, respectively. The third wall-surface protrusions 84 protrude toward the second body surface 30b. This can eliminate or reduce deformation of the second upper sheet surface 20b of the upper sheet 20 into a concave shape. In other words, a portion of the upper sheet 20 overlapping with the upper opening 83, which receives atmospheric pressure with the second upper sheet surface 20b, may enter the first upper vapor channel depressed portion 81 and the second upper vapor channel depressed portions 82 of the decompressed vapor channel portion 50. In such a case, depression of the relevant portion of the upper sheet 20 into a space deeper than the third wall-surface protrusions 84 can be eliminated or reduced. This can eliminate or reduce deformation of the second upper sheet surface 20b of the upper sheet 20 into a concave shape. This can improve the adhesion between the electronic device D and the lower sheet 10, thereby reducing the thermal resistance between the electronic device D and the vapor chamber 1.

In the embodiment described above, the first wall-surface protrusion 57 and the second wall-surface protrusion 58 are disposed at the intermediate position MP between the first body surface 30a and the second body surface 30b in the Z-direction. However, the embodiment is not limited thereto.

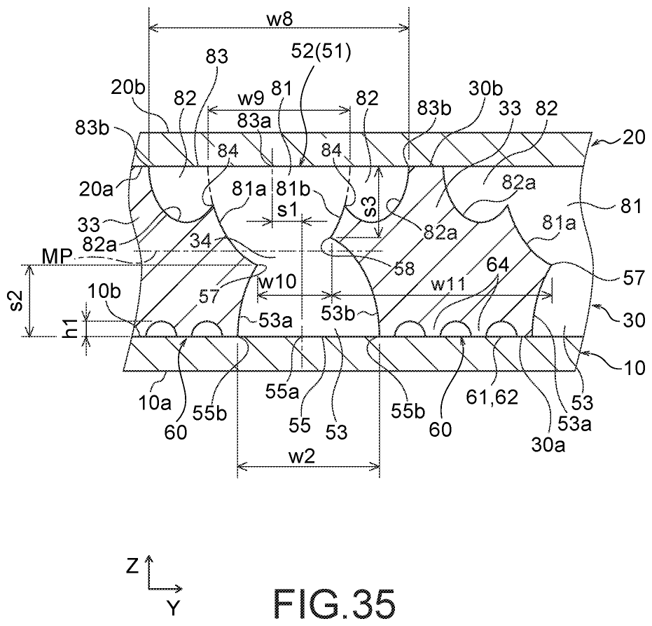

For example, as shown in FIG. 35, the first wall-surface protrusion 57 may be disposed off the intermediate position MP in the Z-direction. In FIG. 35, the first wall-surface protrusion 57 is disposed nearer to the first body surface 30a than the intermediate position MP. The distance s2 from the first body surface 30a to the first wall-surface protrusion 57 may be equal to the distance s2 shown in FIG. 17.

As shown in FIG. 35, the second wall-surface protrusion 58 may be disposed off the intermediate position MP in the Z-direction. In FIG. 35, the second wall-surface protrusion 58 is disposed nearer to the second body surface 30b than the intermediate position MP. The distance s3 from the second body surface 30b to the second wall-surface protrusion 58 may be equal to the distance s3 shown in FIG. 17.

In the modification shown in FIG. 35, the first wall-surface protrusion 57 and the second wall-surface protrusion 58 are disposed as in the example shown in FIG. 17. In this case, the cross-sectional shapes of the first vapor passage 51 and the second vapor passages 52 may be asymmetrical in the Y-direction.

In FIG. 35, the center 55a of the lower opening 55 is disposed off the center 83a of the upper opening 83 to one side in the Y-direction. Although FIG. 35 shows an example in which the lower opening 55 is disposed off the upper opening 83 to the right side, the lower opening 55 may be disposed off to the left side. The amount of the gap between the center 55a of the lower opening 55 and the center 83a of the upper opening 83 may be equal to the gap amount s1 shown in FIG. 17.

In FIG. 35, the right-hand upper opening side edge 83b of the upper opening 83 is disposed off the right-hand lower opening side edge 55b of the lower opening 55 to the right side, and the left-hand upper opening side edge 83b is disposed off the left-hand lower opening side edge 55b to the left side. Thus, the width w8 of the upper opening 83 is larger than the width w2 of the lower opening 55. However, if the width w8 of the upper opening 83 is larger than the width w2 of the lower opening 55, the right-hand upper opening side edge 83b of the upper opening 83 may be disposed off the right-hand lower opening side edge 55b of the lower opening 55 to the left side. Alternatively, in this case, the right-hand upper opening side edge 83b of the upper opening 83 may be disposed at the same position as the right-hand lower opening side edge 55b.

### Fourth Embodiment

Referring next to FIGS. 36 to 47, a body sheet for a vapor chamber, a vapor chamber, and an electronic apparatus according to a fourth embodiment of the present invention will be described.

The fourth embodiment shown in FIGS. 36 to 47 mainly differs in that a first wall surface end closer to the first body surface is positioned inside the vapor channel portion with respect to the protrusion in plan view. The other configurations are substantially the same as those of the first embodiment shown in FIGS. 1 to 17. In FIGS. 36 to 47, the same as those of the first embodiment shown in FIGS. 1 to 17 are given the same reference signs, and detailed descriptions will be omitted.

A vapor chamber 100 according to this embodiment will be described. As shown in FIGS. 36 to 37, the vapor chamber 100 includes a sealed space 103 in which the working fluids 2a and 2b are enclosed. Repetition of the phase change of the working fluids 2a and 2b in the sealed space 103 allows the electronic device D in the electronic apparatus E to be effectively cooled.

As shown in FIGS. 36 and 37, the vapor chamber 100 includes a lower sheet 110, an upper sheet 120, and a wick sheet 130 for the vapor chamber. The wick sheet 130 for the vapor chamber is hereinafter simply referred to as “wick sheet 130”. In the vapor chamber 100 according to this embodiment, the lower sheet 110, the wick sheet 130, and the upper sheet 120 are laminated in this order.

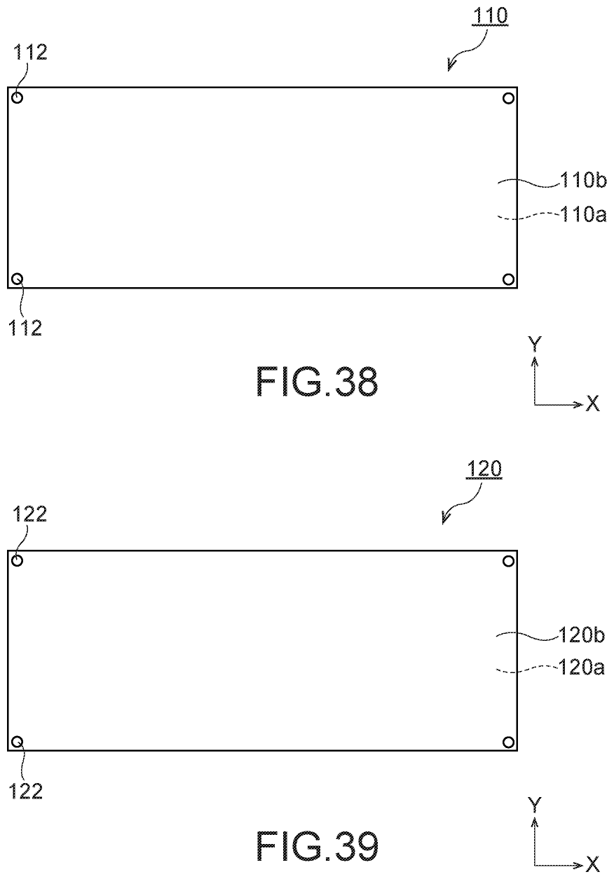

The vapor chamber 100 is schematically formed like a thin flat plate. The vapor chamber 100 may have any planar shape, such as a rectangular shape as shown in FIG. 36. The vapor chamber 100 may be a rectangle 50 mm or more and 200 or less on one side and 150 mm or more and 60 mm on the other side in plan view, or alternatively a square 70 mm or more and 300 or less on one side. The vapor chamber 100 may have any planar dimensions. This embodiment shows an example in which the vapor chamber 100 is a rectangle that is long in the X-direction (described later) in planar shape. In this case, as shown in FIGS. 38 to 41, the lower sheet 110, the upper sheet 120, and the wick sheet 130 may have a planar shape similar to the vapor chamber 100. The planar shape of the vapor chamber 100 is not limited to the rectangular shape and may be a circular shape, an elliptical shape, an L-shape, a T-shape, or any other shape.

As shown in FIG. 36, the vapor chamber 100 includes an evaporation region SR where the working fluids 2a and 2b evaporate and a condensation region CR where the working fluids 2a and 2b condense.

The evaporation region SR is overlapping with the electronic device D in plan view and is fitted with the electronic device D. The evaporation region SR may be disposed at any place of the vapor chamber 100. In this embodiment, the evaporation region SR is formed on one side of the vapor chamber 100 in the X-direction (on the left in FIG. 36). The heat from the electronic device D is transmitted to the evaporation region SR, and the heat causes the working liquid 2b to evaporate in the evaporation region SR. The heat from the electronic device D can be transmitted not only to a region overlapping with the electronic device D in plan view but also to the periphery of the region. For this reason, the evaporation region SR includes the region overlapping with the electronic device D in plan view and its peripheral region. The plan view may be the view of the vapor chamber 100 seen from a direction perpendicular to a surface of the vapor chamber 100 that receives the heat from the electronic device D and a surface that radiates the heat. The surface that receives the heat corresponds to a second upper sheet surface 120b of the upper sheet 120, described below. The surface that radiates the heat corresponds to a first lower sheet surface 110a of the lower sheet 110, described below. For example, the plan view corresponds to a state in which the vapor chamber 100 is seen from above or below, as shown in FIG. 36.

The condensation region CR is a region that is not overlapping with the electronic device D in plan view and in which the working vapor 2a of the working fluid radiates heat to condense. The condensation region CR may be the periphery of the evaporation region SR. In the condensation region CR, the heat from the working vapor 2a is radiated to the lower sheet 110, so that the working vapor 2a is cooled in the condensation region CR to condense.

The vapor chamber 100, if installed in a mobile terminal, may change in the vertical relationship according to the orientation of the mobile terminal. However, in this embodiment, the sheet that receives the heat from the electronic device D is referred to as the upper sheet 120, described above, and the sheet that radiates the received heat is referred to as the lower sheet 110, described above, for convenience. Accordingly, the following description is made, with the lower sheet 110 disposed on the lower side, and the upper sheet 120 on the upper side.

As shown in FIG. 37, the lower sheet 110 is an example of a first sheet. The lower sheet 110 includes a first lower sheet surface 110a disposed opposite to the wick sheet 130 and a second lower sheet surface 110b disposed opposite to the first lower sheet surface 110a. The second lower sheet surface 110b is located closer to the wick sheet 130. The lower sheet 110 may be generally flat and may generally have a fixed thickness. A housing member Ha that constitutes part of the housing of a mobile terminal or the like may be attached to the first lower sheet surface 110a. The entire first lower sheet surface 110a may be covered with the housing member Ha. As shown in FIG. 38, the lower sheet 110 may have alignment holes 112 at the four corners.

As shown in FIG. 37, the upper sheet 120 is an example of a second sheet. The upper sheet 120 includes a first upper sheet surface 120a disposed closer to the wick sheet 130 and a second upper sheet surface 120b disposed opposite to the first upper sheet surface 120a. The upper sheet 120 may be generally flat and may generally have a fixed thickness. The electronic device D may be mounted on the second upper sheet surface 120b. As shown in FIG. 39, the upper sheet 120 may have alignment holes 122 at the four corners.

As shown in FIG. 37, the wick sheet 130 is an example of the body sheet. The wick sheet 130 includes a vapor channel portion 150 and a liquid channel portion 160 next to the vapor channel portion 150. The wick sheet 130 further includes a first body surface 131a and a second body surface 131b opposite to the first body surface 131a. The first body surface 131a is disposed closer to the lower sheet 110, and the second body surface 131b is disposed closer to the upper sheet 120.

The second lower sheet surface 110b of the lower sheet 110 and the first body surface 131a of the wick sheet 130 may be permanently bonded to each other using diffusion bonding. Likewise, the first upper sheet surface 120a of the upper sheet 120 and the second body surface 131b of the wick sheet 130 may be permanently bonded to each other using diffusion bonding. The lower sheet 110, the upper sheet 120, and the wick sheet 130 may be bonded together, not using the diffusion bonding, but using any other method for permanent bonding, such as brazing.

As shown in FIGS. 37, 40, and 41, the wick sheet 130 according to this embodiment includes a frame 132 shaped like a rectangular frame in plan view and lands 133 provided in the frame 132. The frame 132 and the lands 133 extend from the first body surface 131a to the second body surface 131b. The frame 132 and the lands 133 are portions of the material of the wick sheet 130 left without being etched in an etching process, described later. In this embodiment, the frame 132 is shaped like a rectangular frame in plan view. The vapor channel portion 150 is defined in the frame 132. The working vapor 2a flows around the lands 133 in the frame 132.

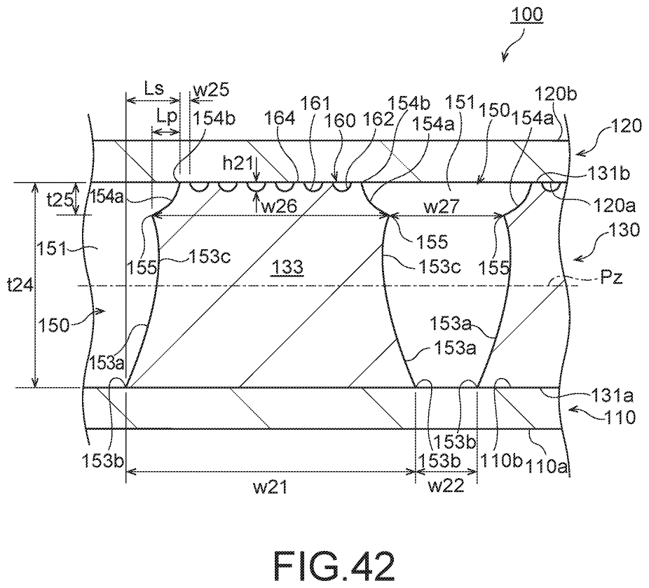

In this embodiment, the lands 133 may extend in an elongated manner in plan view, with the X-direction as the longitudinal direction. The lands 133 may have an elongated rectangular shape in plan view. The lands 133 may be disposed parallel to each other at regular intervals in the Y-direction. The working vapor 2a flows around the individual lands 133 and is conveyed to the condensation region CR. This eliminates or reduces obstruction to the flow of the working vapor 2a. The width w21 of the land 133 (see FIG. 42) may be, for example, 36 μm or more and 4,000 μm or less. The width w21 of the land 133 is the Y-directional dimension of the land 133, which indicates the dimension at a position at which the land 133 is the thickest (for example, a position at which first wall surface ends 153b, described lager, are present)

The frame 132 and the lands 133 are bonded to the lower sheet 110 and the upper sheet 120 using diffusion bonding. This increases the mechanical strength of the vapor chamber 100. A first wall surface 153a, a second wall surface 154a, and a protrusion 155 of a vapor passage 151, described later, constitute a side wall of the land 133. The first wall surface 153a, the second wall surface 154a, and the protrusion 155 are formed on both sides of the land 133 in the width direction (X-direction). The cross-sectional shape of each land 133 in the width direction (X-direction) (see FIG. 42) may be axisymmetric. The width w26 of the land 133 at positions at which the protrusions 155 are present may be, for example, 30 μm or more and 3,000 μm or less. The first body surface 131a and the second body surface 131b of the wick sheet 130 may be flat across the frame 132 and the lands 133. In FIG. 37, the side walls of the frame 132 have substantially the same shape as the sides wall of the land 133. However, the embodiment is not limited thereto. The side walls of the frame 132 do not have to necessarily be substantially the same shape as the side walls of the land 133.

The vapor channel portion 50 is an example of a penetration space. The vapor channel portion 150 is a channel that mainly allows the working vapor 2a to pass through. The vapor channel portion 150 extends from the first body surface 131a to the second body surface 131b and penetrate the wick sheet 130.

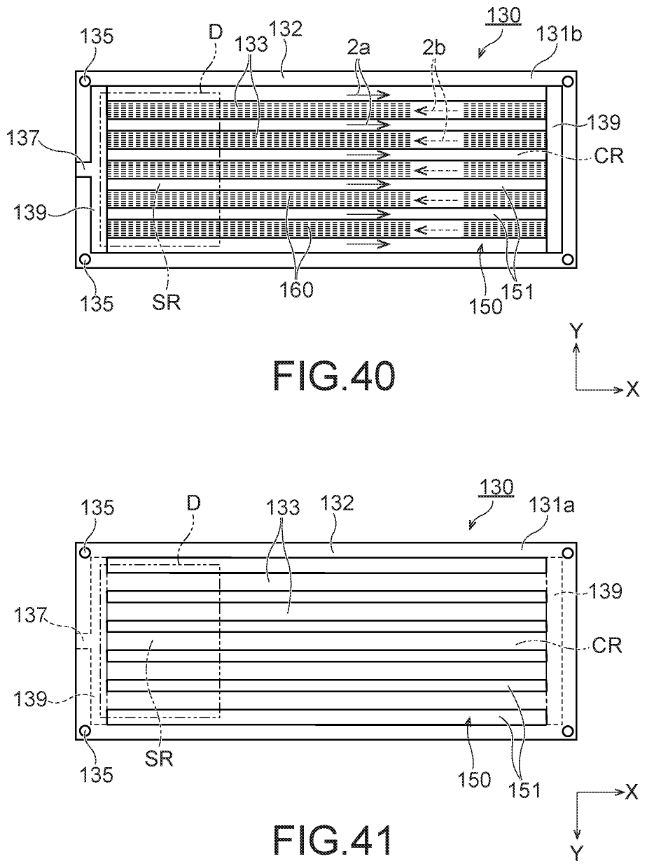

As shown in FIGS. 40 and 41, the vapor channel portion 150 of this embodiment includes a plurality of vapor passages 151. The vapor passages 151 are formed inside the frame 132 and outside the lands 133. In other words, the vapor passages 151 are formed between the frame 132 and the lands 133 and between the adjacent lands 133. The planar shape of each vapor passage 151 is an elongated rectangular shape. The vapor channel portion 150 is divided into the plurality of vapor passages 151 by the plurality of lands 133.

As shown in FIG. 37, the vapor passages 151 extend from the first body surface 131a to the second body surface 131b of the wick sheet 130. The vapor passages 151 may be formed by etching the first body surface 131a and the second body surface 131b of the wick sheet 130 in an etching process, described below.

As shown in FIG. 42, each vapor passage 151 includes a curved first wall surface 153a and a curved second wall surface 154a. The first wall surface 153a is positioned closer to the first body surface 131a and is curved so as to be recessed inward along the width of the land 133. The second wall surface 154a is positioned closer to the second body surface 131b and is curved so as to be recessed inward along the width of the land 133. The first wall surface 153a and the second wall surface 154a join together at the protrusion 155 protruding inward in the vapor passage 151. The protrusion 155 may be acutely or obtusely angled in a cross-sectional view. The width w27 between the pair of protrusions 155 next to each other with the vapor passage 151 therebetween (see FIG. 42) may be, for example, 30 μm or more and 3,000 μm or less. The width w27 between the pair of protrusions 155 is the distance of the vapor passage 151 measured in the width direction (Y-direction) at the positions of the protrusions 155.

The first wall surface 153a includes a first wall surface end 153b closer to the first body surface 131a. The upper end of the first wall surface 153a is the protrusion 155, which corresponds to an end of the first wall surface 153a closer to the second body surface 131b. The lower end of the first wall surface 153a is the first wall surface end 153b, which corresponds to an end of the first wall surface 153a closer to the first body surface 131a. The first wall surface 153a is in contact with the lower sheet 110 at the first wall surface end 153b. The first wall surface end 153b may be acutely angled in a cross-sectional view. In FIG. 42, a point of the first wall surface 153a most recessed inward along the width (Y-direction) of the land 133 in a cross-sectional view is indicated by sign 153c.

The second wall surface 154a includes a second wall surface end 154b closer to the second body surface 131b. The upper end of the second wall surface 154a is the second wall surface end 154b, which corresponds to an end of the second wall surface 154a closer to the second body surface 131b. The lower end of the second wall surface 154a is the protrusion 155, which corresponds to an end of the second wall surface 154a closer to the first body surface 131a. The second wall surface 154a is in contact with the upper sheet 120 at the second wall surface end 154b. The second wall surface end 154b may constitute the outer edge of a protrusion 164, described below. The second wall surface end 154b may be obtusely angled in a cross-sectional view.

In this embodiment, the first wall surface end 153b is positioned more inside the vapor channel portion 150 than the protrusion 155 in plan view. In other words, the second wall surface end 154b, the point 153c, the protrusion 155, and the first wall surface end 153b are present in this order from inside to outside in the width direction of the land 133 (Y-direction) in plan view. The outside corresponds the direction toward the vapor channel portion 150. The planar area of the vapor passage 151 is the maximum at the position of the second wall surface end 154b and is the minimum at the position of the first wall surface end 153b. The width w22 of the vapor passage 151 (see FIG. 42) may be, for example, 100 μm or more and 5,000 μm or less. The width w22 of the vapor passage 151 is the width of the narrowest portion of the vapor passage 151, and in this case, the distance measured in the width direction (Y-direction) at the position of the first wall surface end 153b. The width w22 of the vapor passage 151 corresponds to the gap between the lands 133 adjacent in the width direction (Y-direction).

As shown in FIG. 42, let Lp be the distance between the second wall surface end 154b and the protrusion 155, and Ls be the distance between the second wall surface end 154b and the first wall surface end 153b in the width direction (Y-direction) of the vapor channel portion 150. The distance Ls may be 1.05 or more times and two or less times the distance Lp or may be 1.05 or more times and 1.8 or less times the distance Lp. The fact that the distance Ls is 1.05 or more times the distance Lp can increase the bonding area of the land 133 and the lower sheet 110, thereby increasing the strength of the diffusion bonding in the vicinity of the first wall surface end 153b. The fact that the distance Ls is two or less times the distance Lp can provide a sufficient width of the vapor passage 151, allowing the working vapor 2a to flow smoothly in the vapor passage 151. The distance Ls may be 6 μm or more and 500 μm or less. The distance Lp may be 3 μm or more and 400 μm or less.

The distance Ls between the second wall surface end 154b and the first wall surface end 153b may be 1.1 or more times or 10 or less times the width w25 of the protrusion 164, described below. The fact that the distance Ls is 1.1 or more times the width w25 can increase the bonding area of the land 133 and the lower sheet 110, thereby increasing the strength of bonding, for example, diffusion bonding or brazing, in the vicinity of the first wall surface end 153b. The fact that the distance Ls is 10 or less times the width w25 can provide the vapor passage 151 with a sufficient width, allowing the working vapor 2a to flow smoothly in the vapor passage 151.

The protrusion 155 of the wick sheet 130 in the thickness direction (Z-direction) is nearer to the second body surface 131b than the intermediate position Pz between the first body surface 131a and the second body surface 131b. The distance t25 between the protrusion 155 and the second body surface 131b may be 5% or more, 10% or more, or 20% or more of the thickness t24 of the wick sheet 130, described later. The distance t25 may be 45% or less, 40% or less, or 30% or less of the thickness t24 of the wick sheet 130.

The vapor channel portion 150 including the vapor passage 151 with this configuration constitutes part of the sealed space 103 described above. As shown in FIG. 37, the vapor channel portion 150 according to this embodiment is mainly defined by the lower sheet 110, the upper sheet 120, and the frame 132 and the lands 133 of the wick sheet 130 described above. Each vapor passage 151 has a relatively large channel cross-sectional area so as to allow the working vapor 2a to pass through.

FIG. 37 shows the vapor passages 151 and so on in magnified view for clarification of the drawing. The number and disposition of the vapor passages 151 and so on differ from those in FIGS. 36, 40, and 41.

As shown in FIGS. 40 and 41, support portions 139 that support the lands 133 on the frame 132 are provided in the vapor channel portion 150. The support portions 139 support the adjacent lands 133. The support portions 139 are provided on opposite sides of the lands 133 in the longitudinal direction (X-direction). The support portions 139 may be formed so as not to obstruct the flow of the working vapor 2a diffusing in the vapor channel portion 150. In this case, the support portions 139 are disposed closer to the first body surface 131a of the wick sheet 130, and a space communicating with the vapor channel portion 150 is formed closer to the second body surface 131b. This allows the thickness of the support portion 139 to thinner than the wick sheet 130, thereby preventing the vapor passage 151 from being divided in the X-direction and the Y-direction. However, the embodiment is not limited thereto. The support portions 139 may be disposed closer to the second body surface 131b. A space communicating with the vapor channel portion 150 may be formed on both closer to the first body surface 131a and closer to the second body surface 131b.

As shown in FIGS. 40 and 41, the wick sheet 130 may have alignment holes 135 at the four corners.

As shown in FIG. 36, the vapor chamber 100 may further include an injecting portion 104 for injecting the working liquid 2b into the sealed space 103 at one edge in the X-direction. In the configuration shown in FIG. 36, the injecting portion 104 is disposed closer to the evaporation region SR. The injecting portion 104 includes an injection channel 37 formed in the wick sheet 130. The injection channel 137 is provided closer to the second body surface 131b of the wick sheet 130 and is concave on the second body surface 131b. After the vapor chamber 100 is completed, the injection channel 137 is in a sealed state. The injection channel 137 communicates with the vapor channel portion 150, and the working liquid 2b is injected into the sealed space 103 through the injection channel 137. Depending on the location of the liquid channel portion 160, the injection channel 137 may communicate with the liquid channel portion 160.

In this embodiment, the injecting portion 104 is provided at one of the pair of edges of the vapor chamber 100 in the X-direction. However, the embodiment is not limited thereto. The injecting portion 104 may be disposed at any position. The injecting portion 104 may be formed in advance so as to protrude from one edge of the vapor chamber 100 in the X-direction.

As shown in FIGS. 37, 40, and 41, the liquid channel portion 160 is disposed in the second body surface 131b of the wick sheet 130. The liquid channel portion 160 is configured to mainly allow the working liquid 2b to pass through. The liquid channel portion 160 constitutes part of the sealed space 103 described above and communicates with the vapor channel portion 150. The liquid channel portion 160 has a capillary structure (wick) for conveying the working liquid 2b to the evaporation region SR. In this embodiment, the liquid channel portion 160 is disposed in the second body surface 131b of the lands 133 of the wick sheet 130. The liquid channel portion 160 may be formed across the entire second body surface 131b of the lands 133.

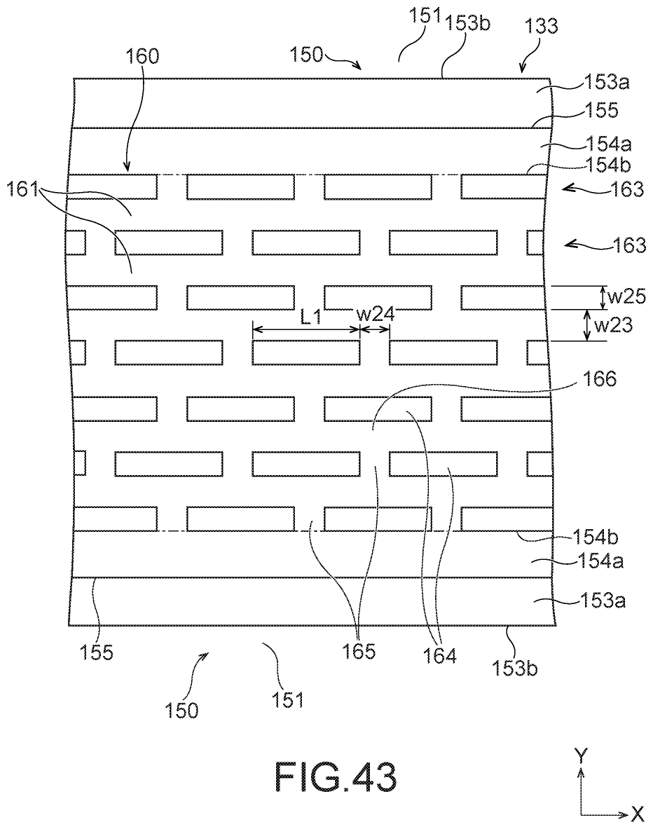

As shown in FIG. 43, the liquid channel portion 160 is an example of a group of grooves including a plurality of grooves. The liquid channel portion 160 includes a plurality of main channel grooves 161 arranged in parallel with each other, through which the working liquid 2b flows, and a plurality of communication grooves 165 communicating with the main channel grooves 161. The main channel grooves 161 of the liquid channel portion 160 are one example of a first groove. The communication grooves 165 of the liquid channel portion 160 are one example of a second groove. In the example shown in FIG. 43, each land 133 includes six main channel grooves 161. However, the embodiment is not limited thereto. Each land 133 may include any number of main channel grooves 161, for example, three or more and 20 or less.

As shown in FIG. 43, the main channel grooves 161 extend in the longitudinal direction (X-direction) of the land 133. The main channel grooves 161 are arranged parallel to each other. If the land 133 is curved in plan view, the main channel grooves 161 may be curved along the curve of the land 133. In other words, the main channel grooves 161 do not necessarily have to extend in a straight line or do not have to extend parallel in the X-direction.

The main channel grooves 161 have a channel cross-sectional area smaller than the vapor passage 151 of the vapor channel portion 150 to that the working liquid 2b flows owing to the capillary action. The main channel grooves 161 is configured to convey the working liquid 2b condensed from the working vapor 2a to the evaporation region SR. The main channel grooves 161 are disposed at intervals in the width direction (Y-direction).

The main channel grooves 161 are formed by etching the second body surface 131b of the wick sheet 130 in an etching process described below. As shown in FIG. 42, each main channel groove 161 has a curved wall surface 162. The wall surface 162 defines the main channel groove 161 and is curved to swell toward the first body surface 131a. In the cross section shown in FIG. 42, the curvature radius of each wall surface 162 may be smaller than the curvature radius of the second wall surface 154a of the vapor passage 151.

In FIG. 43, the width w23 of each main channel groove 161 may be, for example, 2 μm or more and 500 μm or less. The width w23 of the main channel groove 161 is a length in a direction perpendicular to the longitudinal direction of the land 133, and in this case, a Y-directional dimension. The width w23 of each main channel groove 161 is the dimension in the second body surface 131b.

As shown in FIG. 42, the depth h21 of the main channel groove 161 may be, for example, 3 μm or more and 300 μm or less. The depth h21 of the main channel groove 161 is the distance measured from the second body surface 131b in the direction perpendicular to the second body surface 131b, and in this case, a Z-directional dimension. The depth h21 is the depth of the main channel groove 161 at the deepest portion.

As shown in FIG. 43, the communication grooves 165 extend in a direction different from the X-direction. In this embodiment, the communication grooves 165 extend in the Y-direction perpendicular to the main channel grooves 161. Some of the communication grooves 165 are disposed so as to communicate between adjacent main channel grooves 161. The other communication grooves 165 are disposed so as to communicate between the vapor channel portion 150 (vapor passage 151) and the main channel groove 161 closest to the vapor channel portion 150. In other words, the communication grooves 165 extend from an end of the land 133 in the Y-direction to the main channel groove 161 next to the end. Thus, the vapor passage 151 of the vapor channel portion 150 and the main channel grooves 161 communicate with each other.

The communication grooves 165 have a channel cross-sectional area smaller than the vapor passage 151 of the vapor channel portion 150 so that mainly the working liquid 2b flows owing to the capillary action. The communication grooves 165 may be disposed at regular intervals in the longitudinal direction (X-direction) of the land 133.

The communication grooves 165 are also formed by etching as are the main channel grooves 161 and have a curved wall surface (not shown) similar to the main channel grooves 161. As shown in FIG. 43, the width w24 (the X-directional dimension) of the communication groove 165 may be 5 μm or more and 300 μm or less. The depth of the communication groove 165 may be 3 μm or more and 300 μm or less.

The main channel grooves 161 include intersecting portions 166 communicating with the communication grooves 165. At the intersecting portions 166, the main channel grooves 161 and the communication grooves 165 communicate in T-shape. This can eliminate or reduce communication between one main channel groove 161 and the communication groove 165 at one side (for example, the lower side in FIG. 43), at the intersecting portion 166 at which the main channel groove 161 and the communication groove 165 at the other side (for example, the upper side in FIG. 43) communicate. This can eliminate or reduce cutout of the wall surface 162 of the main channel groove 161 at the opposite ends in the Y-direction of the intersecting portion 166, allowing the wall surface 162 on one side to be left. This allows the working liquid 2b in the main channel grooves 161 to be acted upon by the capillary action also at the intersecting portion 166, thereby eliminating or reducing a decrease in the propulsive force of the working liquid 2b toward the evaporation region SR at the intersecting portion 166.

As shown in FIG. 43, a liquid protrusion row 163 is provided between the adjacent main channel grooves 161 of the liquid channel portion 160. In the example shown in FIG. 43, each land 133 includes seven liquid protrusion rows 163. However, the embodiment is not limited thereto. Each land 133 may include any number of liquid protrusion rows 163, for example, three rows or more and 20 rows or less.

As shown in FIG. 43, the liquid protrusion rows 163 extend in the longitudinal direction (X-direction) of the land 133. The liquid protrusion rows 163 are arranged parallel to each other. If the land 133 is curved in plan view, the liquid protrusion rows 163 may be curved along the curve of the land 133. In other words, the liquid protrusion rows 163 do not necessarily have to be formed in a straight line or extend parallel in the X-direction. The liquid protrusion rows 163 are disposed at intervals in the width direction (Y-direction).

Each liquid protrusion row 163 includes a plurality of protrusions 164 (liquid channel protrusions) arrayed in the X-direction. The protrusions 164 are disposed in the liquid channel portion 160 and protrude from the main channel grooves 161 and the communication grooves 165 into contact with the upper sheet 120. Each protrusion 164 has a rectangular shape that is long in the X-direction in plan view. The main channel groove 161 is disposed between the protrusions 164 adjacent in the Y-direction. The communication groove 165 is disposed between the protrusions 164 adjacent in the X-direction. The communication grooves 165 extend in the Y-direction to communicate between the main channel grooves 161 adjacent in the Y-direction. This allows the working liquid 2b to flow back and forth between the main channel grooves 161.

The protrusions 164 are remaining portions of the material of the wick sheet 130 without being etched in the etching process described below. In this embodiment, the planar shape of the protrusions 164 is rectangular, as shown in FIG. 43. The planar shape of the protrusions 164 corresponds to the shape in the second body surface 131b of the wick sheet 130. The width w25 of each protrusion 164 may be, for example, 5 μm or more and 500 μm or less. The width w25 of the protrusion 164 is the value of the maximum width of the protrusion 164.

The array pitch of the protrusions 164 in the width direction (Y-direction) of the protrusions 164 may be, for example, 7 μm or more and 1,000 μm or less. The array pitch of the protrusions 164 is the interval between the Y-directional center of the protrusion 164 and the Y-directional center of the adjacent protrusion 164 measured in the Y-direction.

In this embodiment, the protrusions 164 are disposed in a staggered pattern (alternately). More specifically, the protrusions 164 in the liquid protrusion row 163 next to each other in the Y-direction are alternately disposed in the X-direction. This gap amount may be half the array pitch of the protrusions 164 in the X-direction. The arrangement of the protrusions 164 is not limited to the staggered pattern but may be parallel arrangement. In this case, the protrusions 164 in the liquid protrusion row 163 next to each other in the Y-direction are arrayed also in the X-direction.

The lengths L1 of the protrusions 164 may be equal to each other among the protrusions 164. The length L1 of each protrusion 164 is larger than the width w24 of each communication groove 165 (L1>w24). The length L1 of the protrusion 164 corresponds to the X-directional dimension of the protrusion 164 and indicates the maximum X-directional dimension in the second body surface 131b.

The materials for the lower sheet 110, the upper sheet 120, and the wick sheet 130 may be any materials with high thermal conductivity. The lower sheet 110, the upper sheet 120, and the wick sheet 130 may contain, for example, copper or a copper alloy. This can enhance the thermal conductivity of the sheets 110, 120, and 130, thereby increasing the heat radiation efficiency of the vapor chamber 100. Using pure water as the working fluids 2a and 2b can eliminate or reduce corrosion. The sheets 110, 120, and 130 can be made of any other metallic materials, such as aluminum or titanium, or any other metallic alloy materials, such as stainless steel, that have desired heat radiation efficiency and that can prevent corrosion.

The thickness t21 of the vapor chamber 100 shown in FIG. 37 may be, for example, 100 μm or more and 2,000 μm or less. Setting the thickness t21 of the vapor chamber 100 to 100 μm or more to appropriately provide the vapor channel portion 150 allows the vapor chamber 100 to function appropriately. Setting the thickness t21 to 2,000 μm or less can eliminate or reduce an increase in the thickness t21 of the vapor chamber 100.

The thickness t22 of the lower sheet 110 may be, for example, 25 μm or more and 500 μm or less. Setting the thickness t22 of the lower sheet 110 to 25 μm or more can enhance the mechanical strength of the lower sheet 110. Setting the thickness t22 of the lower sheet 110 to 500 μm or less can eliminate or reduce an increase in the thickness t21 of the vapor chamber 100. Similarly, the thickness t23 of the upper sheet 120 may be set as is the thickness t22 of the lower sheet 110. The thickness t23 of the upper sheet 120 and the thickness t22 of the lower sheet 110 may differ from each other.

The thickness t24 of the wick sheet 130 may be, for example, 50 μm or more and 1,000 μm or less. Setting the thickness t24 of the wick sheet 130 to 50 μm or more to provide the vapor channel portion 150 appropriately allows the vapor chamber 100 to be appropriately operated. Setting the thickness t24 to 1,000 μm or less can eliminate or reduce an increase in the thickness t21 of the vapor chamber 100.

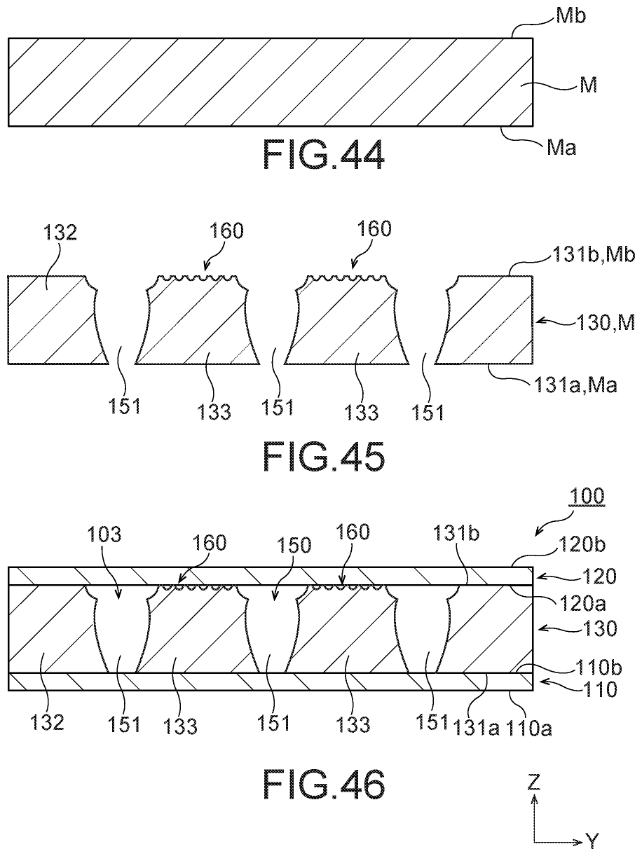

Next, a method for producing the vapor chamber 100 of this embodiment with such a configuration will be described with reference to FIGS. 44 to 46. FIGS. 44 to 46 show the same cross section as in the cross-sectional view of FIG. 37.

First, a process for producing the wick sheet 130 will be described.

First, as shown in FIG. 44, a preparation process is performed in which a plate-like metallic material sheet M including a lower surface Ma and an upper surface Mb is prepared.

After the preparation process, an etching process is performed, as shown in FIG. 45, in which the metallic material sheet M is etched from the lower surface Ma and the upper surface Mb to form the vapor channel portion 150 and the liquid channel portion 160.

More specifically, a patterned resist film (not shown) is formed on the lower surface Ma and the upper surface Mb of the metallic material sheet M using a photolithography technique. Next, the lower surface Ma and the upper surface Mb of the metallic material sheet M are etched via the openings of the patterned resist film. This causes the lower surface Ma and the upper surface Mb of the metallic material sheet M to be etched to a pattern, forming the vapor channel portion 150 and the liquid channel portion 160 as shown in FIG. 45. Examples of the etchant include a ferric chloride etchant, such as a ferric chloride water solution, and a copper chloride etchant, such as a copper chloride water solution.

The lower surface Ma and the upper surface Mb of the metallic material sheet M may be etched at the same time. However, the embodiment is not limited thereto. The lower surface Ma and the upper surface Mb may be separately etched. The vapor channel portion 150 and the liquid channel portion 160 may be etched either at the same time or separately.

In the etching process, a predetermined outline shape, as shown in FIGS. 40 and 41, can be provided by etching the lower surface Ma and the upper surface Mb of the metallic material sheet M. In other words, the edge of the wick sheet 130 is formed.

Thus, the wick sheet 130 according to this embodiment is provided.

After the wick sheet 130 is produced, a bonding process is performed in which the lower sheet 110, the upper sheet 120, and the wick sheet 130 are bonded, as shown in FIG. 46. The lower sheet 110 and the upper sheet 120 may be made of a rolled sheet having a desired thickness.

More specifically, first, the lower sheet 110, the wick sheet 130, and the upper sheet 120 are laminated in this order. In this case, the first body surface 131a of the wick sheet 130 is overlapped on the second lower sheet surface 110b of the lower sheet 110, and the first upper sheet surface 120a of the upper sheet 120 is overlapped on the second body surface 131b of the wick sheet 130. At that time, the sheets 110, 120, and 130 are aligned using the alignment holes 112 of the lower sheet 110, the alignment holes 135 of the wick sheet 130, and the alignment holes 122 of the upper sheet 120.

Next, the lower sheet 110, the wick sheet 130, and the upper sheet 120 are temporarily bonded together. For example, the sheets 110, 120, and 130 may be temporarily bonded using either spot resistance welding or laser welding.

Next, the lower sheet 110, the wick sheet 130, and the upper sheet 120 are permanently bonded using diffusion bonding. More specifically, the frame 132 of the wick sheet 130 and the first body surface 131a of each land 133 are diffusion-bonded to the second lower sheet surface 110b of the lower sheet 110. The frame 132 of the wick sheet 130 and the second body surface 131b of each land 133 are diffusion-bonded to the first upper sheet surface 120a of the upper sheet 120. Thus, the sheets 110, 120, and 130 are diffusion-bonded to form the sealed space 103 including the vapor channel portion 150 and the liquid channel portion 160, between the lower sheet 110 and the upper sheet 120.

After the bonding process, the working liquid 2b is injected into the sealed space 103 through the injecting portion 104.

Thereafter, the injection channel 137 described above is sealed. For example, the injection channel 137 may be sealed by partially melting the injecting portion 104. This can block the communication between the sealed space 103 and the outside to seal the working liquid 2b in the sealed space 103, thereby eliminating or reducing leakage of the working liquid 2b in the sealed space 103 to the outside.

Thus, the vapor chamber 100 according to this embodiment is provided.

Next, a method for operating the vapor chamber 100, that is, a method for cooling the electronic device D, will be described.

The vapor chamber 100 thus obtained is installed in the housing H of the electronic apparatus E, such as a mobile terminal, and in which the electronic device D, which is a device to be cooled, such as a CPU, is mounted on the second upper sheet surface 120b of the upper sheet 120. Alternatively, the vapor chamber 100 is mounted on the electronic device D. The working liquid 2b in the sealed space 103 adheres to the wall surfaces of the sealed space 103, in other words, the first wall surfaces 153a and the second wall surfaces 154a of the vapor passages 151, the wall surfaces 162 of the main channel grooves 161 of the liquid channel portions 160, and the wall surfaces of the communication grooves 165 by its surface tension. The working liquid 2b can also adhere to portions of the second lower sheet surface 110b of the lower sheet 110 exposed to the vapor passages 151. Furthermore, the working liquid 2b can also adhere to portions of the first upper sheet surface 120a of the upper sheet 120 exposed to the vapor passages 151, the main channel grooves 161, and the communication grooves 165.

When the electronic device D generates heat in this state, the working liquid 2b in the evaporation region SR (see FIGS. 40 and 41) receives the heat from the electronic device D. The received heat is absorbed as latent heat to evaporate (vaporize) the working liquid 2b to generate the working vapor 2a. Most of the generated working vapor 2a diffuses in the vapor passages 151 constituting the sealed space 103 (see the solid arrows in FIG. 40). The working vapor 2a in the vapor passages 151 goes away from the evaporation region SR, and most of the working vapor 2a is conveyed to the condensation region CR with a relatively low temperature (the right-hand portion in FIGS. 40 and 41). In the condensation region CR, the working vapor 2a radiates heat mainly to the lower sheet 110 and is cooled. The heat that the lower sheet 110 has received from the working vapor 2a is transmitted to the outside air via the housing member Ha (see FIG. 37).

The working vapor 2a radiates heat to the lower sheet 110 in the condensation region CR to lose the latent heat absorbed in the evaporation region SR to be condensed to generate the working liquid 2b. The generated working liquid 2b adheres to the first wall surface 153a and the second wall surface 154a of each vapor passage 151, the second lower sheet surface 110b of the lower sheet 110, and the first upper sheet surface 120a of the upper sheet 120. Here, the working liquid 2b continues to evaporate in the evaporation region SR. For this reason, the working liquid 2b in a region of the liquid channel portions 160 other than the evaporation region SR (that is, the condensation region CR) is conveyed to the evaporation region SR owing to the capillary action of the main channel grooves 161 (see the broken-line arrows in FIG. 40). This causes the working liquid 2b adhering to the vapor passages 151, the second lower sheet surface 110b, and the first upper sheet surface 120a to move to the liquid channel portions 160 and enter the main channel grooves 161 through the communication grooves 165. Thus, the working liquid 2b is charged to the main channel grooves 161 and the communication grooves 165. The charged working liquid 2b is thus smoothly conveyed to the evaporation region SR by the propulsive force toward the evaporation region SR owing to the capillary action of the main channel grooves 161.

In the liquid channel portions 160, the main channel grooves 161 communicate with adjacent main channel grooves 161 through the corresponding communication grooves 165. This configuration allows the working liquid 2b to flow back and forth between the adjacent main channel grooves 161, thereby eliminating or reducing the dry-out of the main channel grooves 161. This causes a capillary action in the working liquid 2b in the main channel grooves 161, allowing the working liquid 2b to be smoothly conveyed to the evaporation region SR.

The working liquid 2b that has reached the evaporation region SR evaporates when heated again by the electronic device D. The working vapor 2a that has evaporated from the working liquid 2b moves to the vapor passages 151 with a large channel cross-sectional area through the communication grooves 165 in the evaporation region SR and diffuses in the vapor passages 151. Thus, the working fluids 2a and 2b reflux in the sealed space 103 while repeating a phase change, that is, evaporation and condensation, to convey and radiate the heat in the electronic device D. As a result, the electronic device D is cooled.

In the evaporation region SR, the working vapor 2a generated from the working liquid 2b moves from the liquid channel portions 160 to the vapor passages 151. At that time, the working vapor 2a flows out from the main channel grooves 161 to the vapor passages 151 through the communication grooves 165 next to the protrusions 164 on the outside of the liquid channel portions 160 in the width direction.

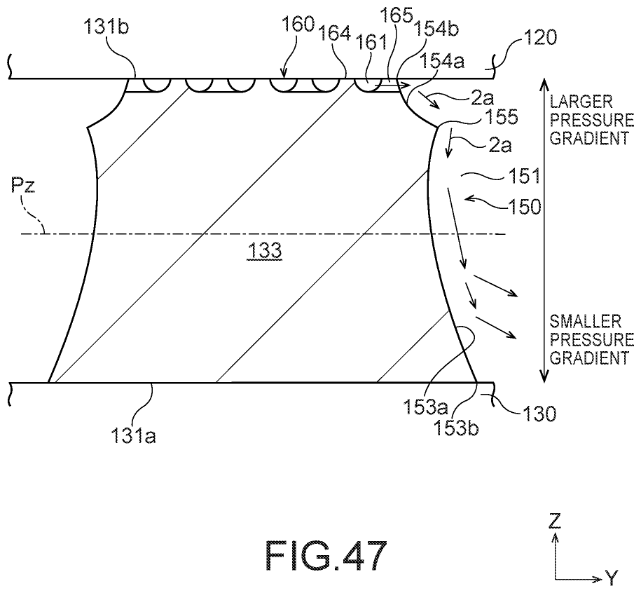

In general, a portion of the vapor passage 151 closer to the second body surface 131b has a pressure gradient of the working vapor 2a in the thickness direction (Z-direction), and a portion of the vapor passage 151 closer to the first body surface 131a has a small pressure gradient of the working vapor 2a in the thickness direction (Z-direction). In this embodiment, the protrusion 155 is positioned nearer to the second body surface 131b than the intermediate position Pz between the first body surface 131a and the second body surface 131b, as shown in FIG. 47. For this reason, the pressure gradient above and below the protrusion 155 is large when the vaporized working vapor 2a diffuses from the liquid channel portion 160 to the vapor passage 151. The pressure difference between the portions above and below the protrusion 155 can be large. The portion above the protrusion 155 corresponds to a portion closer to the second wall surface 154a, and the portion below the protrusion 155 corresponds to a portion closer to the first wall surface 153a. This allows the air pressure of the working vapor 2a above the protrusion 155 to be sufficiently higher than the air pressure of the working vapor 2a below the protrusion 155, allowing the working vapor 2a to easily go over the protrusion 155. This allows the working vapor 2a to easily wrap around from above to below the protrusion 155. As a result, the protrusion 155 is unlikely to obstruct the passage of the working vapor 2a, allowing the working vapor 2a to be smoothly diffused from the protrusion 155 to below the protrusion 155.

In this embodiment, the first wall surface end 153b of the first wall surface 153a is positioned more inside the vapor channel portion 150 than the protrusion 155 in plan view. The first wall surface 153a is therefore formed toward the interior of the vapor passage 151. This allows the working vapor 2a that has moved from above to below the protrusion 155 to be guided inside the vapor passage 151 in the width direction (Y-direction) along the first wall surface 153a. As a result, the working vapor 2a is smoothly diffused in the vapor passage 151, enhancing the cooling capacity of the vapor chamber 100. The curvature radius of the first wall surface 153a may be gradually increased toward the first wall surface end 153b. This increases the obstruction to the flow of the working vapor 2a to the first body surface 131a as the curvature radius increases. This allows the working vapor 2a in the vapor passage 151 to diffuse more smoothly.

In contrast, in the condensation region CR, the working liquid 2b generated from the working vapor 2a moves from the vapor passages 151 toward the liquid channel portions 160. At that time, the working liquid 2b passes through the communication grooves 165 next to the protrusions 164 widthwise outside the liquid channel portions 160 and enters the main channel grooves 161.

In this embodiment, the first wall surface end 153b of the first wall surface 153a is positioned more inside the vapor channel portion 150 than the protrusion 155 in plan view. This causes the working liquid 2b that has flowed through the vapor passage 151 to be guided to the liquid channel portion 160 along the first wall surface 153a. As a result, the working liquid 2b enters the liquid channel portion 160 smoothly. Furthermore, since the working liquid 2b easily goes over the protrusion 155, the protrusion 155 is not likely to obstruct the passage of the working liquid 2b, allowing the working liquid 2b to smoothly flow into the liquid channel portion 160 via the protrusion 155.

In this embodiment, the protrusion 155 is positioned nearer to the second body surface 131b than the intermediate position Pz. This allows the curvature radius of the second wall surface 154a to be smaller than the curvature radius of the first wall surface 153a. This configuration can enhance the capillary action of the second wall surface 154a, allowing the working liquid 2b to smoothly flow into the liquid channel portion 160. The enhancement of the capillary action can enhance the action to hold the working liquid 2b with the second wall surface 154a. This allows the amount of the working liquid 2b conveyed to the evaporation region SR to be increased.

In this embodiment, the first wall surface end 153b of the first wall surface 153a is positioned more inside the vapor channel portion 150 than the protrusion 155 in plan view. This facilitates checking the shape defect of the widthwise ends of the land 133 in plan view.

In this embodiment, the first wall surface 153a is curved toward the liquid channel portion 160. This can increase the volume of the vapor passage 151, thereby enhancing the cooling capacity of the vapor chamber 100.

It is to be understood that the present invention is not limited to the embodiments and the modifications and that the components can be modified in embodiments without departing from the spirit and scope of the invention. It is further to be understood that various inventions can be made using appropriate combinations of a plurality of components disclosed in the embodiments and modifications. Some of all the components disclosed in the embodiments and modifications may be deleted.

1. A body sheet for a vapor chamber in which a working fluid is enclosed, the body sheet comprising:
a first body surface;
a second body surface disposed opposite to the first body surface;
a penetration space extending from the first body surface to the second body surface; and
a plurality of first grooves provided on the first body surface and communicating with the penetration space, the plurality of first grooves extending in a first direction,
wherein the penetration space extends in the first direction in plan view, and
wherein, as seen in a cross section perpendicular to the first direction, the penetration space includes a first opening positioned on the first body surface and a second opening positioned on the second body surface, the second opening extending from a region overlapping with the first opening in plan view to a position overlapping with the first grooves in plan view.

2. The body sheet for a vapor chamber according to claim 1,
wherein, as seen in a cross section perpendicular to the first direction, the penetration space includes a first space depressed portion disposed on the first body surface and defining the first opening and a second space depressed portion disposed on the second body surface and defining the second opening, the second space depressed portion communicating with the first space depressed portion,
wherein the first space depressed portion includes a pair of first wall surfaces curved in a concave shape,
wherein the second space depressed portion includes a pair of second wall surfaces curved in a concave shape,
wherein the first wall surface and the second wall surface corresponding to each other are connected by a wall-surface protrusion protruding toward inside of the penetration space, and
wherein, as seen in a cross section perpendicular to the first direction, the second space depressed portion includes a flat surface having a flat shape connecting the second wall surface and the wall-surface protrusion corresponding to each other.

3. The body sheet for a vapor chamber according to claim 1,
wherein, as seen in a cross section perpendicular to the first direction, the penetration space includes a first space depressed portion disposed on the first body surface and defining the first opening and a second space depressed portion disposed on the second body surface and defining the second opening, the second space depressed portion communicating with the first space depressed portion,
wherein the first space depressed portion includes a pair of first wall surfaces curved in a concave shape,
wherein the second space depressed portion includes a pair of second wall surfaces curved in a concave shape,
wherein the first wall surface and the second wall surface corresponding to each other are connected by a wall-surface protrusion protruding toward inside of the penetration space,
wherein, as seen in a cross section perpendicular to the first direction, the second space depressed portion includes a protruding surface connecting the second wall surface and the wall-surface protrusion corresponding to each other, and
wherein the protruding surface includes a spatial protrusion extending in the first direction and protruding toward the second body surface.

4. The body sheet for a vapor chamber, according to claim 3, wherein the protruding surface includes a plurality of the spatial protrusions separate from each other.

5. The body sheet for a vapor chamber according to claim 1,
wherein, as seen in a cross section perpendicular to the first direction, the penetration space includes a first space depressed portion disposed on the first body surface and defining the first opening and a second space depressed portion disposed on the second body surface and defining the second opening, the second space depressed portion communicating with the first space depressed portion,
wherein the first space depressed portion includes a pair of first wall surfaces curved in a convex shape, and
wherein the second space depressed portion includes a pair of second wall surfaces curved in a concave shape.

6. The body sheet for a vapor chamber according to claim 1, wherein, as seen in a cross section perpendicular to the first direction, the second opening extends from a region overlapping with the first opening in plan view to positions overlapping with the first grooves in plan view on both sides of the first opening.

7. The body sheet for a vapor chamber according to claim 1, further comprising:
a frame having a frame shape in plan view and extending from the first body surface to the second body surface, the frame defining the penetration space; and
a land disposed inside the frame, the land extending in the first direction and extending from the first body surface to the second body surface,
wherein the first opening and the second opening are positioned between the frame and the land,
wherein the first grooves are positioned on the first body surface of the land, and
wherein, as seen in a cross section perpendicular to the first direction, the second opening extends from a region overlapping with the first opening in plan view to a position overlapping with the first grooves positioned in the land in plan view, the second opening extending more toward outside of the frame than the first opening.

8. A body sheet for a vapor chamber in which a working fluid is enclosed, the body sheet comprising:
a first body surface;
a second body surface disposed opposite to the first body surface; and
a penetration space extending from the first body surface to the second body surface,
wherein the penetration space extends in a first direction in plan view,
wherein, as seen in a cross section perpendicular to the first direction, the penetration space includes a first space depressed portion disposed on the first body surface and a second space depressed portion disposed on the second body surface and communicating with the first space depressed portion,
wherein the first space depressed portion includes a pair of first wall surfaces,
wherein the second space depressed portion includes a pair of second wall surfaces,
wherein one of the first wall surfaces of the first space depressed portion and corresponding one of the second wall surfaces of the second space depressed portion are connected by a first wall-surface protrusion,
wherein the first wall-surface protrusion protrudes toward inside of the penetration space,
wherein the first wall-surface protrusion is disposed off an intermediate position between the first body surface and the second body surface in a direction normal to the first body surface, and
wherein the first wall surface positioned opposite to the first wall-surface protrusion of the first space depressed portion and corresponding one of the second wall surfaces of the second space depressed portion are continuously formed in a concave shape from the first wall surface to the second wall surface.

9. The body sheet for a vapor chamber according to claim 8,
wherein the penetration space includes a first opening positioned on the first body surface and defined by the first space depressed portion and a second opening positioned on the second body surface and defined by the second space depressed portion, and
wherein, as seen in a cross section perpendicular to the first direction, a center of the first opening is disposed off a center of the second opening.

10. (canceled)

11. The body sheet for a vapor chamber according to claim 9, further comprising:
a frame having a frame shape in plan view; and
a land disposed inside the frame, the land extending in the first direction and defining the penetration space with the frame,
wherein a gap amount between the center of the first opening and the center of the second opening is expressed as 0.05 mm to (0.8×w1) mm, where w1 is a width of the land.

12. The body sheet for a vapor chamber according to claim 8, further comprising:
a plurality of first grooves provided on the first body surface and communicating with the penetration space,
wherein the first wall-surface protrusion is disposed nearer to the first body surface than the intermediate position.

13. The body sheet for a vapor chamber according to claim 12,
wherein the first wall surface of the first space depressed portion positioned opposite to the first wall-surface protrusion and corresponding one of the second wall surfaces of the second space depressed portion are connected by a second wall-surface protrusion,
wherein the second wall-surface protrusion protrudes toward inside of the penetration space, and
wherein the second wall-surface protrusion is disposed off an intermediate position between the first body surface and the second body surface in the direction of normal.

14. The body sheet for a vapor chamber according to claim 13, wherein the second wall-surface protrusion is disposed nearer to the first body surface than the intermediate position.

15. A body sheet for a vapor chamber in which a working fluid is enclosed, the body sheet comprising:
a first body surface;
a second body surface disposed opposite to the first body surface; and
a penetration space extending from the first body surface to the second body surface,
wherein the penetration space extends in a first direction in plan view,
wherein, as seen in a cross section perpendicular to the first direction, the penetration space includes a first space depressed portion disposed on the first body surface, a second space depressed portion disposed on the second body surface and communicating with the first space depressed portion, and third space depressed portions positioned on the second body surface on both sides of the second space depressed portion and communicating with the second space depressed portion,
wherein the second space depressed portion includes a pair of second wall surfaces,
wherein the third space depressed portions each include a third wall surface,
wherein each of the second wall surfaces of the second space depressed portion and corresponding one of the third wall surfaces of the third space depressed portions are connected by a third wall-surface protrusion, and
wherein the third wall-surface protrusion protrudes toward the second body surface.

16-18. (canceled)

19. A vapor chamber comprising:
a first sheet;
a second sheet; and
the body sheet for the vapor chamber according to claim 1, the body sheet being interposed between the first sheet and the second sheet.

20. An electronic apparatus comprising:
a housing;
an electronic device housed in the housing; and
the vapor chamber according to claim 19, the vapor chamber being thermally in contact with the electronic device.
